(19) United States
(12) Patent Application Publication
(10) Pub. No.: US 2014/0093824 A1
(43) Pub. Date: Apr. 3, 2014

(54) RESIST COMPOSITION FOR EUV OR EB AND METHOD OF FORMING RESIST PATTERN

(71) Applicant: Tokyo Ohka Kogyo Co., Ltd., Kawasaki-shi (JP)

(72) Inventors: Daisuke Kawana, Kawasaki-shi (JP); Kenta Suzuki, Kawasaki-shi (JP); Tatsuya Fujii, Kawasaki-shi (JP); Jun Iwashita, Kawasaki-shi (JP); Kenri Konno, Kawasaki-shi (JP)

(73) Assignee: Tokyo Ohka Kogyo Co., Ltd., Kawasaki-shi (JP)

(21) Appl. No.: 14/043,315

(22) Filed: Oct. 1, 2013

(30) Foreign Application Priority Data
Oct. 2, 2012 (JP) 2012-220412

(51) Int. Cl. G03F 7/038; G03F 7/20

(52) U.S. Cl. CPC G03F 7/0388; G03F 7/20
USPC 430/296; 526/243; 430/325

(57) ABSTRACT

A resist composition including a polymeric compound (A1) containing a structural unit (a0) represented by general formula (a0-1) and a structural unit (a6) which generates acid upon exposure, and a method of forming a resist pattern using the resist composition. In general formula (a0-1), R represents a hydrogen atom, an alkyl group of 1 to 5 carbon atoms or a halogenated alkyl group of 1 to 5 carbon atoms; Wa⁰ represents a single bond or an aliphatic hydrocarbon group having 1 to 5 carbon atoms and having a valency of (nₐ₀+1); Ra⁰ represents an aryl group of 4 to 16 carbon atoms which may have a substituent; and nₐ₀ represents 1 or 2.

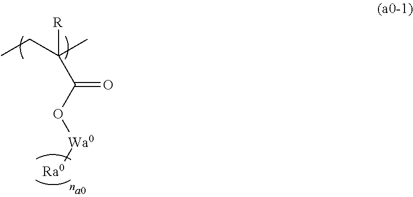

### TECHNICAL FIELD

The present invention relates to a resist composition for EUV or EB and a method of forming a resist pattern.

Priority is claimed on Japanese Patent Application No. 2012-220412 filed on Oct. 2, 2012, the content of which is incorporated herein by reference.

### BACKGROUND ART

In lithography techniques, for example, a resist film composed of a resist material is formed on a substrate, and the resist film is subjected to selective exposure, followed by development, thereby forming a resist pattern having a predetermined shape on the resist film. A resist material in which the exposed portions of the resist film become soluble in a developing solution is called a positive-type, and a resist material in which the exposed portions of the resist film become insoluble in a developing solution is called a negative-type.

In recent years, in the production of semiconductor elements and liquid crystal display elements, advances in lithography techniques have led to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production of the semiconductor elements.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid generator component that generates acid upon exposure. For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid generator component, and the action of this acid causes an increase in the solubility of the base resin in an alkali developing solution, making the exposed portions soluble in the alkali developing solution. Thus, by conducting alkali developing, the unexposed portions remain to form a positive resist pattern.

The base resin used exhibits increased polarity by the action of acid, thereby exhibiting increased solubility in an alkali developing solution, whereas the solubility in an organic solvent is decreased. Therefore, when such a base resin is applied to a solvent developing process using a developing solution containing an organic solvent (organic developing solution) instead of an alkali developing process, the solubility of the exposed portions in an organic developing solution is decreased. As a result, in the solvent developing process, the unexposed portions of the resist film are dissolved and removed by the organic developing solution, and a negative resist pattern in which the exposed portions are remaining is formed. Such a solvent developing process for forming a negative-tone resist composition is sometimes referred to as “negative-tone developing process” (for example, see Patent Document 1).

Currently, resins that contain structural units derived from (meth)acrylate esters within the main chain (acrylic resins) are now widely used as base resins for chemically amplified resist compositions that use ArF excimer laser lithography, as they exhibit excellent transparency in the vicinity of 193 nm (for example, see Patent Document 2).

Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

On the other hand, as acid generators usable in a chemically amplified resist composition, various types have been proposed including, for example, onium salt acid generators; oxime sulfonate acid generators; diazomethane acid generators; nitrobenzylsulfonate acid generators; iminosulfonate acid generators; and disulfone acid generators.

Furthermore, research is also being conducted into lithography techniques that use an exposure light source having a wavelength shorter (energy higher) than ArF excimer laser, such as electron beam (EB), extreme ultraviolet radiation (EUV), and X ray.

It is required for a resist material for EUV lithography or EB lithography to improve the sensitivity to EUV or EB, the resolution capable of forming a target fine resist pattern, excellent lithography properties and excellent resist pattern shape.

Recently, in EUV lithography or EB lithography, as a resist material, in terms of lithography properties, a chemically amplified composition is generally used, which has been proposed for KrF excimer lasers or ArF excimer lasers.

Further, in Patent Document 3, a resist composition which is effective for EUV lithography or EB lithography, and which can suppress thickness loss of the resist film caused during formation of a resist pattern, is proposed. Specifically, a positive resist composition which includes, as a base resin, a polymeric compound which contains a structural unit having an acid dissociable, dissolution inhibiting group that contains a naphthalene ring, is disclosed.

### DOCUMENTS OF RELATED ART

### Patent Document

[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. 2011-123463

### SUMMARY OF THE INVENTION

However, when a chemically amplified composition proposed for KrF excimer lasers or ArF excimer lasers is used in EUV lithography or EB lithography, the shape of the resist pattern to be formed is deteriorated.

For example, in EUV lithography, due to the influence from deflection of reflected light (flare) caused by an EUV exposure apparatus, an acid generator component is decomposed at unexposed portions to generate acid, and problems that the contrast of the resist pattern, thickness loss and roughness (surface roughness on the upper surface or side wall of the pattern) are deteriorated are likely to occur.

Further, in EB lithography, due to the influences from scatter of electrons (blur) such as forward scatter caused by an electron beam lithography apparatus and back scatter caused by a substrate, problems similar to the problems due to flare are likely to occur.

The roughness of the resist pattern becomes the cause of defects in the shape of the resist pattern. For example, roughness on the side wall surfaces of a pattern can cause non-uniformity of the line width of line and space patterns, or distortions around the holes in hole patterns.

As the miniaturization of patterns proceed, defects in the shape of the resist pattern adversely affect the formation of very fine semiconductor elements. Therefore, it is required for a resist material for EUV lithography or EB lithography to be resistant to any adverse influences from flair caused by an EUV exposure apparatus and blur caused by EB.

When the positive resist composition containing the polymer composition described in Patent Document 3 is used in EUV lithography or EB lithography, satisfactory lithography properties and shape of the resist pattern required in formation of a target fine pattern cannot be achieved, and therefore, further improvement has been demanded.

The present invention takes the above circumstances into consideration, with an object of providing a resist composition useful for EUV or EB and a method of forming a resist pattern.

A first aspect of the present invention for solving the aforementioned problems is a resist composition for EUV or EB which includes a base component (A) which generates acid upon exposure and exhibits changed solubility in a developing solution by the action of acid, the base component (A) containing a polymeric compound (A1) having a structural unit (a0) represented by general formula (a0-1) shown below and a structural unit (a6) which generates acid upon exposure.

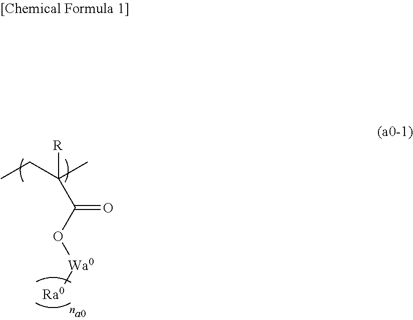

In the formula, R represents a hydrogen atom, an alkyl group of 1 to 5 carbon atoms or a halogenated alkyl group of 1 to 5 carbon atoms; Wa⁰ represents a single bond or an aliphatic hydrocarbon group having 1 to 5 carbon atoms and having a valency of (nₐ₀+1); Ra⁰ represents an aryl group of 4 to 16 carbon atoms which may have a substituent; and nₐ₀ represents 1 or 2.

A second aspect of the present invention is a method of forming a resist pattern, including forming a resist film on a substrate using a resist composition for EUV or EB according to the first aspect of the present invention, subjecting the resist film to irradiate with EUV or EB, and subjecting the resist film to developing to form a resist pattern.

According to the present invention, there are provided a resist composition useful for EUV or EB, and a method of forming a resist pattern using the same.

### MODE FOR CARRYING OUT THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with fluorine atom(s).

The term “structural unit” refers to a monomer unit that contributes to the formation of a polymeric compound (resin, polymer, copolymer).

The expression “may have a substituent” means that a case where a hydrogen atom (—H) is substituted with a monovalent group, or a case where a methylene (—CH₂—) group is substituted with a divalent group.

The term “exposure” is used as a general concept that includes irradiation with any form of radiation.

An “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (Ra) that substitutes the hydrogen atom bonded to the carbon atom on the α-position is an atom other than hydrogen or a group, and examples thereof include an alkyl group of 1 to 5 carbon atoms and a halogenated alkyl group of 1 to 5 carbon atoms. Further, an acrylate ester having the hydrogen atom bonded to the carbon atom on the α-position substituted with a substituent (R^{α0}) which has been substituted with a substituent containing an ester bond (e.g., an itaconic acid diester), or an acrylic acid having the hydrogen atom bonded to the carbon atom on the α-position substituted with a substituent (R^{α0}) which has been substituted with a hydroxyalkylgroup or a group in which the hydroxy group within a hydroxyalkyl group has been modified (e.g., α-hydroxyalkyl acrylate) can be mentioned as an acrylate ester having the hydrogen atom bonded to the carbon atom on the α-position substituted with a substituent. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from acrylamide” refers to a structural unit that is formed by the cleavage of the ethylenic double bond of acrylamide.

The acrylamide may have the hydrogen atom bonded to the carbon atom on the α-position substituted with a substituent, and may have either or both terminal hydrogen atoms on the amino group of acrylamide substituted with a substituent. A carbon atom on the α-position of an acrylamide refers to the carbon atom bonded to the carbonyl group, unless specified otherwise.

As the substituent which substitutes the hydrogen atom on the α-position of acrylamide, the same substituents as those described above for the substituent (R^{α0}) on the α-position of the aforementioned α-substituted acrylate ester can be mentioned.

A “structural unit derived from hydroxystyrene or a hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and which may have the hydrogen atom on the α-position substituted with a substituent; and hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include vinylbenzoic acid in which the hydrogen atom of the carboxy group has been substituted with an organic group and which may have the hydrogen atom on the α-position substituted with a substituent; and vinylbenzoic acid which has a substituent other than a hydroxy group or carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The term “styrene” includes styrene itself and compounds in which the hydrogen atom at the α-position of styrene has been substituted with another substituent such as an alkyl group or a halogenated alkyl group.

A “structural unit derived from styrene or a styrene derivative” refers to a structural unit that is formed by the cleavage of the ethylenic double bond of styrene or a styrene derivative.

As the alkyl group as a substituent on the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

<<Resist Composition for EUV or EB>>

The resist composition according to a first aspect of the present invention is a resist composition for EUV or EB including a base component (A) which generates acid upon exposure and exhibits changed solubility in a developing solution under action of acid (hereafter, frequently referred to as “component (A)”).

Since the resist composition of the present embodiment includes a component (A), the resist composition exhibits changed solubility in a developing solution upon exposure of EUV or EB. When a resist film formed using the resist composition is subjected to a selective exposure, acid is generated from the component (A) at exposed portions, and the generated acid acts on the component (A) to change the solubility of the component (A) in a developing solution. As a result, the solubility of the exposed portions in a developing solution is changed, whereas the solubility of the unexposed portions in a developing solution remains unchanged. Therefore, by subjecting the resist film to development, the exposed portions are dissolved and removed to form a positive-tone resist pattern in the case of a positive resist, whereas the unexposed portions are dissolved and removed to form a negative-tone resist pattern in the case of a negative resist.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present embodiment may be either a positive resist composition or a negative resist composition. Further, in the formation of a resist pattern, the resist composition of the present embodiment can be applied to an alkali developing process using an alkali developing solution in the developing treatment, or a solvent developing process using a developing solution containing an organic solvent (organic developing solution) in the developing treatment. The resist composition of the present invention is preferably used in the formation of a positive-tone resist pattern by an alkali developing process. In such a case, as the component (A), a base component that exhibits increased solubility in an alkali developing solution under the action of acid is used.

<Component (A)>

The component (A) used in the resist composition of the present embodiment is a base component which generates acid upon exposure and exhibits changed solubility in a developing solution under action of acid and contains a polymeric compound (A1) (hereafter, frequently referred to as “component (A1)”) having a structural unit (a0) and a structural unit (a6) described later.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a non-polymer having a molecular weight in the range of 500 to less than 4,000 is referred to as a low molecular weight compound.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

As the component (A), a low molecular weight compound and the component (A1) may be used in combination.

The component (A) containing the component (A1) may be a component that exhibits increased solubility in a developing solution under action of acid or a component that exhibits decreased solubility in a developing solution under action of acid.

[Component (A1)]

The component (A1) is a polymeric compound including the structural unit (a0) represented by general formula (a0-1) and the structural unit (a6) which generates acid upon exposure.

When the resist film formed using the resist composition of the present embodiment is subjected to irradiate with EUV or EB, in the structural unit (a0), at least a part of the bond within the structure thereof is cleaved by the action of acid to exhibit increased polarity. Therefore, the resist composition of the present embodiment becomes a positive type in the case of an alkali developing process, and a negative type in the case of a solvent developing process. Since the polarity of the component (A1) is changed prior to and after exposure, by using the component (A1), an excellent development contrast can be achieved not only in an alkali developing process, but also in a solvent developing process.

More specifically, in the case of applying an alkali developing process, the component (A1) is substantially insoluble in an alkali developing solution prior to exposure, but when acid is generated from the structural unit (a6) upon exposure, the action of this acid causes an increase in the polarity of the base component, thereby increasing the solubility of the component (A1) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A1) exhibits high solubility in an organic developing solution prior to exposure, and when acid is generated from the structural unit (a6) upon exposure, the polarity of the component (A1) is increased by the action of the generated acid, thereby decreasing the solubility of the component (A1) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

(Structural Unit (a0))

The structural unit (a0) is represented by general formula (a0-1) shown below.

In the structural unit (a0), when the structural unit (a0) is irradiated with EUV or EB, the bond between the oxygen atom and Wa⁰ in the “—O-Wa⁰-” bond within the structural unit (a0) can be cleaved. As a result, a polar group (i.e., carboxy group) is generated, and therefore, the polarity is increased. As a result, the polarity of the entire component (A1) is increased. By the increase in the polarity, the solubility in an alkali developing solution changes, and the solubility in an alkali developing solution is relatively increased, whereas the solubility in an organic developing solution is relatively decreased.

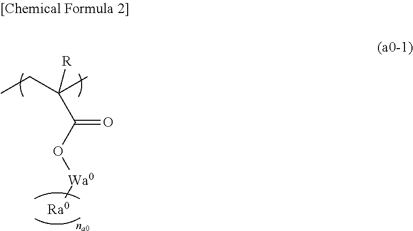

In the formula, R represents a hydrogen atom, an alkyl group of 1 to 5 carbon atoms or a halogenated alkyl group of 1 to 5 carbon atoms; Wa⁰ represents a single bond or an aliphatic hydrocarbon group having 1 to 5 carbon atoms and having a valency of (nₐ₀+1); Ra⁰ represents an aryl group of 4 to 16 carbon atoms which may have a substituent; and nₐ₀ represents 1 or 2.

In general formula (a1-0), as the alkyl group of 1 to 5 carbon atoms represented by R, a linear or branched alkyl group of 1 to 5 carbon atoms is preferable, and specific examples include a methyl group, an ethyl group, a propyl group, an isopropyl group, an n-butyl group, an isobutyl group, a tert-butyl group, a pentyl group, an isopentyl group and a neopentyl group.

The halogenated alkyl group of 1 to 5 carbon atoms is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In the formula (a0-1), Wa⁰ represents a single bond or an aliphatic hydrocarbon group having 1 to 5 carbon atoms and having a valency of (nₐ₀+1).

Wa⁰ represents an aliphatic hydrocarbon group having a valency of (nₐ₀+1), that is, a divalent or trivalent aliphatic hydrocarbon group.

The divalent aliphatic hydrocarbon group for Wa⁰ may be a linear, branched or cyclic aliphatic hydrocarbon group, and preferably a linear or branched aliphatic hydrocarbon group. Specific examples for Wa⁰ (divalent aliphatic hydrocarbon group) include —CH₂—, —CH(CH₃)—, —C(CH₃)₂—, —(CH₃)C(C₂H₅)—, —C(C₂H₅)₂—, —(CH₃)C(CH(CH₃)₂)—, —CH(CH(CH₃)₂)—; —CH₂—CH(CH₃)—, —CH₂—C(CH₃)₂—, —CH₂—CH(C₂H₅)—, —C(CH₃)₂—CH₂—, —CH(CH₃)—CH₂—, and —CH(C₂H₅)—CH₂—, and —CH₂—, —CH(CH₃)—, —C(CH₃)₂—, and —C(CH₃)₂—CH₂— are preferred.

As the trivalent aliphatic hydrocarbon group for Wa⁰, a group in which one hydrogen atom has been removed from the aforementioned divalent aliphatic hydrocarbon group for Wa⁰, and a group in which the divalent aliphatic hydrocarbon group has been bonded to an another divalent aliphatic hydrocarbon group can be mentioned. Specific examples of Wa⁰ (trivalent aliphatic hydrocarbon group) are shown below.

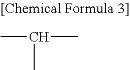

In the formula (a0-1), Ra⁰ represents an aryl group of 4 to 16 carbon atoms which may have a substituent.

The aryl group for Ra⁰ is a group in which one hydrogen atom has been removed from an aromatic ring, and may be a monocyclic group or a polycyclic group (condensed ring), and may be a heterocycle containing a hetero atom. The aryl group preferably has 4 to 16 carbon atoms, more preferably 8 to 16 and still more preferably 10 to 14. Here, the number of carbon atoms within a substituent(s) is not included in the number of carbon atoms of the aryl group.

Specific examples of Ra⁰ are shown below. The “*” in the formula represents a valence bond.

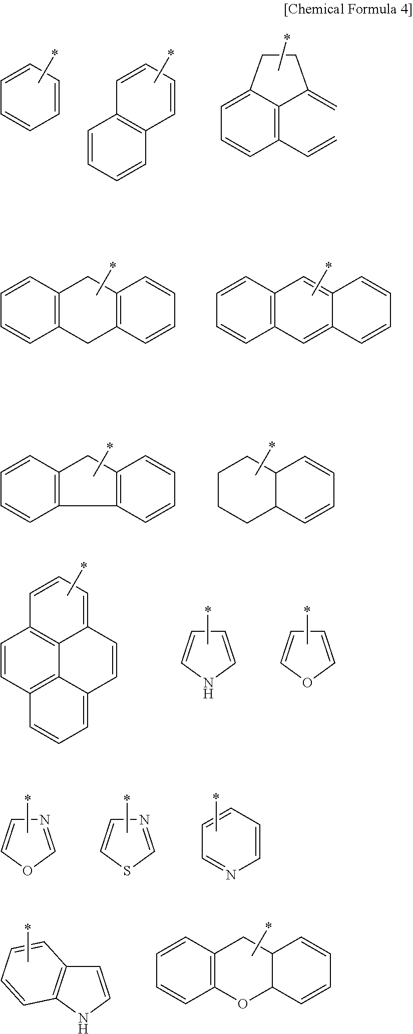

As the substituent which the aryl group for Ra⁰ may have (i.e., substituent for substituting a hydrogen atom of the aryl group), any groups which have no aromatic ring in the structure thereof can be used, and examples thereof include an alkyl group, a halogen atom and a halogenated alkyl group.

The alkyl group as the substituent is preferably an alkyl group of 1 to 6 carbon atoms, and a methyl group, an ethyl group, a propyl group, an n-butyl group or a tert-butyl group is more preferable.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

In formula (a0-1), nₐ₀ represents 1 or 2, and in terms of suppressing the solubility in a developing solution, na₀ is preferably 2.

When nₐ₀ is 2, a plurality of Ra⁰ may have a same structure or a different structure from each other.

Specific examples of structural units represented by general formula (a0-1) are shown below. In the formulae shown below, R^{α} represents a hydrogen atom, a methyl group or a trifluoromethyl group (hereinafter the same definition shall apply).

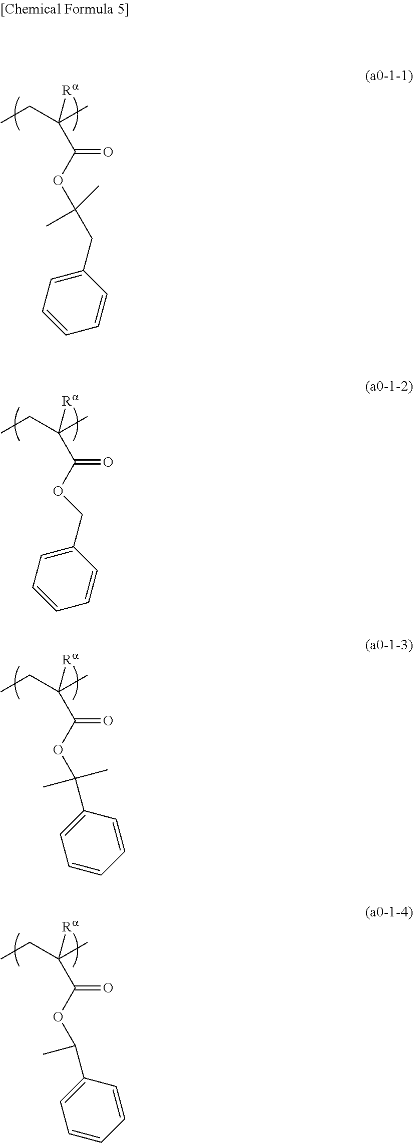

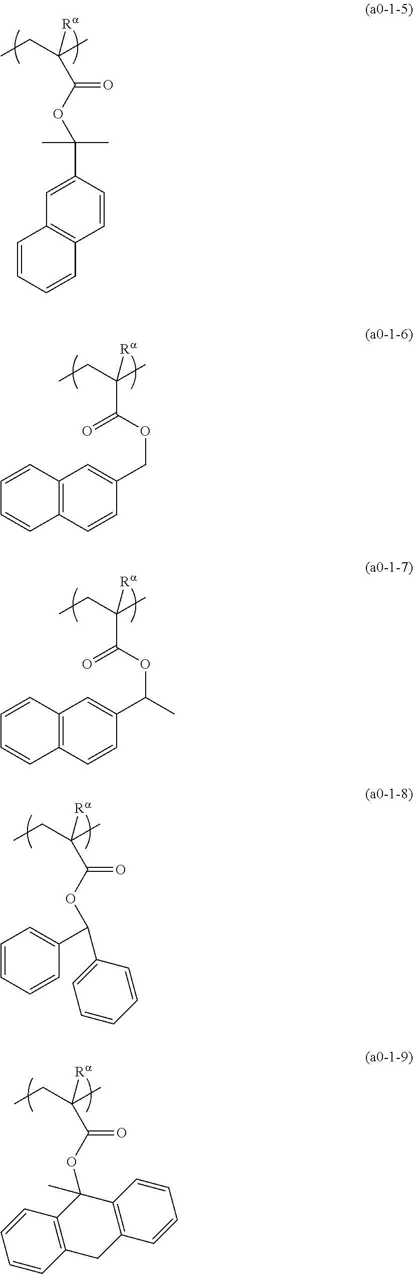

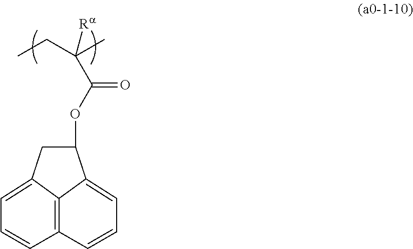

As the structural unit (a0) contained in the component (A1), 1 type of structural unit may be used, or 2 or more types may be used.

In the component (A1), the amount of the structural unit (a0) based on the combined total of all structural units constituting the component (A1) is preferably 20 to 60 mol %, more preferably 20 to 55 mol %, still more preferably 20 to 50 mol %, and particularly preferably 25 to 45 mol %.

When the amount of the structural unit (a0) is at least as large as the lower limit of the above-mentioned range, thickness loss of the resist film caused during development can be reduced, and various lithography properties (such as sensitivity, roughness and the like) can be improved. On the other hand, when the amount of the structural unit (a0) is no more than the upper limit of the above-mentioned range, a good balance can be achieved with the other structural units, and lithography properties can be improved.

(Structural Unit (a6))

The structural unit (a6) is a structural unit which generates acid upon exposure.

The structural unit (a6) is not particularly limited as long as it generates acid upon exposure. For example, a structural unit copolymerizable with the structural unit (a0) and in which the structure of an acid generator proposed for a conventional chemically amplified resist have been introduced can be used.

Preferable examples of the structural unit copolymerizable with the structural unit (a0) include a structural unit derived from a (meth)acrylate ester and a structural unit derived from hydroxystyrene.

Preferable examples of compounds having a structure of the acid generator for a conventional chemically amplified resist include the component (B) described later.

As the structural unit (a6), a structural unit (a6a) in which an anion group capable of generating acid upon exposure has been introduced on the side chain, or a structural unit (a6c) in which a cation group capable of being decomposed upon exposure has been introduced on the side chain can be mentioned.

—Structural Unit (a6a)

The structural unit (a6a) is a structural unit in which an anion group capable of generating acid upon exposure has been introduced on the side chain.

The anion group capable of generating acid upon exposure is not particularly limited, and a sulfonate anion, an amide anion and a methide anion can be preferably used.

In particular, as the structural unit (a6a), a structural unit having a group represented by general formula (a6a-r-1) shown below, a group represented by general formula (a6a-r-2) shown below or a group represented by general formula (a6a-r-3) shown below can be preferably used.

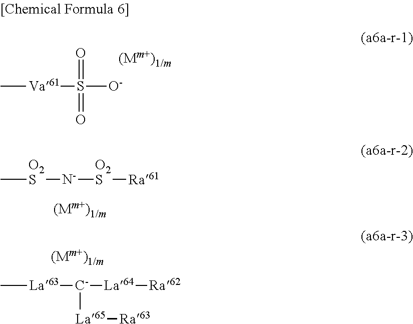

In the formulae, Va′⁶¹ represents a divalent hydrocarbon group containing a fluorine atom; Ra′⁶¹ represents a hydrocarbon group; each of La′⁶³ to La′⁶⁵ independently represents an —SO₂— or a single bond; each of Ra′⁶² to Ra′⁶³ independently represents a hydrocarbon group; m is an integer of 1 or more; and M^{m+} is an organic cation having a valency of m.

In the formula (a6a-r-1), Va′⁶¹ represents a divalent hydrocarbon group containing a fluorine atom.

The divalent hydrocarbon group for Va′⁶¹ may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof can be given.

(Linear or Branched, Unsaturated Aliphatic Hydrocarbon Group)

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂—], a trimethylene group [—(CH₂)₃-], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

Such a linear or branched aliphatic hydrocarbon group has a fluorine atom, and may have part or all of the hydrogen atoms within the aliphatic hydrocarbon group substituted with a fluorine atom. Further, the aliphatic hydrocarbon group may be substituted with an oxo group (═O) in addition to a fluorine atom.

(Aliphatic Hydrocarbon Group Containing a Ring in the Structure Thereof)

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed within a linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic alicyclic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

Such a cyclic aliphatic hydrocarbon group has a fluorine atom, and may have part or all of the hydrogen atoms within the cyclic aliphatic hydrocarbon group substituted with a fluorine atom. Further, the hydrocarbon group may be substituted with a substituent such as an alkyl group, an alkoxy group, a hydroxy group and an oxo group (═O) in addition to a fluorine atom.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

In the cyclic aliphatic hydrocarbon group, part of the carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—

The aromatic hydrocarbon group as the divalent hydrocarbon group for Va′⁶¹ is a hydrocarbon group having at least one aromatic ring.

The aromatic ring is not particularly limited, as long as it is a cyclic conjugated compound having (4n+2) π electrons, and may be either monocyclic or polycyclic. The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic ring. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hetero ring include a pyridine ring and a thiophene ring.

Specific examples of the aromatic hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom has been removed from the aforementioned aromatic hydrocarbon ring or aromatic hetero ring and one hydrogen atom thereof has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and most preferably 1 carbon atom.

Such an aromatic hydrocarbn group has a fluorine atom, and may have all of the hydrogen atoms within the aromatic hydrocarbon group substituted with a fluorine atom. Further, the hydrocarbon group may be substituted with a substituent such as an alkyl group, an alkoxy group, a hydroxy group and an oxo group (═O) in addition to a fluorine atom. The alkyl group and the alkoxy group as a substituent are the same as defined for the alkyl group and the alkoxy group as the substituent for the aforementioned cyclic aliphatic hydrocarbon group.

Among these anion groups represented by the formula (a6a-r-1), a group represented by general formula (a6a-r-11) shown below is preferable.

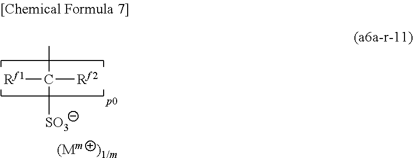

In the formula, each of R^{f1} and R^{f2} independently represent a hydrogen atom, an alkyl group, a fluorine atom or a fluorinated alkyl group, and at least one of R^{f1} and R^{f2} represents a fluorine atom or a fluorinated alkyl group; p0 represented an integer of 1 to 8; m is an integer of 1 or more; and M^{m+} is an organic cation having a valency of m.

In the formula (a6a-r-11), each of R^{f1} and R^{f2} independently represents a hydrogen atom, an alkyl group, a fluorine atom or a fluorinated alkyl group, and at least one of R^{f1} and R^{f2} represents a fluorine atom or a fluorinated alkyl group.

The alkyl group for R^{f1} and R^{f2} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f1} and R^{f2} is preferably a group in which part or all of the hydrogen atoms within the aforementioned alkyl group for R^{f1} and R^{f2} have been substituted with a fluorine atom.

As R^{f1} and R^{f2}, a fluorine atom or a fluorinated alkyl is preferable. In the formula (a6a-r-11), p0 represents an integer of 1 to 8, preferably an integer of 1 to 4, and more preferably 1 or 2.

In the formula (a6a-r-2), as the hydrocarbon group for Ra′⁶¹, an alkyl group, a monovalent alicyclic hydrocarbon group, an aryl group and an aralkyl group can be mentioned.

The alkyl group for Ra′⁶¹ preferably has 1 to 8 carbon atoms, more preferably 1 to 6, and still more preferably 1 to 4, and may be either linear or branched. Specific examples include a methyl group, an ethyl group, a propyl group, a butyl group, a hexyl group and an octyl group.

The monovalent alicyclic hydrocarbon group for Ra′⁶¹ preferably has 3 to 20 carbon atoms and more preferably 3 to 12 carbon atoms, and may be either monocyclic or polycyclic. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic alicyclic hydrocarbon group, a group in which one or more hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

The aryl group for Ra′⁶¹ preferably has 6 to 18 carbon atoms and more preferably 6 to 10 carbon atoms, and a phenyl group is particularly preferable.

Examples of the aralkyl group for Ra′⁶¹ include a group in which an alkylene group of 1 to 8 carbon atoms and the aforementioned “aryl group for Ra′⁶¹” are mutually bonded. An aralkyl group in which an alkylene group of 1 to 6 carbon atoms and the aforementioned “aryl group for Ra′⁶¹” are mutually bonded is preferable, and an aralkyl group in which an alkylene group of 1 to 4 carbon atoms and the aforementioned “aryl group for Ra′⁶¹” are mutually bonded is particularly preferable.

The hydrocarbon group for Ra′⁶¹ is preferably a group in which part or all of the hydrogen atoms within a hydrocarbon group has been substituted with a fluorine atom, and more preferably a group in which 30 to 100% of the hydrogen atoms within a hydrocarbon group have been substituted with fluorine atoms. Among these, a perfluoroalkyl group in which all of the hydrogen atoms within the alkyl group have been substituted with fluorine atoms is particularly preferable.

In the formula (a6a-r-3), each of La′⁶³ to La′⁶⁵ independently represents an —SO₂— or a single bond, and each of Ra′⁶² and Ra′⁶³ independently represents a hydrocarbon group. The hydrocarbon group for Ra′⁶² and Ra′⁶³ is the same as defined for the hydrocarbon group for Ra′⁶¹.

Examples of the structural unit (a6a) include structural units represented by the general formulae (a6a-1) to (a6a-8) shown below.

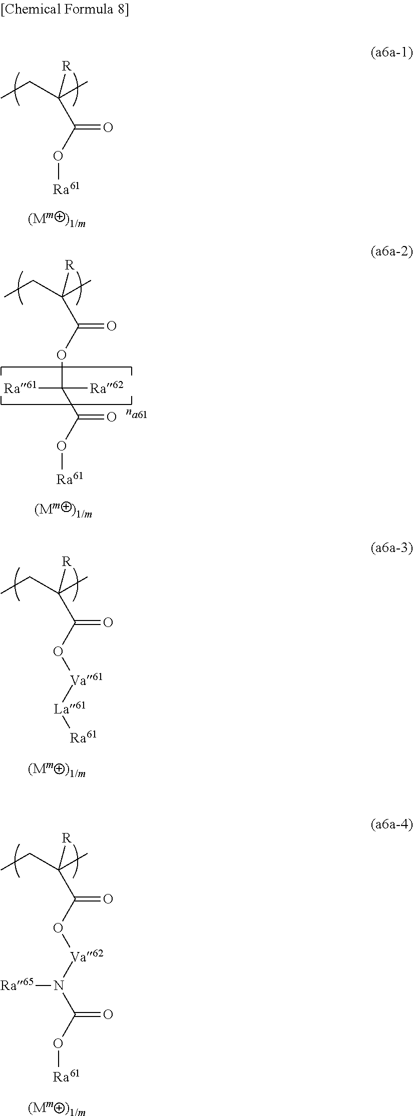

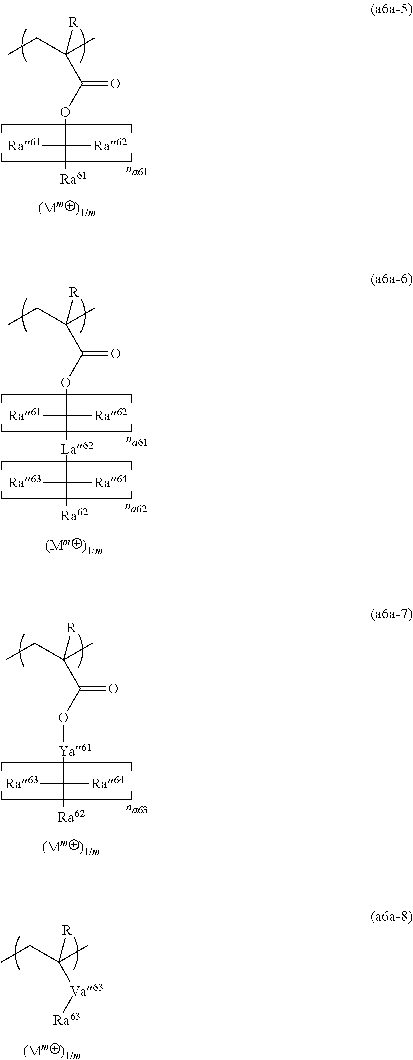

In the formulae, R represents a hydrogen atom, an alkyl group of 1 to 5 carbon atoms or a halogenated alkyl group of 1 to 5 carbon atoms; Ra⁶¹ represents a group represented by the formula (a6a-r-1); Ra⁶² represents a group represented by the formula (a6a-r-2) or (a6a-r-3); Ra⁶³ represents a group represented by the formula (a6a-r-3); each of Ra″⁶¹ to Ra″⁶⁴ independently represents a hydrogen atom, a fluorine atom, an alkyl group of 1 to 5 carbon atoms or a fluorinated alkyl group; each of nₐ₆₁ and nₐ₆₂ independently represents an integer of 1 to 10; nₐ₆₃ represents an integer of 0 to 10;

Va″⁶¹ represents a divalent cyclic hydrocarbon group; La″⁶¹ represents —C(═O)—O—, —O—C(═O)—O— or —O—CH₂—C(═O)—O—; Va″⁶² represents a divalent hydrocarbon group;

Ra″⁶⁵ represents a hydrogen atom or an alkyl group of 1 to 5 carbon atoms; La″⁶² represents —C(═O)—O—, —O—C(═O)—O—, or —NH—C(═O)—O—; Ya″⁶¹ represents a divalent linking group containing a cyclic hydrocarbon group; Va″⁶³ represents a divalent cyclic hydrocarbon group or a single bond; m represents an integer of 1 or more; and M^{m+} each independently represents an organic cation having a valency of m.

In general formulae (a6a-1) to (a6a-8), R is the same as defined for R in general formula (a0-1).

In the formulae (a6a-1) to (a6a-4), Ra⁶¹ each independently represents a group represented by the aforementioned formula (a6a-r-1). In the formulae (a6a-5) to (a6a-7), Ra⁶² each independently represents a group represented by the aforementioned formula (a6a-r-2) or (a6a-r-3). In the formula (a6a-8), Ra⁶³ represents a group represented by the aforementioned formula (a6a-r-3).

In the formulae (a6a-2) and (a6a-5) to (a6a-7), each of Ra″⁶¹ to Ra″⁶⁴ independently represents a hydrogen atom, a fluorine atom, an alkyl group of 1 to 5 carbon atoms or a fluorinated alkyl group. Examples of the fluorinated alkyl group for Ra″⁶¹ to Ra″⁶⁴ include groups in which part or all of the hydrogen atoms within the alkyl group of 1 to 5 carbon atoms has been substituted with a fluorine atom.

In the formulae (a6a-2), (a6a-5) and (a6a-6), each of nₐ₆₁ independently represents an integer of 1 to 10, preferably an integer of 1 to 8, more preferably an integer of 1 to 4, and still more preferably 1 or 2.

In the formula (a6a-6), nₐ₆₂ represents an integer of 1 to 10, more preferably an integer of 1 to 8, still more preferably an integer of 1 to 4, and particularly preferably an integer of 1 or 2.

In the formula (a6a-7), nₐ₆₃ represents an integer of 0 to 10, preferably an integer of 0 to 5, more preferably an integer of 0 to 3, and particularly preferably an integer of 0.

In the formula (a6a-3), Va″⁶¹ represents a divalent cyclic hydrocarbon group, and examples thereof include the same groups as exemplified above for the aliphatic hydrocarbon group containing a ring in the structure thereof and the aromatic hydrocarbon group in the explanation for Va′⁶¹ in the formula (a6a-r-1).

La″⁶¹ represents —C(═O)—O—, —O—C(═O)—O— or —O—CH₂—C(═O)—O—.

In the formula (a6a-4), Va″⁶² represents a divalent hydrocarbon group, and examples thereof include the same groups as exemplified above for the divalent hydrocarbon group in the explanation for Va′⁶¹ in the formula (a6a-r-1).

Ra″⁶⁵ represents a hydrogen atom or an alkyl group of 1 to 5 carbon atoms.

In the formula (a6a-6), La″⁶² represents —C(═O)—O—, —O—C(═O)—O— or —NH—C(═O)—O—.

In the formula (a6a-7), Ya″⁶¹ represents a divalent linking group containing a cyclic hydrocarbon group, and preferable examples thereof include an aliphatic hydrocarbon group containing a ring in the structure thereof, an aromatic hydrocarbon group, and a divalent linking group containing a hetero atom (and containing an aliphatic hydrocarbon group having a ring in the structure thereof or containing an aromatic hydrocarbon group in the structure thereof).

The aliphatic hydrocarbon group containing a ring in the structure thereof and the aromatic hydrocarbon group for Ya″⁶¹ are the same as exemplified above for the aliphatic hydrocarbon group containing a ring in the structure thereof and the aromatic hydrocarbon group in the explanation for Va′⁶¹ in the structure (a6a-r-1).

With respect to the divalent linking group containing a hetero atom (and containing an aliphatic hydrocarbon group having a ring in the structure thereof or containing an aromatic hydrocarbon group in the structure thereof) for Ya″⁶¹, the hetero atom is an atom other than carbon and hydrogen, and examples thereof include an oxygen atom, a nitrogen atom, a sulfur atom and a halogen atom.

Preferable examples of the divalent linking group containing a hetero atom include one type or a combination of at least two type of groups selected from —O—, —C(═O)—O—, —C(═O)—, —O—C(═O)—O—, —C(═O)—NH—, —NH—, NH—C(═NH)— (wherein H may be substituted with a substituent such as an alkyl group or an acyl group), —S—, —S(═O)₂—, —S(═O)₂—O—, —CF₂— and a group represented by general formula —Y⁶¹²—Y⁶¹¹—C(═O)—O—, —[Y⁶¹¹—C(═O)—O]_{m″}—Y⁶¹²—, —Y⁶¹¹—O—C(═O)—Y⁶¹²— or —Y⁶¹¹—S(O)₂—O—Y⁶¹²— [in the formulae, each of Y⁶¹¹ and Y⁶¹² independently represents an aliphatic hydrocarbon group containing a ring in the structure thereof or an aliphatic hydrocarbon group containing an aromatic hydrocarbon group in the structure thereof; O represents an oxygen atom; and m″ represents an integer of 0 to 3].

In the aforementioned formulae, each of Y⁶¹¹ and Y⁶¹² independently represents an aliphatic hydrocarbon group containing a ring in the structure thereof or an aliphatic hydrocarbon group containing an aromatic hydrocarbon group in the structure thereof. The aliphatic hydrocarbon group containing a ring in the structure thereof and the aromatic hydrocarbon group are the same as exemplified above for the aliphatic hydrocarbon group containing a ring in the structure thereof and the aromatic hydrocarbon group in the explanation for Va′⁶¹ in the formula (a6a-r-1).

In the formula (a6a-8), Va″⁶³ represents a divalent cyclic hydrocarbon group or a single bond. The divalent cyclic hydrocarbon group for Va″⁶³ is the same as exemplified above for the aliphatic hydrocarbon group containing a ring in the structure thereof and the aromatic hydrocarbon group in the explanation for Va′⁶¹ in the formula (a6a-r-1).

In the formulae (a6a-r-1), (a6a-r-2), (a6a-r-3), (a6a-r-11) and (a6a-1) to (a6a-8), m represents an integer of 1 or more, M^{m+} each independently represents an organic cation having a valency of m.

The organic cation for M^{m+} is not particularly limited, and an onium cation having a valency of m is preferable. Among these, a sulfonium cation or an iodonium cation is more preferable, and organic cations represented by general formulae (ca-1) to (ca-4) shown below are particularly preferable.

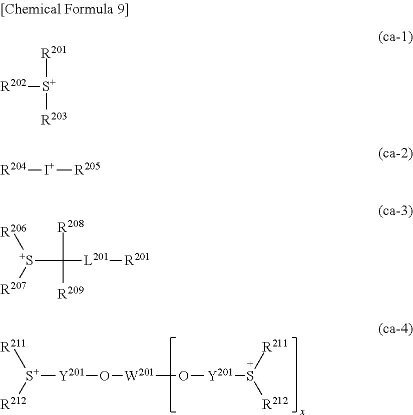

In the formulae, each of R²⁰¹ to R²⁰⁷, R²¹¹ and R²¹² independently represents an aryl group which may have a substituent, an alkyl group which may have a substituent or an alkenyl group which may have a substituent; R²⁰¹ to R²⁰³, R²⁰⁶ and R²⁰⁷ and R²¹¹ and R²¹² may be mutually bonded to form a ring with the sulfur atom; R²⁰⁸ and R²⁰⁹ each represents a hydrogen atom or an alkyl group of 1 to 5 carbon atoms; R²¹⁰ represents an aryl group which may have a substituent, an alkyl group which may have a substituent, an alkenyl group which may have a substituent or an —SO₂— containing cyclic group which may have a substituent; L²⁰¹ represents —C(═O)— or —C(═O)—O—; Y²⁰¹ each independently represents an arylene group, an alkylene group or an alkenylene group; x represents 1 or 2; and W²⁰¹ represents a linking group having a valency of (x+1).

As the aryl group for R²⁰¹ to R²⁰⁷, R²¹¹ and R²¹², an unsubstituted aryl group of 6 to 20 carbon atoms can be mentioned, and a phenyl group or a naphthyl group is preferable.

As the alkyl group for R²⁰¹ to R²⁰⁷, R²¹¹ and R²¹², a chain-like or cyclic alkyl group of 1 to 30 carbon atoms is preferable.

The alkenyl group for R²⁰¹ to R²⁰⁷, R²¹¹ and R²¹² preferably has 2 to 10 carbon atoms.

Specific examples of the substituent which R²⁰¹ to R²⁰⁷, and R²¹⁰ to and R²¹² may have include an alkyl group, a halogen atom, a halogenated alkyl group, a carbonyl group, a cyano group, an amino group, an aryl group and groups represented by formulae (a6a-r-1) to (ca-r-7) shown below.

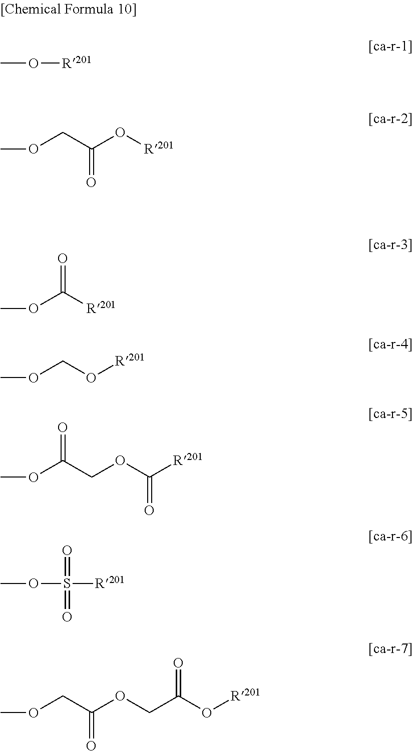

In the formulae, R′²⁰¹ each independently represents a hydrogen atom, a cyclic group which may have a substituent, a chain-like alkyl group which may have a substituent or a chain-like alkenyl group which may have a substituent.

As the cyclic group which may have a substituent, the chain-like alkyl group which may have a substituent and the chain-like alkenyl group which may have a substituent for R′²⁰¹, the same groups as those for R¹⁰¹ in formula (b-1) described later can be mentioned. As the cyclic group which may have a substituent and chain-like alkyl group which may have a substituent, the same groups as those described above for the acid dissociable group represented by the aforementioned formula (a6a-r-2) can be also mentioned.

When R²⁰¹ to R²⁰³, R²⁰⁶ and R²⁰⁷, and R²¹¹ and R²¹² are mutually bonded to form a ring with the sulfur atom, these groups may be mutually bonded via a hetero atom such as a sulfur atom, an oxygen atom or a nitrogen atom, or a functional group such as a carbonyl group, —SO—, —SO₂—, —SO₃—, —COO—, —CONH— or —N(R_{N})— (wherein R_{N} represents an alkyl group of 1 to 5 carbon atoms). As the ring to be formed, the ring containing the sulfur atom in the skeleton thereof is preferably a 3 to 10-membered ring, and particularly preferably a 5 to 7-membered ring. Examples of the formed ring include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring and a tetrahydrothiopyranium ring.

R²⁰⁸ and R²⁰⁹ each independently represents a hydrogen atom or an alkyl group of 1 to 5 carbon atoms, is preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

R²¹⁰ represents an aryl group which may have a substituent, an alkyl group which may have a substituent, an alkenyl group which may have a substituent or an —SO₂— containing cyclic group which may have a substituent.

As the aryl group for R²¹⁰, an unsubstituted aryl group of 6 to 20 carbon atoms can be mentioned, and a phenyl group or a naphthyl group is preferable.

As the alkyl group for R²¹⁰, a chain-like or cyclic alkyl group of 1 to 30 carbon atoms is preferable.

The alkenyl group for R²¹⁰ preferably has 2 to 10 carbon atoms.

As the —SO₂— containing cyclic group for R²¹⁰ which may have a substituent, the same groups as the “—SO₂— containing cyclic group” for Ra²¹ in general formula (a2-1) described later can be mentioned, and the group represented by general formula (a6a-r-1) described later is preferable.

Y²⁰¹ each independently represents an arylene group, an alkylene group or an alkenylene group.

As the arylene group for Y²⁰¹, a group in which one hydrogen atom has been removed from an aryl group exemplified as an aromatic hydrocarbon group for R¹⁰¹ in formula (b-1) described later can be mentioned.

As the alkylene group and the alkenylene group for Y²⁰¹, the same aliphatic hydrocarbon group as the divalent hydrocarbon group for Va¹ in general formula (a1-1) described later can be mentioned.

In the formula (ca-4), x represents 1 or 2.

W²⁰¹ represents a linking group having a valency of (x+1), that is, a divalent or trivalent linking group.

As the divalent linking group for W²⁰¹, a divalent hydrocarbon groups which may have a substituent is preferable, and as examples thereof, the same groups as the hydrocarbon group for Ya²¹ in general formula (a2-1) described later can be mentioned. The divalent linking group for W²⁰¹ may be linear, branched or cyclic, and cyclic is more preferable. Among these, an arylene group having two carbonyl groups, each bonded to the terminal thereof is preferable. As the arylene group, a phenylene group and a naphthylene group can be mentioned. Of these, a phenylene group is particularly desirable.

As the trivalent linking group for W²⁰¹, a group in which one hydrogen atom has been removed from the aforementioned divalent linking group for W²⁰¹, and a group in which the divalent linking group has been bonded to an another divalent linking group can be mentioned. The trivalent linking group for W²⁰¹ is preferably an arylene group having two carbonyl groups bonded thereto.

Specific examples of preferable cations represented by formula (ca-1) include cations represented by formulae (ca-1-1) to (ca-1-67) shown below.

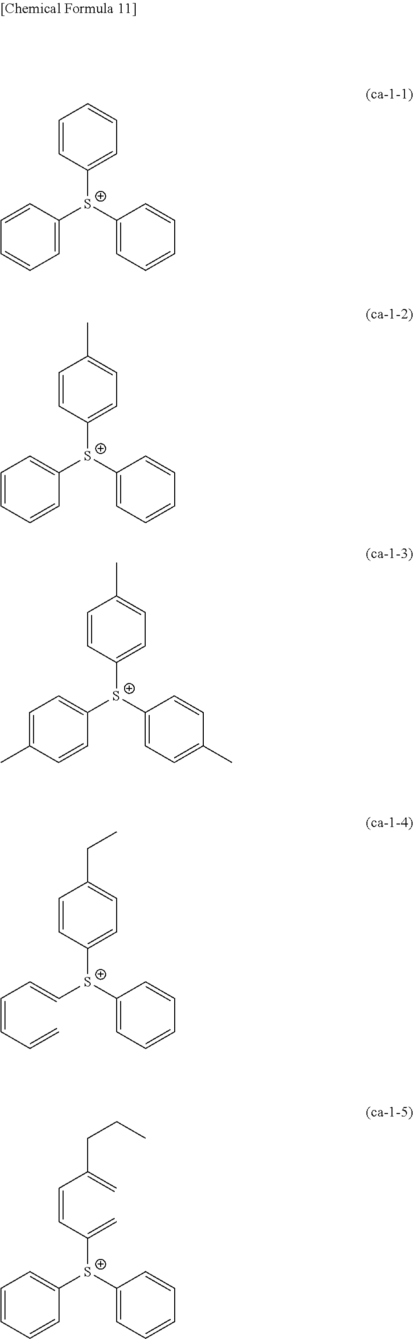

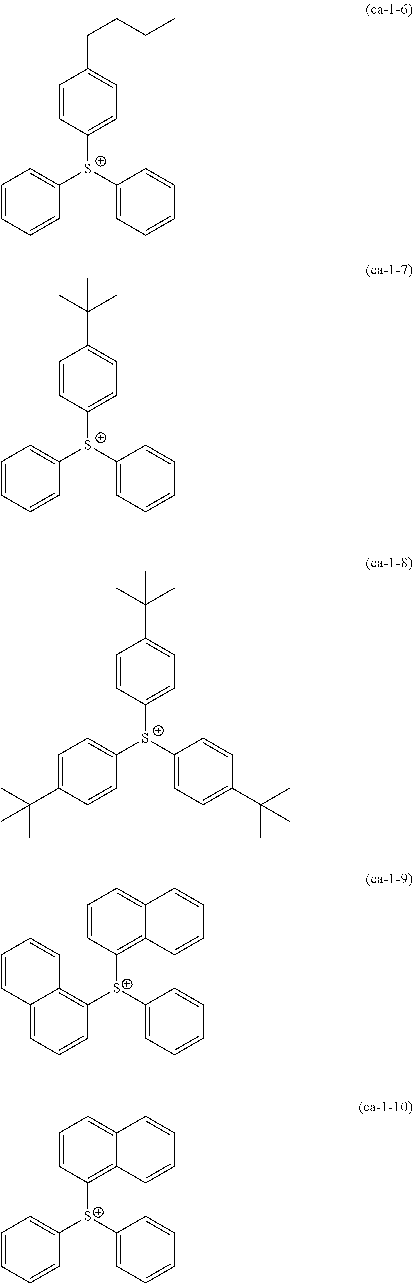

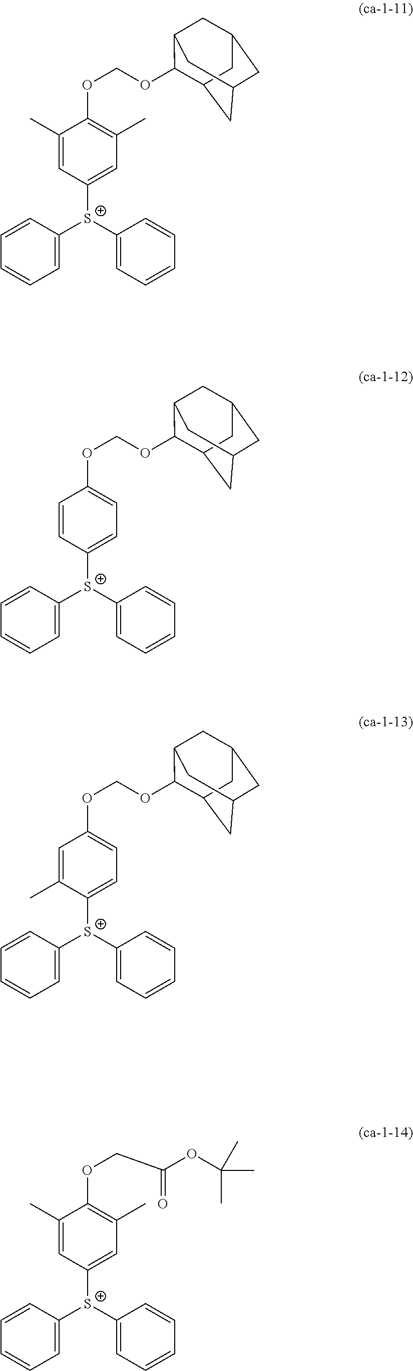

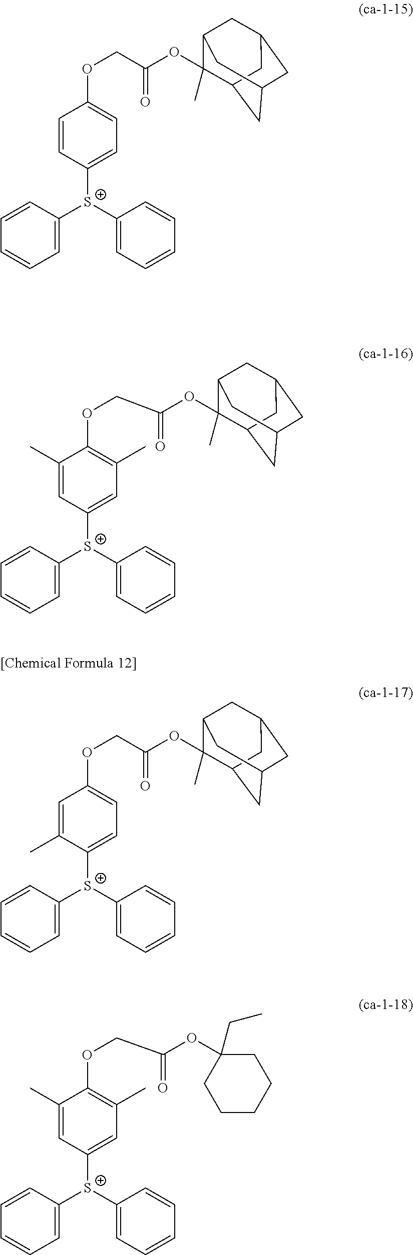

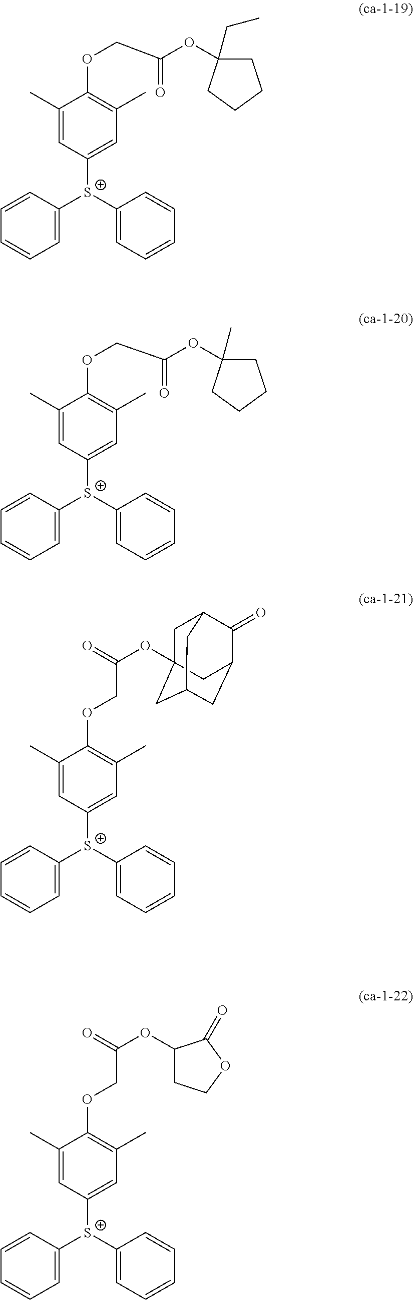

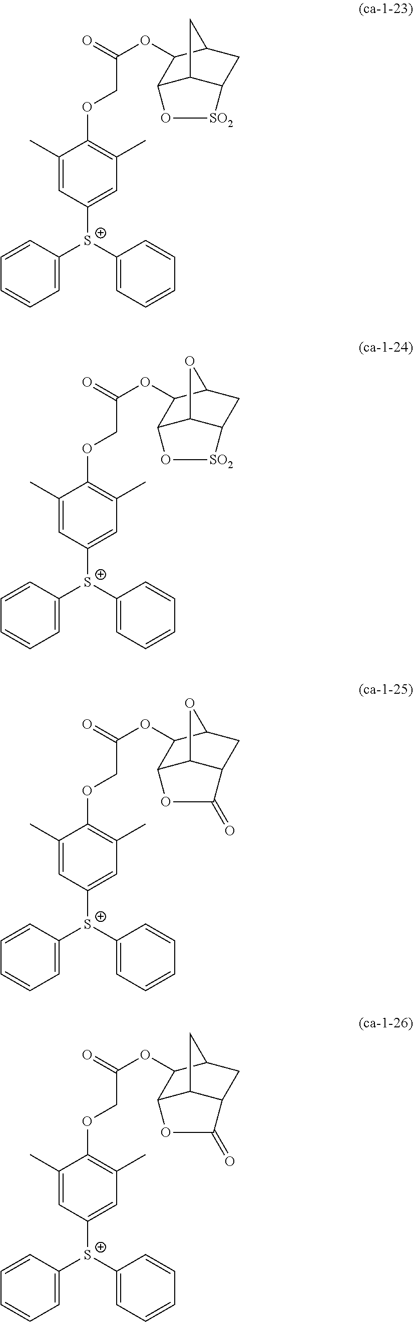

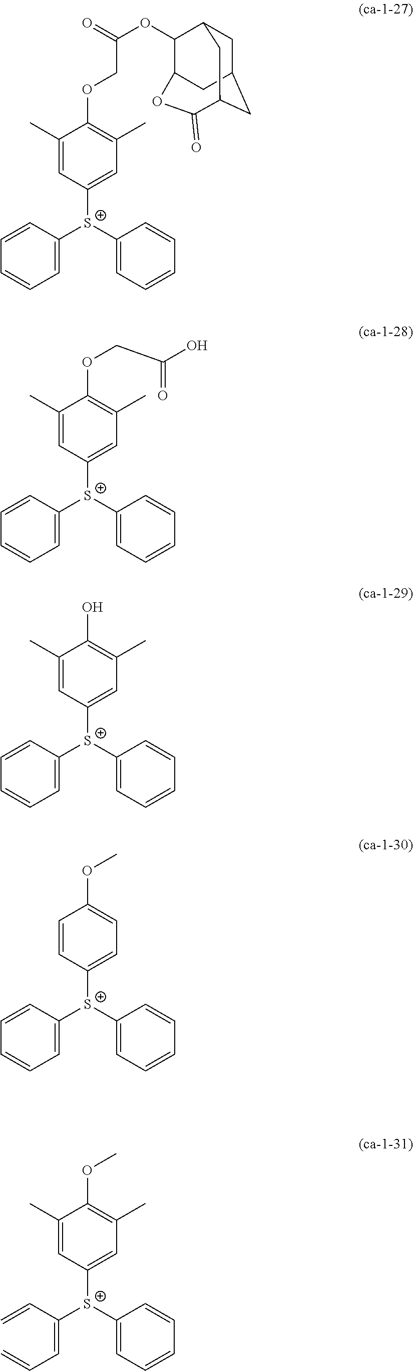

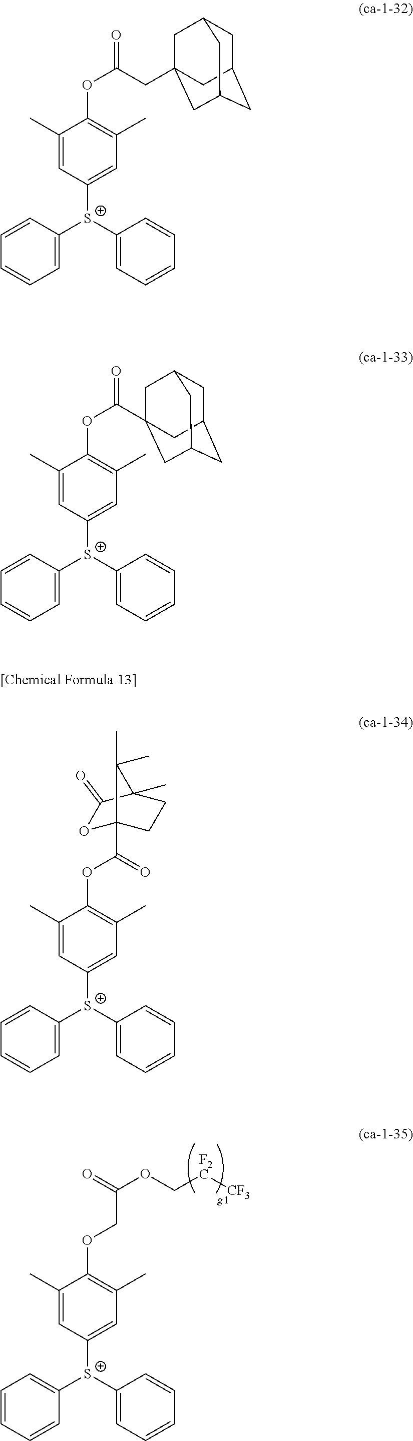

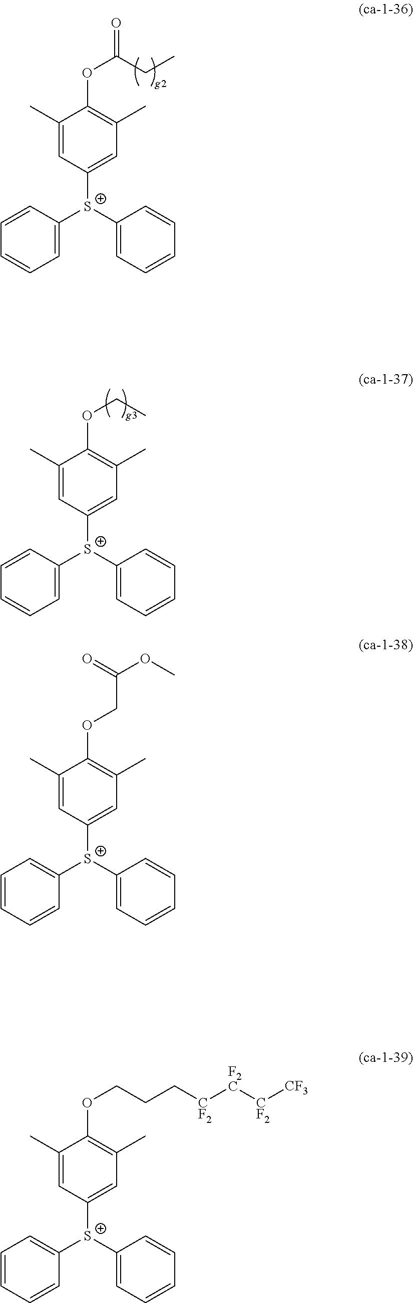

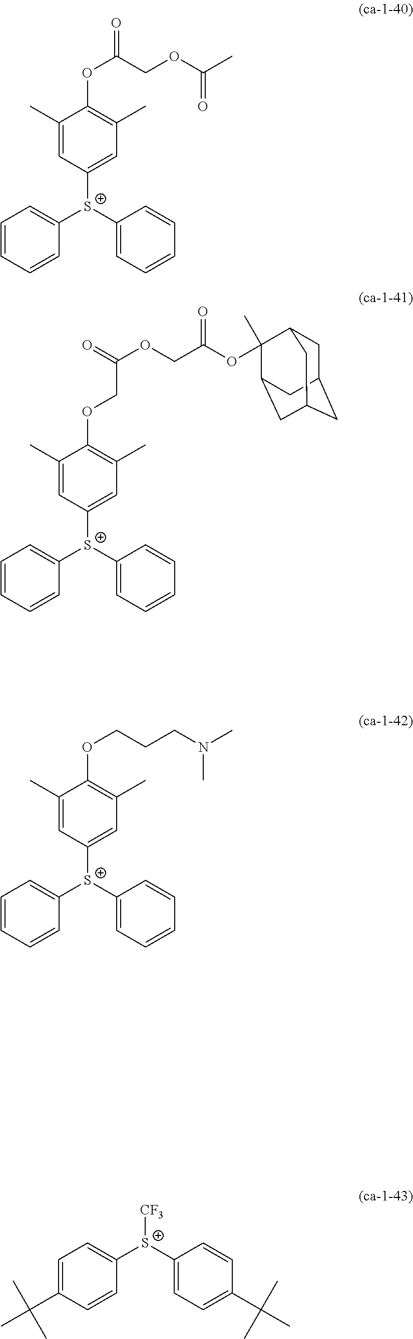

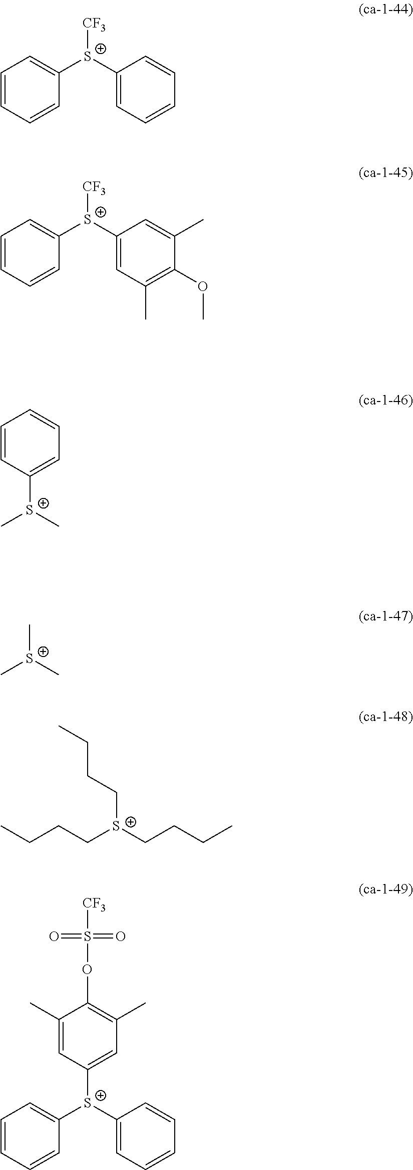

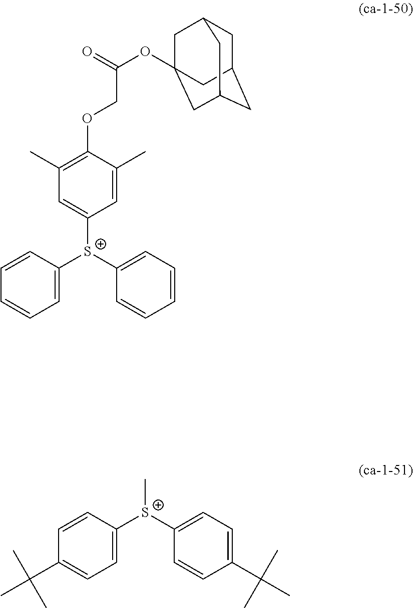

In the formulae, g1, g2 and g3 represent recurring numbers, wherein g1 is an integer of 1 to 5, g2 is an integer of 0 to 20, and g3 is an integer of 0 to 20.

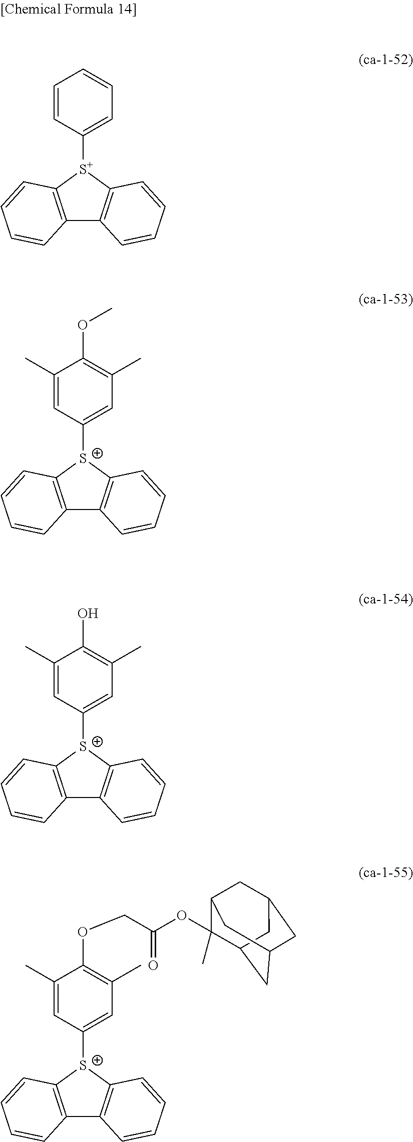

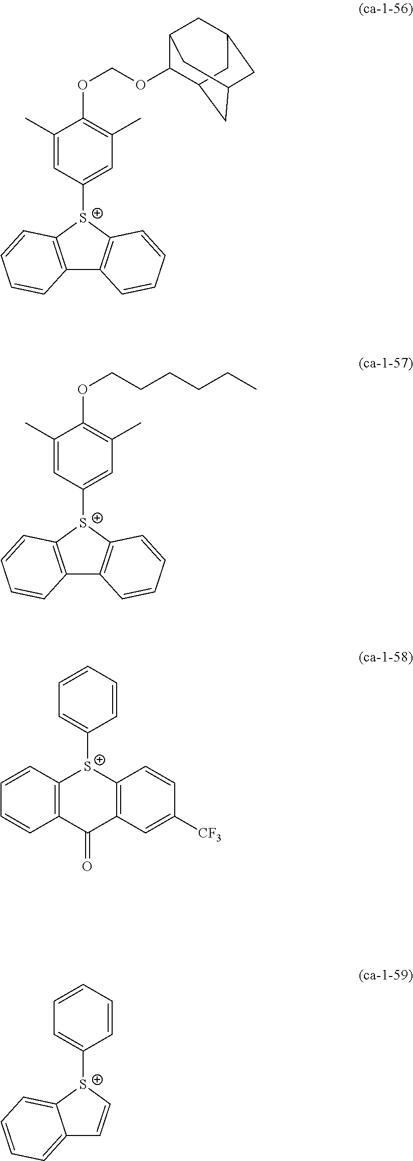

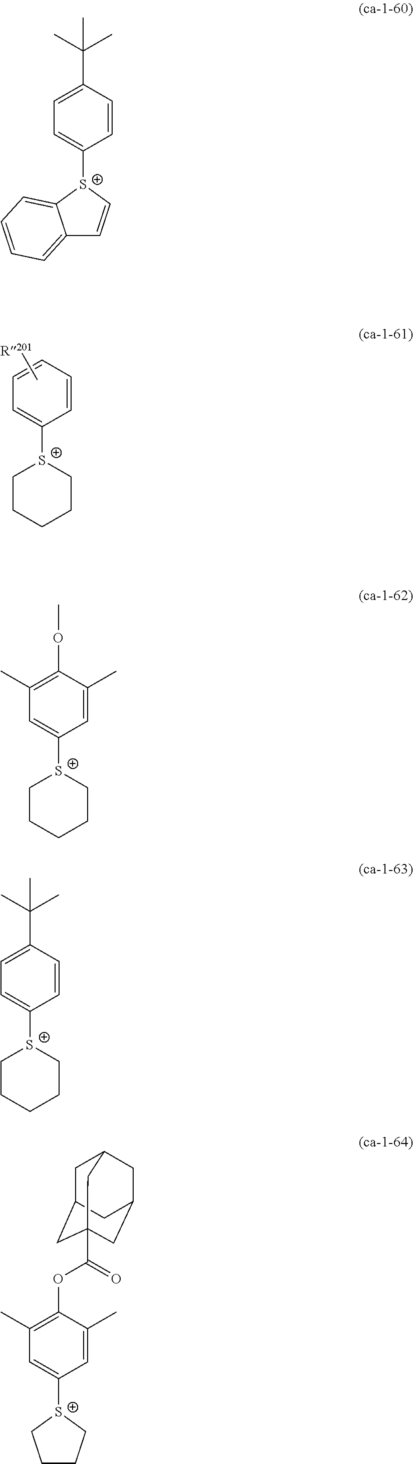

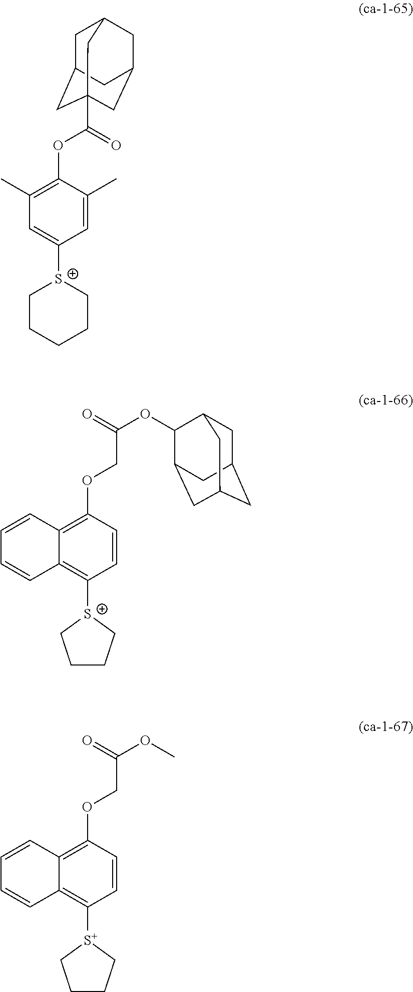

In the formulae, R″²⁰¹ represents a hydrogen atom or a substituent, and as the substituent, the same groups as those described above for substituting the R²⁰¹ to R²⁰⁷ and R²¹⁰ to R²¹² can be mentioned.

Specific examples of preferable cations represented by the formula (ca-2) include diphenyliodonium cation and bis(4-tert-butylphenyl)iodonium cation.

Specific examples of preferable cations represented by the formula (ca-3) include cations represented by formulae (ca-3-1) to (ca-3-6) shown below.

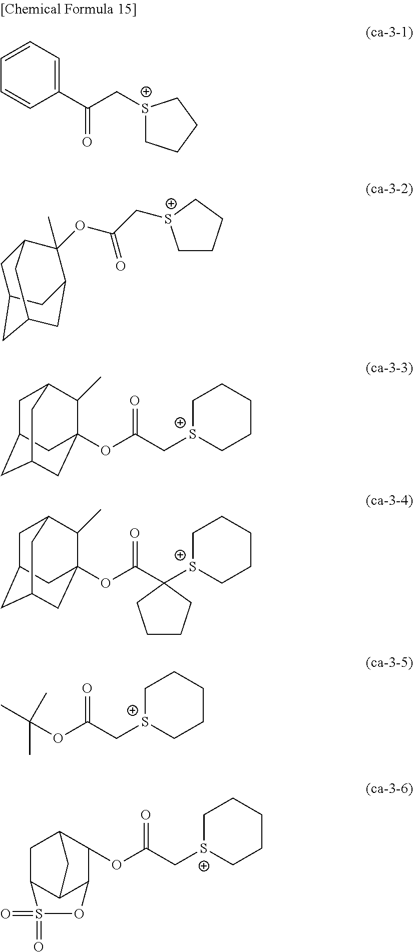 [SMILES: O=C(C[S+]1CCCC1)c1ccccc1 ; CC1(OC(=O)C[S+]2CCCC2)C2CC3CC(C2)CC1C3 ; CC1C2CC3CC(C2)CC1(OC(=O)C[S+]1CCCCC1)C3 ; CC1C2CC3CC(C2)CC1(OC(=O)C1([S+]2CCCCC2)CCCC1)C3 ; CC(C)(C)OC(=O)C[S+]1CCCCC1 ; O=C(C[S+]1CCCCC1)OC1C2CC3C1OS(=O)(=O)C3C2]

Specific examples of preferable cations represented by formula (ca-4) include cations represented by formulae (ca-4-1) to (ca-4-2) shown below.

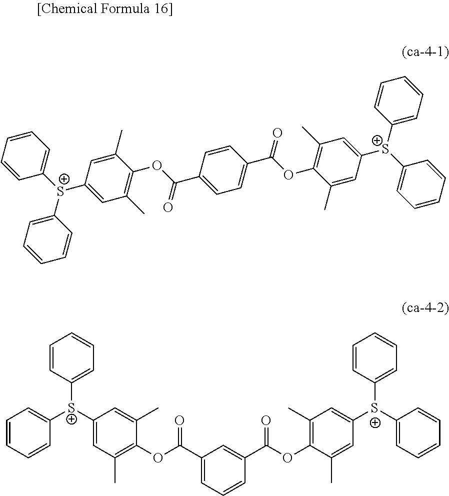 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Among these, as the cation moiety [(M^{m+})_{1/m}], a cation moiety represented by general formula (ca-1-1) is preferable, and cation moieties represented by formulae (ca-1-1) to (ca-1-67) are more preferable.

Specific examples of structural units represented by the general formula (a6a-1) are shown below. R^{α} and (M^{m+})_{1/m} are the same as defined above.

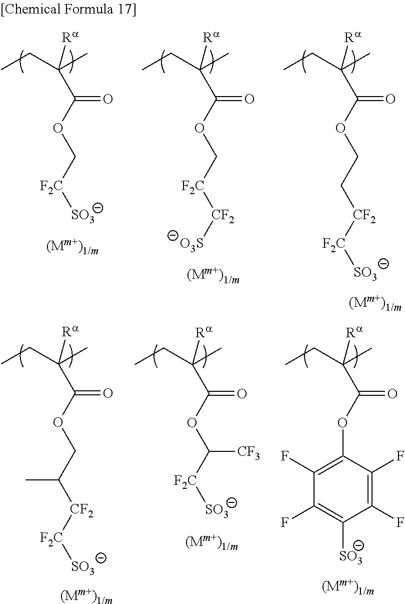

Specific examples of structural units represented by the general formula (a6a-2) are shown below. R^{α} and (M^{m+})_{1/m} are the same as defined above.

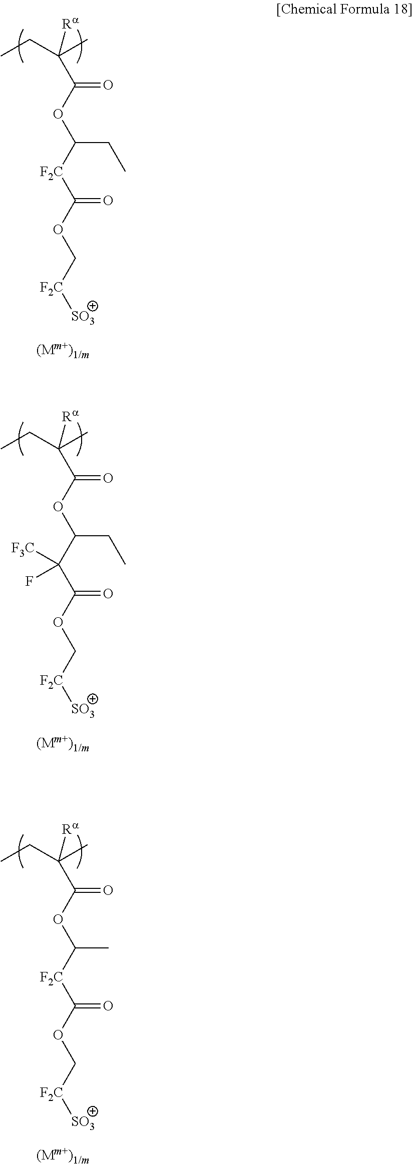

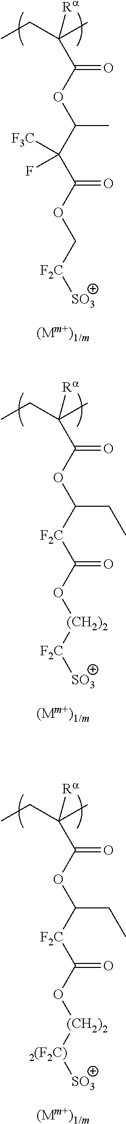

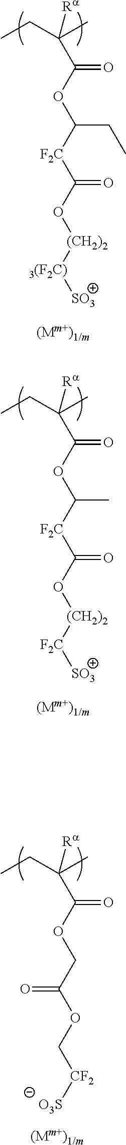

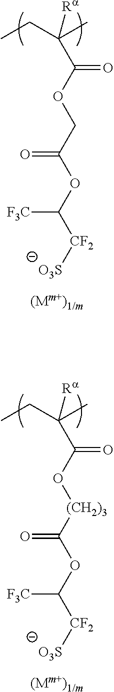

Specific examples of structural units represented by the general formula (a6a-3) are shown below. R^{α} and (M^{m+})_{1/m} are the same as defined above.

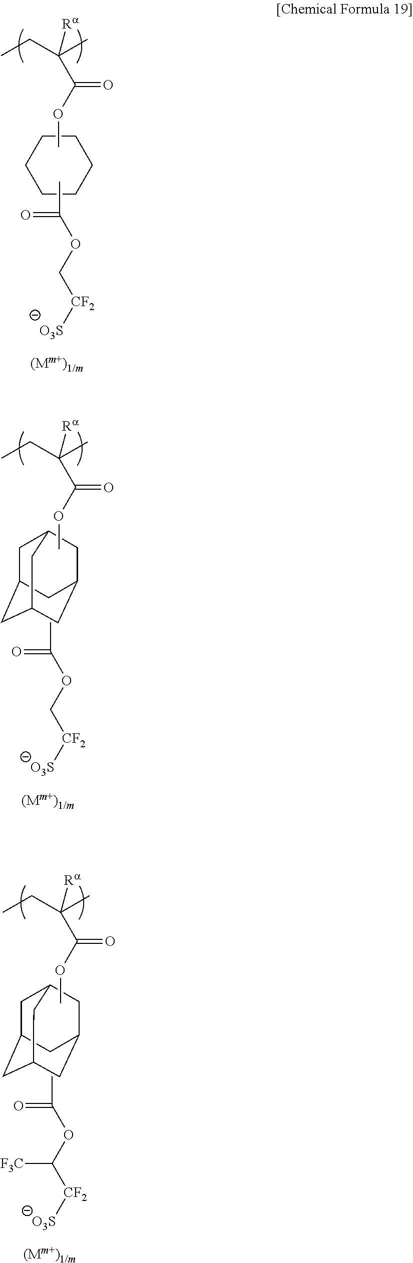

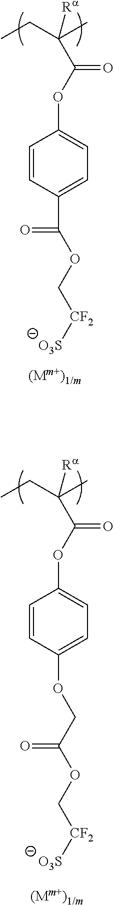

Specific examples of structural units represented by the general formula (a6a-4) are shown below. R^{α} and (M^{m+})_{1/m} are the same as defined above.

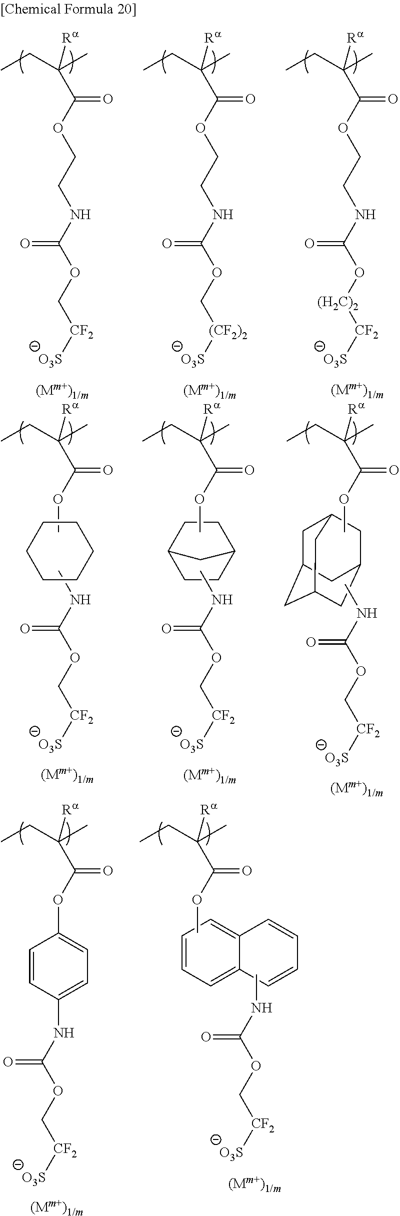

Specific examples of structural units represented by the general formula (a6a-5) are shown below. R^{α} and (M^{m+})_{1/m} are the same as defined above.

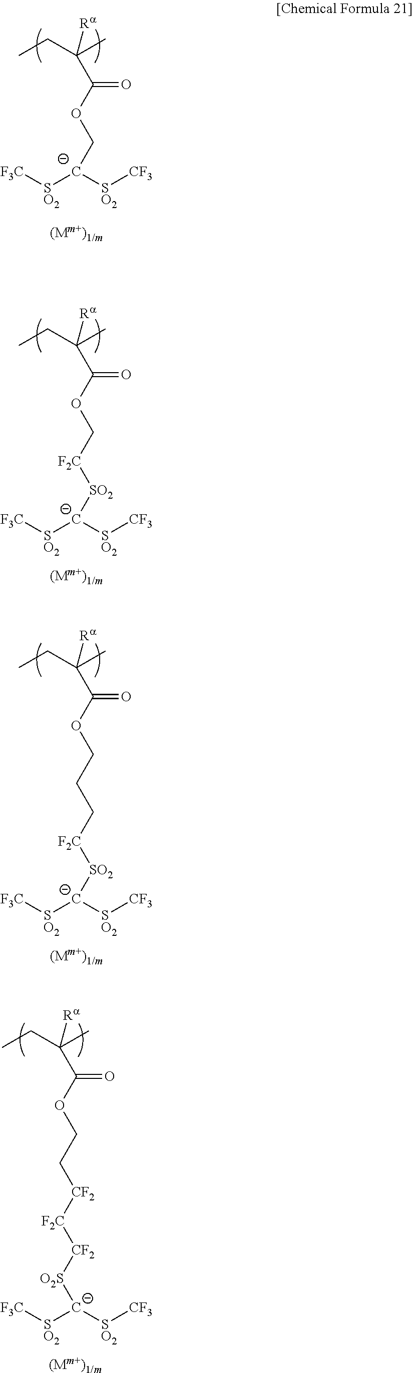

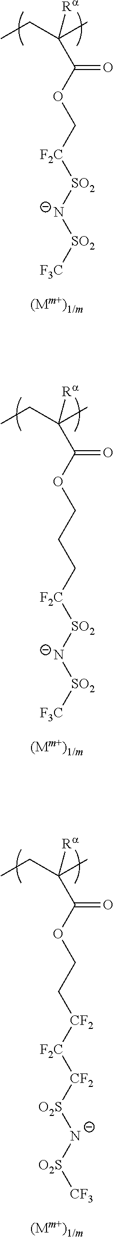

Specific examples of structural units represented by the general formula (a6a-6) are shown below. R^{α} and (M^{m+})_{1/m} the same as defined above.

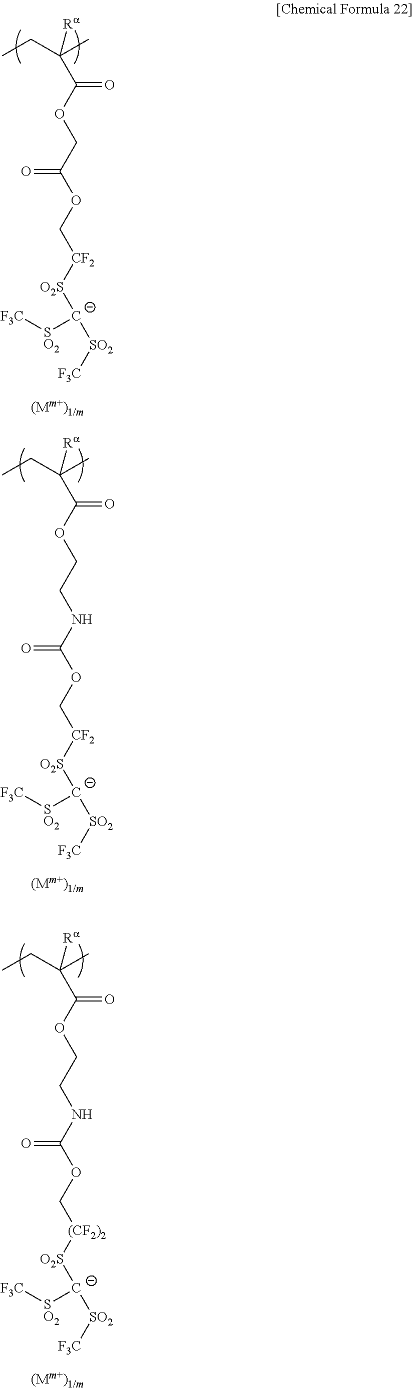

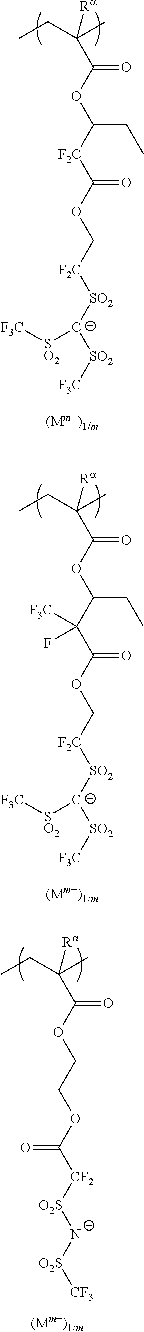

Specific examples of structural units represented by the general formula (a6a-7) are shown below. R^{α} and (M^{m+})_{1/m} are the same as defined above.

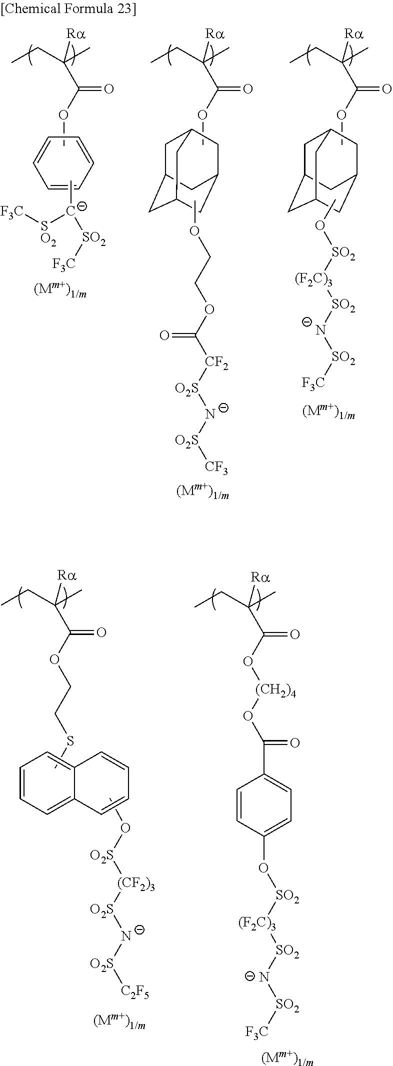

Specific examples of structural units represented by the general formula (a6a-8) are shown below. R^{α} and (M^{m+})_{1/m} are the same as defined above.

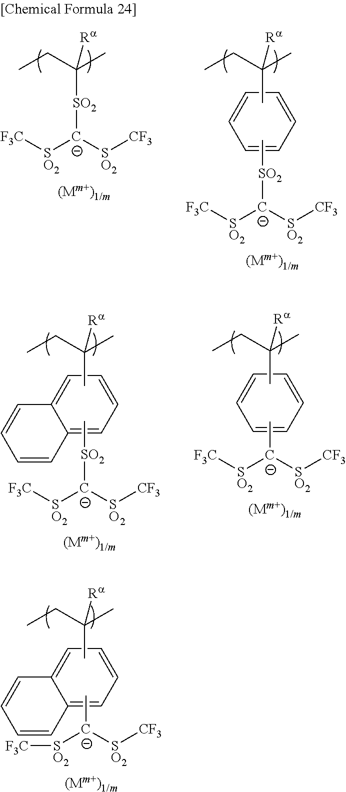

—Structural Unit (a6c)

The structural unit (a6c) is a structural unit having a cation group capable of being decomposed upon exposure on the side chain.

The cation group capable of being decomposed upon exposure is not particularly limited, and a group represented by general formula (a6c-r-1) shown below is preferable.

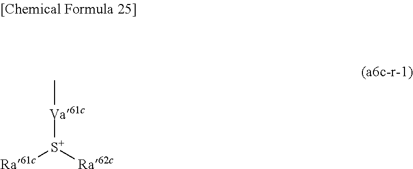

In the formula, each of Ra′^{61c} and Ra′^{62c} independently represents an aryl group which may have a substituent, an alkyl group which may have a substituent or an alkenyl group which may have a substituent; Va′^{61c} represents an arylene group, an alkylene group or an alkenylene group, provided that, Ra′^{61c}, Ra′^{62c} and Va′^{61c} may be mutually bonded to form a ring with the sulfur atom.

In the formula (a6c-r-1), each of R′^{61c} and Ra′^{62c} independently represents an aryl group which may have a substituent, an alkyl group which may have a substituent or an alkenyl group which may have a substituent. As Ra′^{61c} and Ra′^{62c}, the same groups as defined above for the aryl group which may have a substituent, the alkyl group which may have a substituent or the alkenyl group which may have a substituent represented by R²⁰¹ an to R²⁰³ in the formula (ca-1) can be mentioned.

Va′^{61c} represents an arylene group, an alkylene group or an alkenylene group, and examples thereof include a group in which one hydrogen atom has been removed from the aryl group, the alkyl group or the alkenyl group for Ra′^{61c} and Ra′^{62c},

provided that, Ra′^{61c}, Ra′^{62c} and Va′^{61c} may be mutually bonded to form a ring with the sulfur atom. The ring structure to be formed is a group in which one hydrogen atom has been removed from the ring, the ring is formed by R²⁰¹ to R²⁰³ in the formula (ca-1) bonded together with the sulfur atom.

Examples of the structural unit (a6c) include structural units represented by the general formulae (a6c-1) to (a6c-3) shown below.

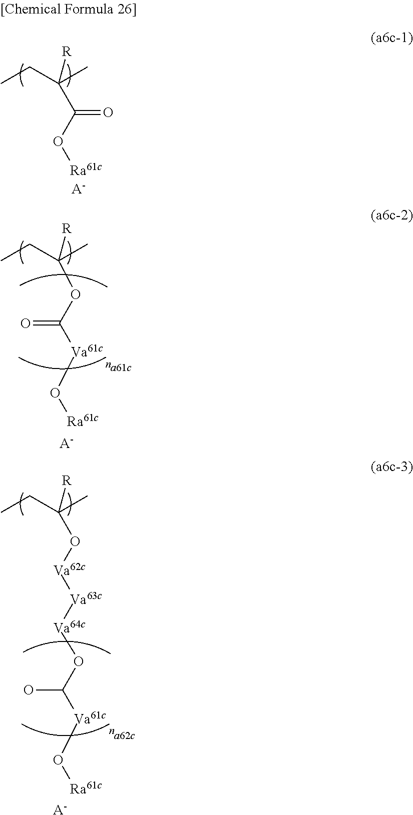

In the formulae, R represents a hydrogen atom, an alkyl group of 1 to 5 carbon atoms or a halogenated alkyl group of 1 to 5 carbon atoms; Va^{61c} each independently represents an alkylene group of 1 to 5 carbon atoms; each of Va^{62c} and Va^{64c} independently represents an alkylene group of 1 to 10 carbon atoms; Va^{63c} represents an aliphatic cyclic group or a single bond; na^{61c} represents an integer of 0 to 2; na^{62c} represents 0 or 1; Ra^{61c} is a group represented by the aforementioned formula (a6c-r-1); and A⁻ represents a counteranion.

In general formulae (a6c-1) to (a6c-3), R is the same as defined for R in general formula (a0-1). Ra^{61c} each independently represents a group represented by the aforementioned formula (a6c-r-1).

In the formulae (a6c-2) and (a6c-3), Va^{61c} each independently represents an alkylene group of 1 to 5 carbon atoms, and is preferably an alkylene group of 1 to 3 carbon atoms, and more preferably a methylene group.

In the formula (a6c-3), Va^{62c} and Va^{64c} each represents an alkylene group of 1 to 10 carbon atoms, preferably an alkylene group of 1 to 8 carbon atoms, more preferably an alkylene group of 1 to 5 carbon atoms, and still more preferably an alkylene group of 1 to 3 carbon atoms.

In the formula (a6c-3), Va^{63c} represents an aliphatic cyclic group or a single bond. The aliphatic cyclic group for Va^{63c} is the same as exemplified above for the aliphatic cyclic groups in the explanation for Va″⁶¹ in the formula (a6a-r-1).
na^{61c} represents an integer of 0 to 2, and preferably 1 or 2.

na^{62c} represents 0 or 1.

In the formulae (a6c-1) to (a6c-3), A⁻ represents a counteranion.

The counteranion for A⁻ is not particularly limited, and examples thereof include an anion moiety (R⁴″SO₃⁻) of the onium salt-based acid generator represented by general formula (b-1) or (b-2) described later in the explanation of the component (B), and an anion moiety represented by general formula (b-3) or (b-4). In particular, the counteranion is preferably R⁴″SO₃⁻, and more preferably a fluorinated alkylsulfonate ion of 1 to 8 carbon atoms (preferably 1 to 4 carbon atoms) or at least one member selected from those represented by general formulae (an-1) to (an-3) described later.

Specific examples of the group represented by the formulae (a6c-1), (a6c-2) or (a6c-3) are shown below. A⁻ is the same as defined above.

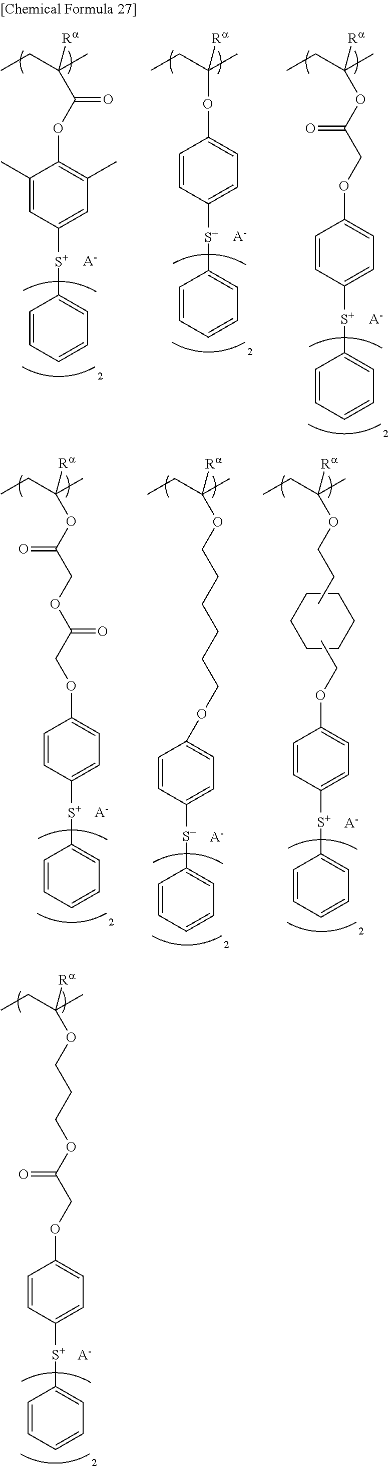

As the structural unit (a6) contained in the component (A1), 1 type of structural unit may be used, or 2 or more types may be used.

As the structural unit (a6a), a structural unit represented by general formula (a6a-1) or (a6a-2) is preferable. As the structural unit (a6c), a structural unit represented by general formula (a6c-1) is preferable.

Among these, as the structural unit (a6), the structural unit (a6a) is particularly desirable.

The amount of the structural unit (a6) within the component (A1) based on the combined total of all structural units constituting the component (A1) is preferably 5 to 35 mol %, more preferably 10 to 30 mol %, and particularly more preferably 10 to 25 mol %.

When the amount of the structural unit (a6) is at least as large as the lower limit of the above-mentioned range, roughness can be reduced, and a resist pattern having an excellent shape can be obtained. On the other hand, when the amount of the structural unit (a6) is no more than the upper limit of the above-mentioned range, a good balance can be achieved with the other structural units, and lithography properties can be improved.

(Other Structural Units)

The component (A1) may further include a structural unit other than the structural units (a0) and (a6), as well as the structural units (a0) and (a6).

As the other structural unit, any other structural unit which cannot be classified as the aforementioned structural units can be used without any particular limitation, and any of the multitude of conventional structural units used within resist resins for ArF excimer lasers or KrF excimer lasers (and particularly for ArF excimer lasers) can be used. For example, a structural units (a1) to (a4) and a structural unit (a10) shown below can be used.

—Structural Unit (a1):

The structural unit (a1) is a structural unit containing an acid decomposable group that exhibits increased polarity by the action of acid, and which does not fall under the definition of the structural unit (a0).

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of acid to form a polar group.

Examples of the polar group include a carboxy group, a hydroxy group, an amino group and a sulfo group (—SO₃H). Among these, a polar group containing —OH in the structure thereof (hereafter, frequently referred to as “OH-containing polar group”) is preferable, a carboxy group or a hydroxy group is more preferable, and a carboxy group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

Here, the “acid dissociable group” is (i) a group in which the bond between the acid dissociable group and the adjacent atom is cleaved by the action of acid; and (ii) a group in which one of the bonds is cleaved by the action of acid, or then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in an alkali developing solution changes, and the solubility in an alkali developing solution is relatively increased, whereas the solubility in an organic developing solution is relatively decreased.

The acid dissociable group is not particularly limited, and any of the groups that have been conventionally proposed as acid dissociable groups for the base resins of chemically amplified resists can be used.

Examples of the acid dissociable group for protecting the carboxy group or hydroxy group as a polar group include the acid dissociable group represented by general formula (a1-r-1) shown below (hereafter, referred to as “acetal-type acid dissociable group”).

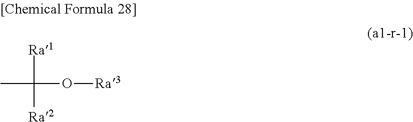

In the formula, Ra′¹ and Ra′² represents a hydrogen atom or an alkyl group; and Ra′³ represents a hydrocarbon group, provided that Ra′³ may be bonded to Ra′¹ or Ra′² to form a ring.

In the formula (a1-r-1), it is preferable that at least one of Ra′¹ and Ra′² represents a hydrogen atom, and it is more preferable that both of Ra′¹ and Ra′² represent a hydrogen atom.

In the case where Ra′¹ or Ra′² is an alkyl group, as the alkyl group, the same alkyl groups as those described above the for the substituent which may be bonded to the carbon atom on the α-position of the aforementioned α-substituted acrylate can be mentioned, and an alkyl group of 1 to 5 carbon atoms is preferable. Specific examples thereof include a linear or branched alkyl group. Specific examples of the linear or branched alkyl group include a methyl group, an ethyl group, a propyl group, an isopropyl group, an n-butyl group, an isobutyl group, a tert-butyl group, a pentyl group, an isopentyl group and a neopentyl group. Of these, a methyl group or an ethyl group is preferable, and a methyl group is particularly preferable.

In the formula (a1-r-1), examples of the hydrocarbon group for Ra′³ include a linear or branched alkyl group or a cyclic hydrocarbon group.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group, a neopentyl group, a 1,1-diethylpropyl group and a 2,2-dimethylbutyl group, and an isopropyl group is desirable.

When Ra′³ is a cyclic hydrocarbon group, the hydrocarbon group may be either an aliphatic group or an aromatic group, and may be either a polycyclic group or a monocyclic group.

As the monocyclic alicyclic hydrocarbon group, a group in which one hydrogen atom has been removed from a monocycloalkane is preferable. The monocycloalkane preferably has 3 to 6 carbon atoms, and specific examples thereof include cyclopentane and cyclohexane.

As the polycyclic alicyclic hydrocarbon group, a group in which one hydrogen atom has been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

When the cyclic hydrocarbon group for Ra′³ is an aromatic hydrocarbon group, examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which one hydrogen atom has been removed from the aforementioned aromatic hydrocarbon ring (aryl group); and a group in which one hydrogen atom of the aforementioned aryl group has been substituted with an alkylene group (an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atoms, more preferably 1 or 2, and most preferably 1.

In the case where Ra′³ is bonded to Ra′¹ or Ra′² to form a ring, the cyclic group is preferably a 4 to 7-membered ring, and more preferably a 4 to 6-membered ring. Specific examples of the cyclic group include tetrahydropyranyl group and tetrahydrofuranyl group.

Examples of the acid dissociable group for protecting the carboxy group as a polar group include the acid dissociable group represented by general formula (a1-r-2) shown below. Hereafter, with respect to the acid dissociable group represented by the following formula (a1-r-2), the acid dissociable group constituted of alkyl groups is referred to as “tertiary ester-type acid dissociable group”.

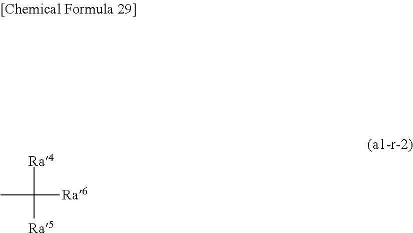

In the formula, Ra′⁴ to Ra′⁶ each independently represents a hydrocarbon group, provided that Ra′⁵ and Ra′⁶ may be mutually bonded to form a ring.

As the hydrocarbon group for Ra′⁴ to Ra′⁶, the same groups as those described above for Ra′³ can be mentioned.

Ra′⁴ is preferably an alkyl group of 1 to 5 carbon atoms. In the case where Ra′⁵ and Ra′⁶ are mutually bonded to form a ring, a group represented by general formula (a1-r2-1) shown below. On the other hand, in the case where Ra′⁴ to Ra′⁶ are not mutually bonded and independently represent a hydrocarbon group, the group represented by general formula (a1-r2-2) shown below can be mentioned.

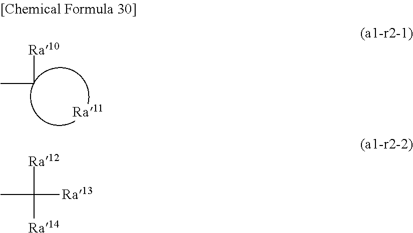

In the formulae, Ra′¹⁰ represents an alkyl group of 1 to 10 carbon atoms; Ra′¹¹ is a group which forms an aliphatic cyclic group together with a carbon atom having Ra′¹ thereto; and Ra′¹² to Ra′¹⁴ each independently represents a hydrocarbon group.

In the formula (a1-r-1), as the alkyl group of 1 to 10 carbon atoms for Ra′¹⁰, the same groups as described above for the linear or branched alkyl group for Ra′³ in the formula (a1-r-1) are preferable. In the formula (a1-r2-1), as the aliphatic cyclic group which is formed by Ra′¹¹ and the carbon group having Ra′¹⁰ bonded thereto, the same groups as those described above for the cyclic alkyl group for Ra′³ in the formula (a1-r-1) are preferable.

In the formula (a1-r2-2), it is preferable that Ra′¹² and Ra′¹⁴ each independently represents an alkyl group or 1 to 10 carbon atoms, and it is more preferable that the alkyl group is the same group as the described above for the linear or branched alkyl group for Ra′³ in the formula (a1-r-1), it is still more preferable that the alkyl group is a linear alkyl group of 1 to 5 carbon atoms, and it is particularly preferable that the alkyl group is a methyl group or an ethyl group.

In the formula (a1-r2-2), it is preferable that Ra′¹³ is the same group as described above for the linear, branched or cyclic alkyl group for Ra′³ in the formula (a1-r-1).

Among these, the same cyclic alkyl group as those describe above for Ra′³ is more preferable.

Specific examples of the group represented by formula (a1-r2-1) are shown below. In the present specification, “*” in the formula represents a valence bond.

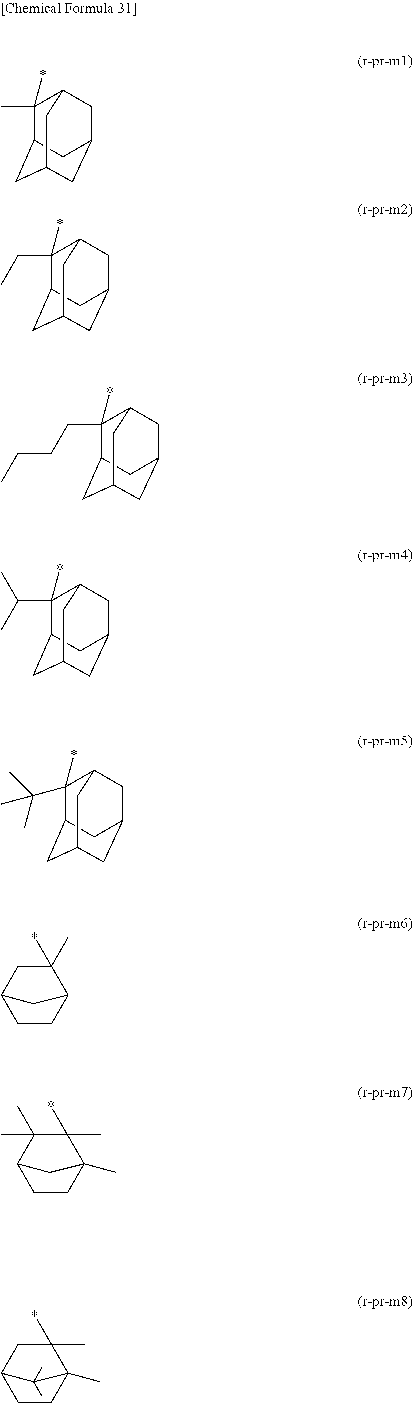

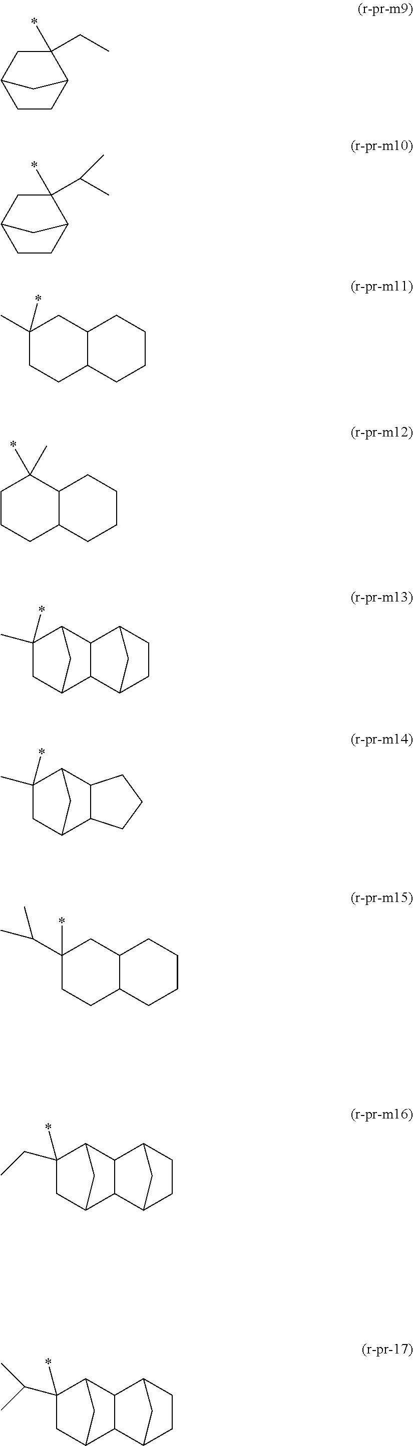

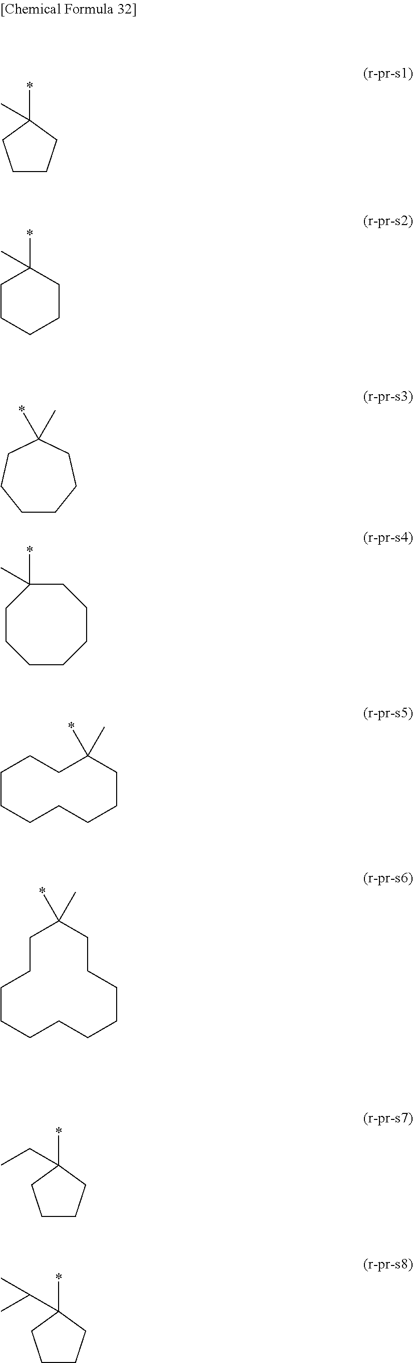

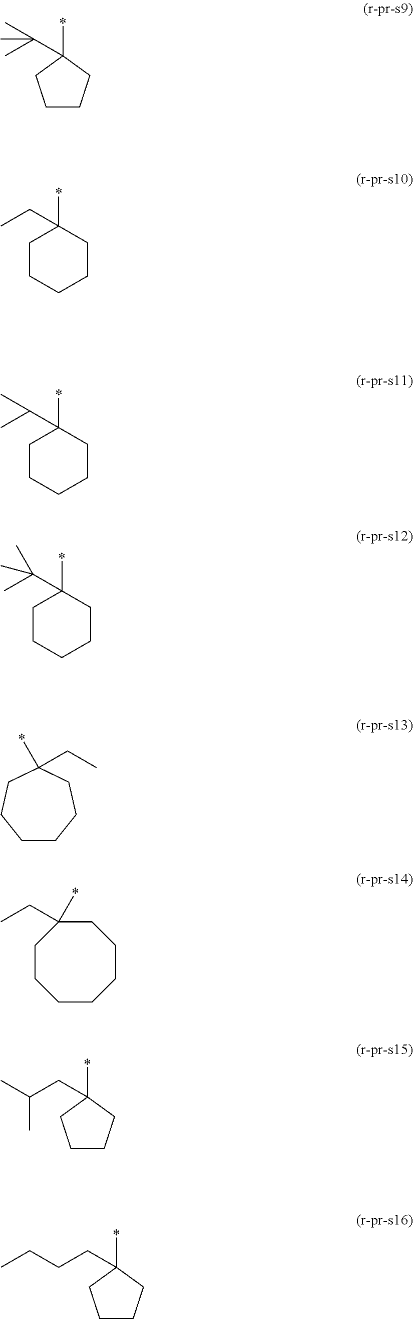

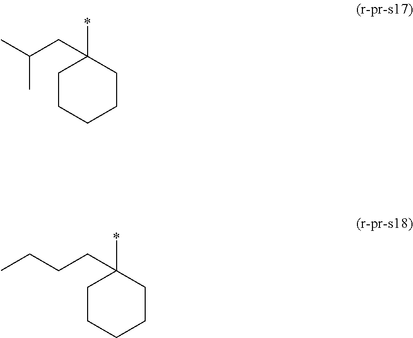 [SMILES: *C1(CC(C)C)CCCCC1 ; *C1(CCCC)CCCCC1]

Specific examples of the group represented by formula (a1-r2-2) are shown below.

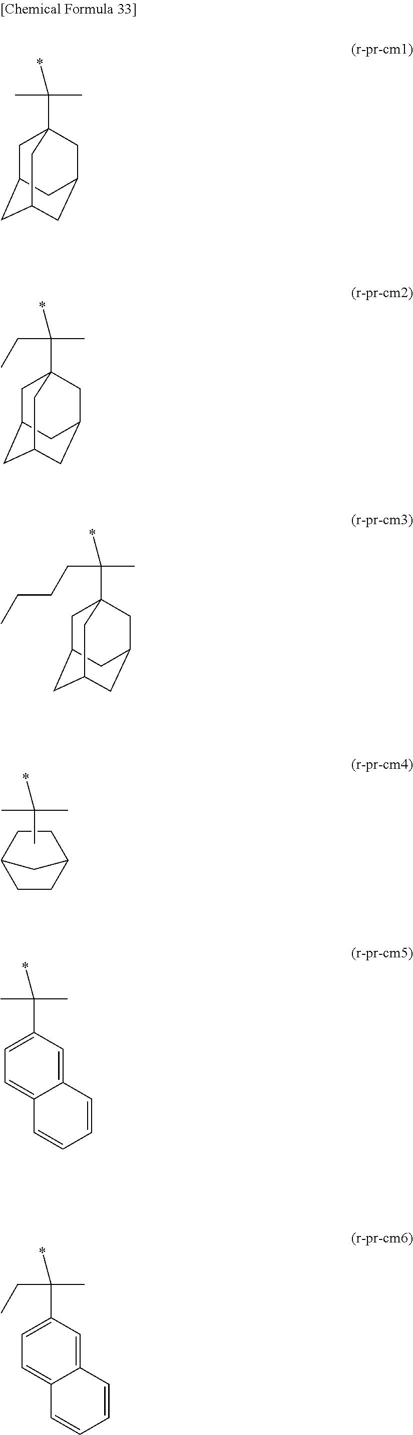

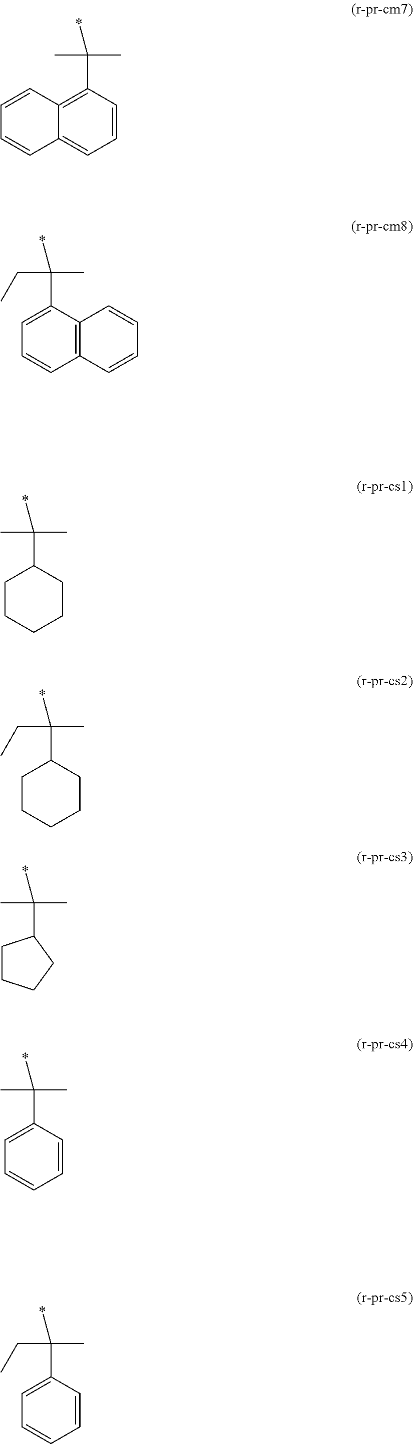

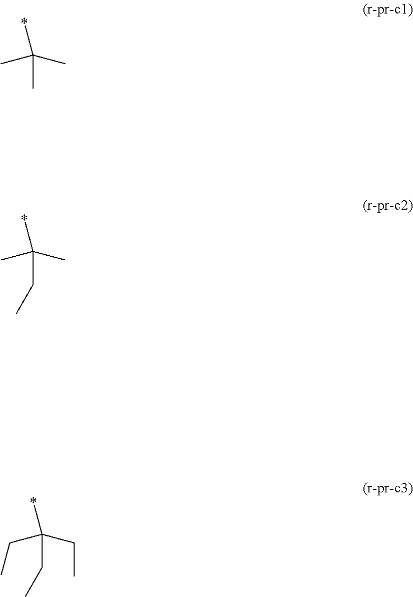

Examples of the acid dissociable group for protecting a hydroxy group as a polar group include the acid dissociable group represented by general formula (a1-r-3) shown below (hereafter, referred to as “tertiary alkyloxycarbonyl-type acid dissociable group”).

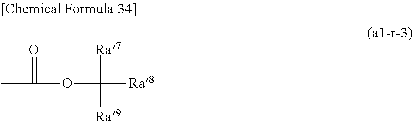

In the formula, Ra′⁷ to Ra′⁹ each independently represents an alkyl group.

In the formula (a1-r-3), Ra′⁷ to Ra′⁹ is each preferably an alkyl group of 1 to 5 carbon atoms, and more preferably an alkyl group of 1 to 3 carbon atoms.

Further, the total number of carbon atoms within the alkyl group is preferably 3 to 7, more preferably 3 to 5, and most preferably 3 or 4.

Examples of the structural unit (a1) include a structural unit derived from an acrylate ester which may have the hydrogen atom bonded to the carbon atom on the α-position substituted with a substituent and contains an acid decomposable group which exhibits increased polarity by the action of acid; a structural unit derived from an acrylamide which contains an acid decomposable group which exhibits increased polarity by the action of acid; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1), a structural unit derived from an acrylate ester which may have the hydrogen atom bonded to the carbon atom on the α-position substituted with a substituent is preferable.

Specific examples of preferable structural units for the structural unit (a1) include structural units represented by general formula (a1-1) or (a1-2) shown below.

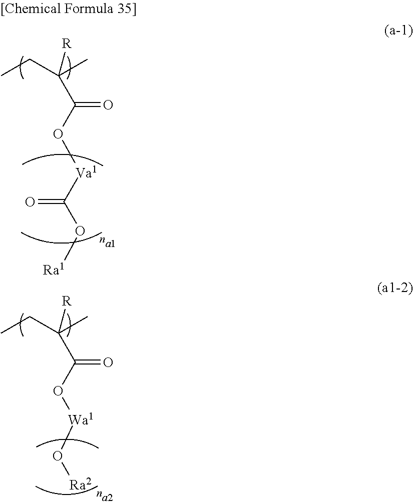

In the formulae, R represents a hydrogen atom, an alkyl group of 1 to 5 carbon atoms or a halogenated alkyl group of 1 to 5 carbon atoms; Va¹ represents a divalent hydrocarbon group which may have an ether bond; nₐ₁ represents 0 to 2; Ra′ represents an acid dissociable group represented by the aforementioned formula (a1-r-1) or (a1-r-2); Wa¹ represents a hydrocarbon group having a valency of (nₐ₂+1); nₐ₂ represents 1 to 3; and Ra² represents an acid dissociable group represented by the aforementioned formula (a1-r-1) or (a1-r-3).

In general formula (a1-1), as the alkyl group of 1 to 5 carbon atoms represented by R, a linear or branched alkyl group of 1 to 5 carbon atoms is preferable, and specific examples include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

The hydrocarbon group for Va¹ may be either an aliphatic hydrocarbon group or an aromatic hydrocarbon group. An “aliphatic hydrocarbon group” refers to a hydrocarbon group that has no aromaticity. The aliphatic hydrocarbon group as the divalent hydrocarbon group for Va¹ may be either saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

Further, Va¹ may have an ether bond (—O—) interposed between the carbon atoms of the aforementioned divalent hydrocarbon group. Va¹ may have one ether bond or two ether bonds.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂—], a trimethylene group [—(CH₂)₃-], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

As examples of the aliphatic hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed within a linear or branched aliphatic hydrocarbon group, can be given. As the linear or branched aliphatic hydrocarbon group, the same groups as those described above can be used.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane.

As the polycyclic alicyclic group, a group in which two hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

The aromatic hydrocarbon group is a hydrocarbon group having an aromatic ring.

The aromatic hydrocarbon group as the divalent hydrocarbon group for Va¹ preferably has 3 to 30 carbon atoms, more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (for example, a group in which one hydrogen atom has been removed from an aryl group within an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atoms, more preferably 1 or 2, and most preferably 1.

In the aforementioned formula (a1-2), the hydrocarbon group for Wa¹ having a valency of (nₐ₂+1) may be either an aliphatic hydrocarbon group or an aromatic hydrocarbon group. The aliphatic hydrocarbon group refers to a hydrocarbon group that has no aromaticity, and may be either saturated or unsaturated, but is preferably saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof.

The valency of (nₐ₂+1) is preferably divalent, trivalent or tetravalent, and divalent or trivalent is more preferable.

Specific examples of structural units represented by the general formula (a1-1) are shown below. In the formulae shown below, R^{α} represents a hydrogen atom, a methyl group or a trifluoromethyl group.

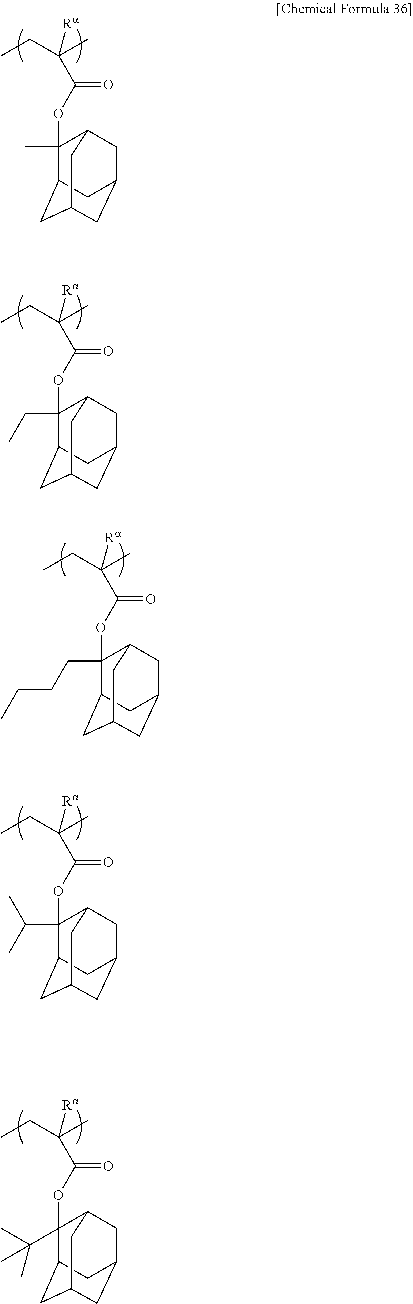

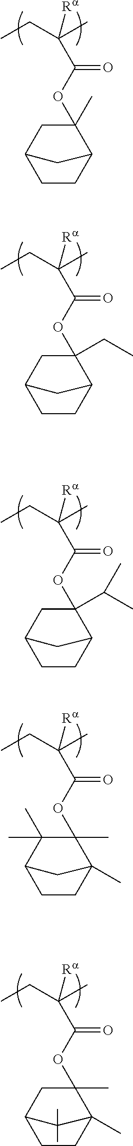

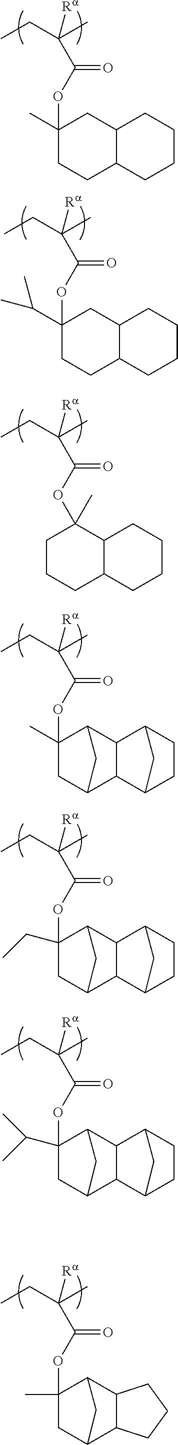

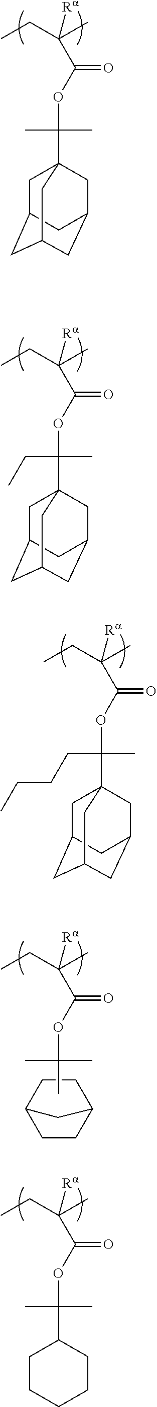

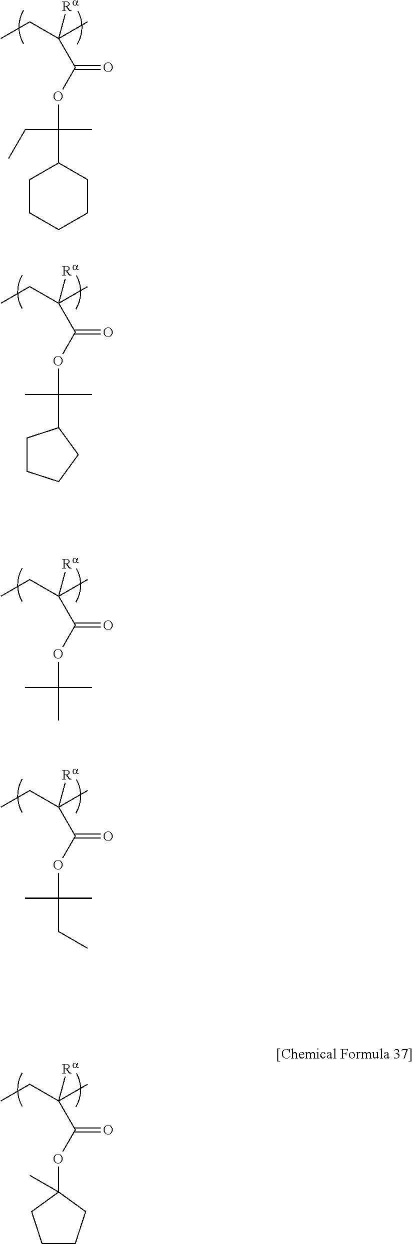

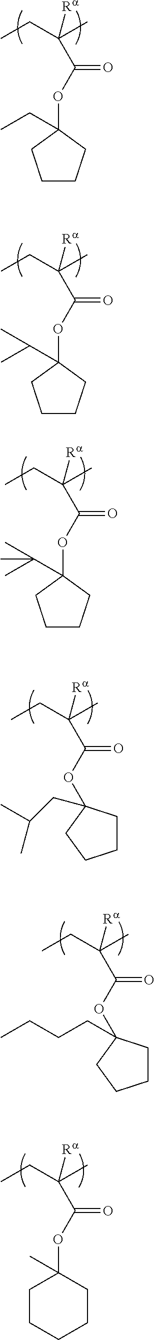

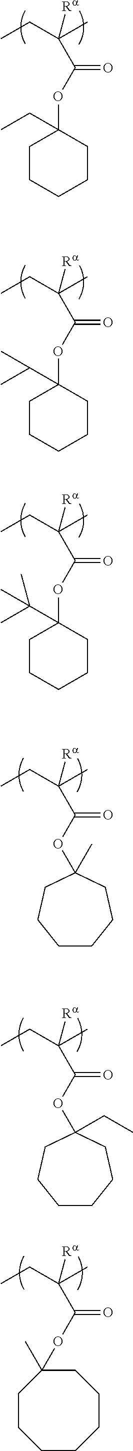

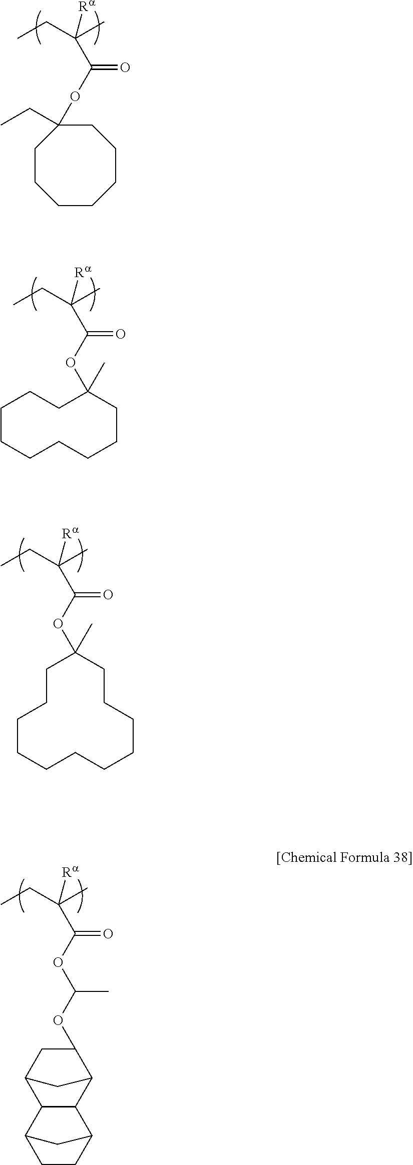

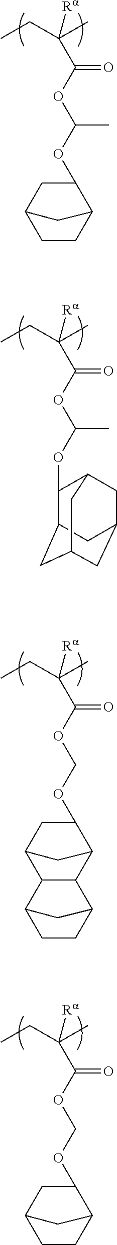

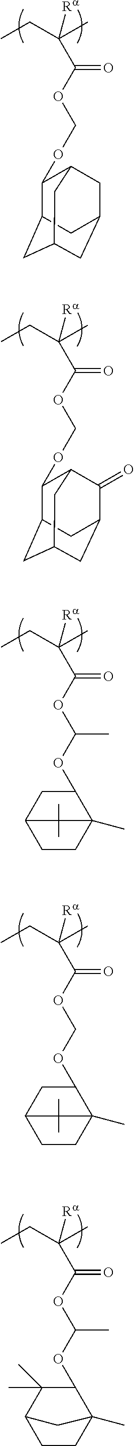

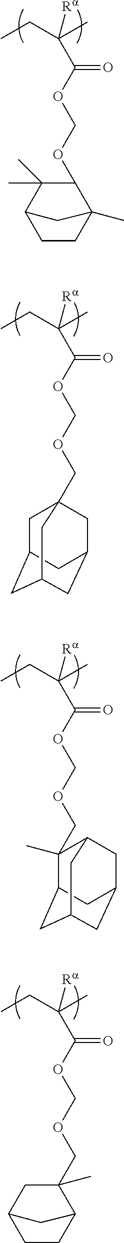

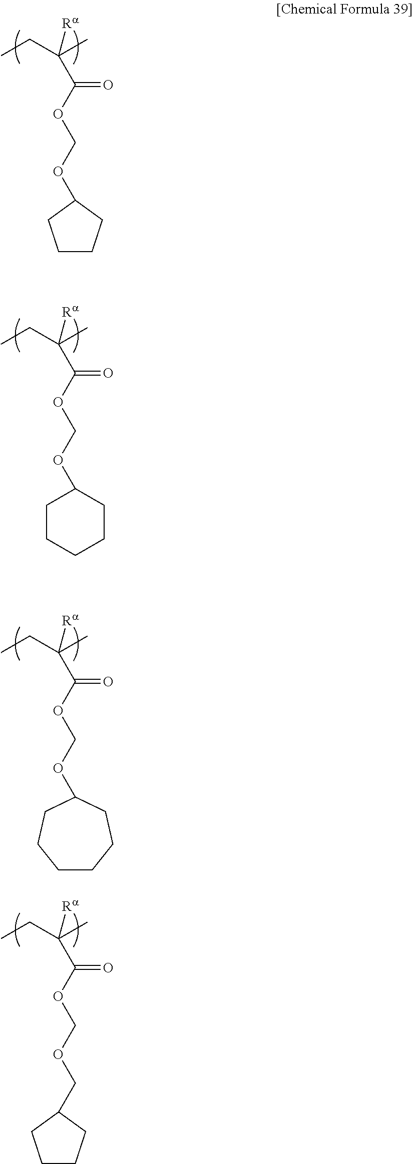

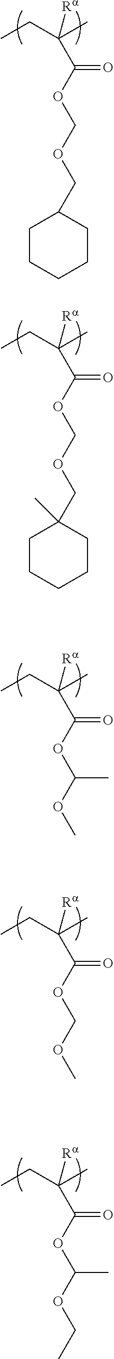

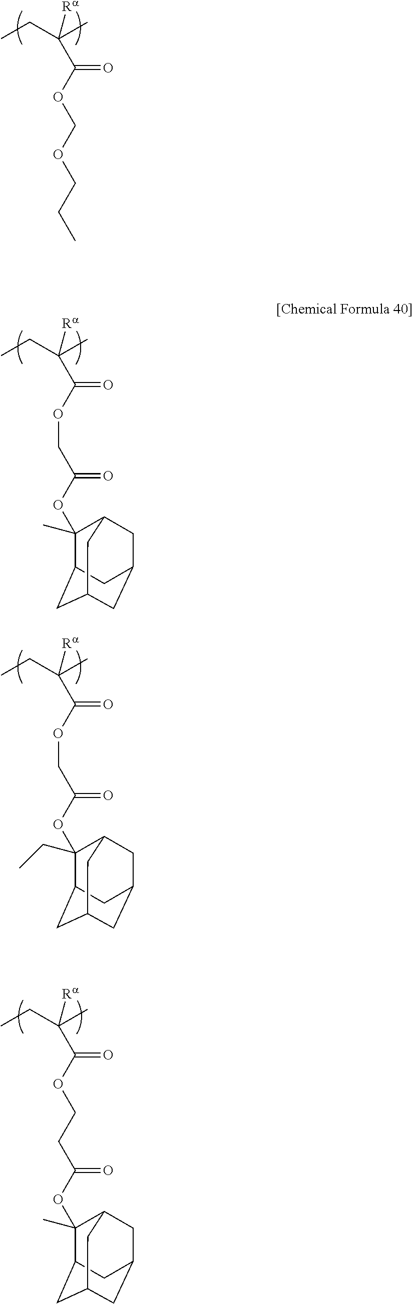

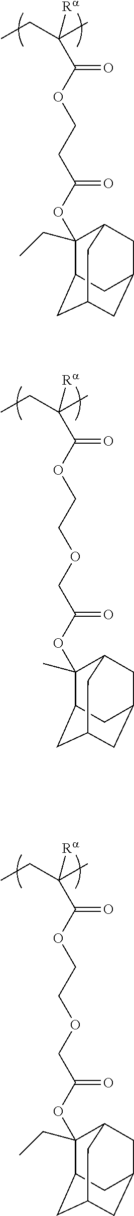

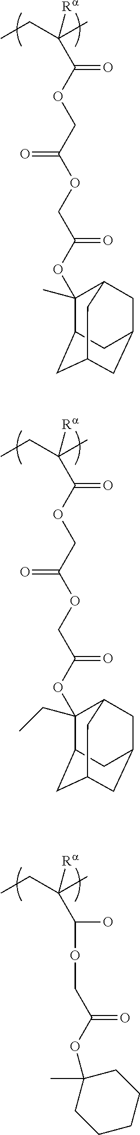

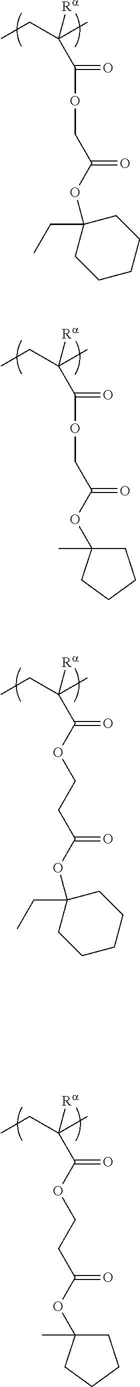

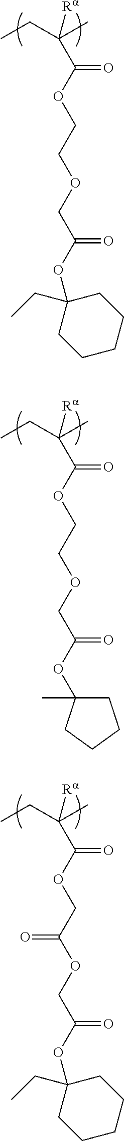

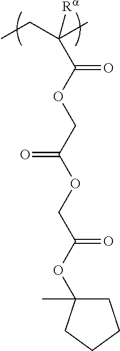

Specific examples of structural units represented by the general formula (a1-2) are shown below. In the formulae shown below, R^{α} represents a hydrogen atom, a methyl group or a trifluoromethyl group.

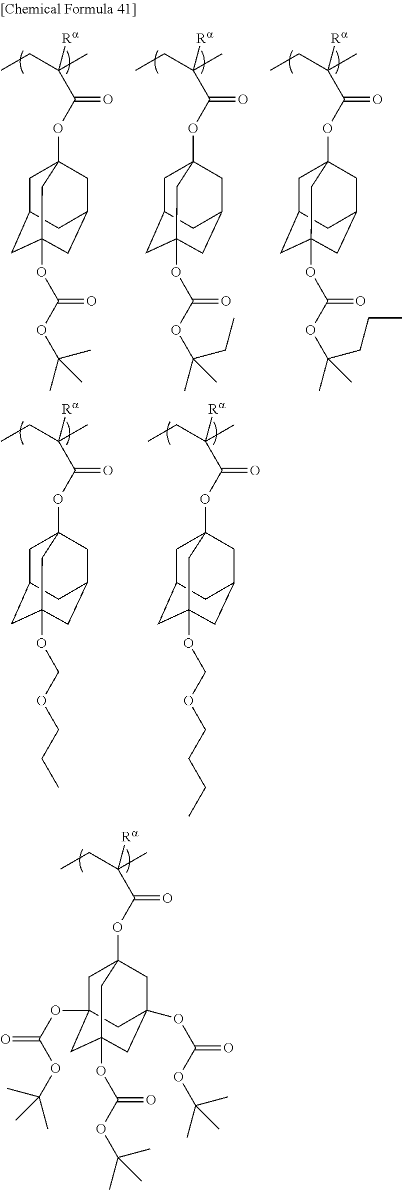

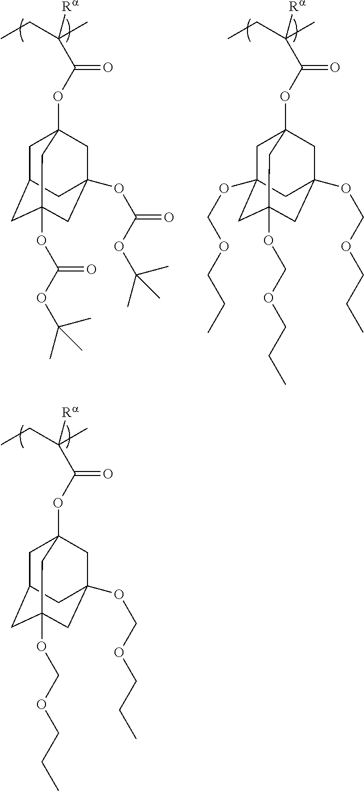

As the structural unit (a1) contained in the component (A1), 1 type of structural unit may be used, or 2 or more types may be used.

In the component (A1), the amount of the structural unit (a1) based on the combined total of all structural units constituting the component (A1) is preferably 20 to 80 mol %, more preferably 20 to 75 mol %, and still more preferably 25 to 70 mol %. When the amount of the structural unit (a1) is at least as large as the lower limit of the above-mentioned range, a resist pattern can be easily formed, and various lithography properties such as sensitivity, resolution, LWR and the like are improved. On the other hand, when the amount of the structural unit (a1) is no more than the upper limit of the above-mentioned range, a good balance can be achieved with the other structural units.

Structural Unit (a2):

The structural unit (a2) is a structural unit which contains a lactone-containing cyclic group, an —SO₂— containing cyclic group or a carbonate-containing cyclic group.

When the component (A1) is used for forming a resist film, the lactone-containing cyclic group, the —SO₂— containing cyclic group or the carbonate-containing cyclic group within the structural unit (a2) is effective in improving the adhesion between the resist film and the substrate.

The aforementioned structural units (a0), (a6) and (a1)) which contain a lactone-containing cyclic group, an —SO₂— containing cyclic group or a carbonate-containing cyclic group fall under the definition of the structural unit (a2); however, such a structural unit does not fall under the definition of the structural unit (a2).

The term “lactone-containing cyclic group” refers to a cyclic group including a ring containing a —O—C(═O)— structure (lactone ring). The term “lactone ring” refers to a single ring containing a —O—C(═O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a2) is not particularly limited, and an arbitrary structural unit may be used. Specific examples include structural units represented by general formulae (a1-r-1) to (a2-r-8) shown below.

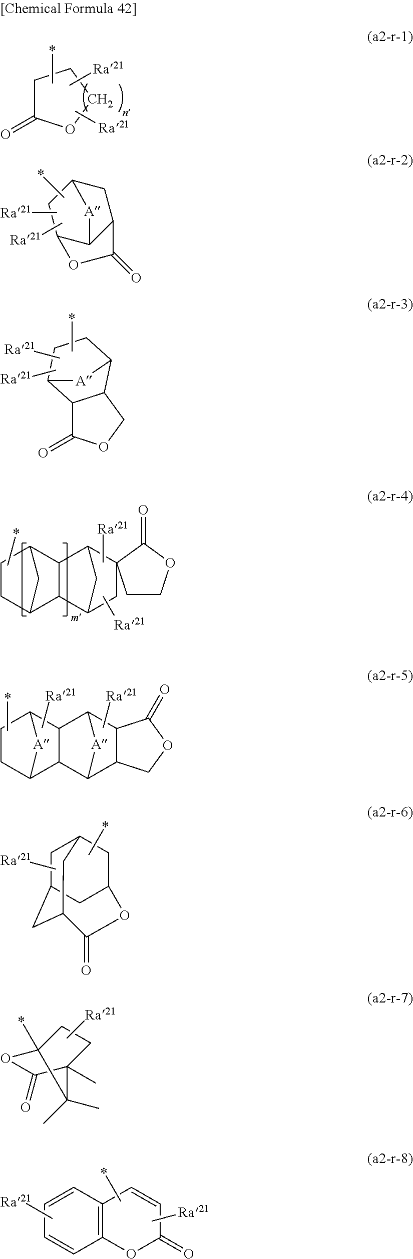

In the formulae, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom (—O—) or a sulfur atom (—S—); n′ represents an integer of 0 to 2; and m′ represents 0 or 1.

In the formulae (a1-r-1) to (a2-r-8), the alkyl group for Ra′²¹ is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or an ethyl group is preferable, and a methyl group is particularly desirable.

The alkoxy group for Ra′²¹ is preferably an alkoxy group of 1 to 6 carbon atoms.

Further, the alkoxy group is preferably a linear or branched alkoxy group. Specific examples of the alkoxy groups include the aforementioned alkyl groups for Ra′²¹ having an oxygen atom (—O—) bonded thereto.

As examples of the halogen atom for Ra′²¹, a fluorine atom, chlorine atom, bromine atom and iodine atom can be given. Among these, a fluorine atom is preferable.

Examples of the halogenated alkyl group for Ra′²¹ include groups in which part or all of the hydrogen atoms within the aforementioned alkyl groups has been substituted with the aforementioned halogen atoms. As the halogenated alkyl group, a fluorinated alkyl group is preferable, and a perfluoroalkyl group is particularly desirable.

With respect to —COOR″ and —OC(═O)R″ for Ra′²¹, R″ represents a hydrogen atom or an alkyl group.

The alkyl group for R″ may be linear, branched or cyclic, and preferably has 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for Ra′²¹ preferably has 1 to 6 carbon atoms, and specific examples thereof include the aforementioned alkyl groups for the substituent in which at least one hydrogen atom has been substituted with a hydroxy group.

In the formulae (a2-r-2), (a2-r-3) and (a2-r-5), as the alkylene group of 1 to 5 carbon atoms for A″, a linear or branched alkylene group is preferable, and examples thereof include a methylene group, an ethylene group, an n-propylene group and an isopropylene group. Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂— and —CH₂—S—CH₂—. As A″, an alkylene group of 1 to 5 carbon atoms or —O— is preferable, more preferably an alkylene group of 1 to 5 carbon atoms, and most preferably a methylene group.

Specific examples of the group represented by the aforementioned general formulae (a2-r-1) to (a2-r-8) are shown below.

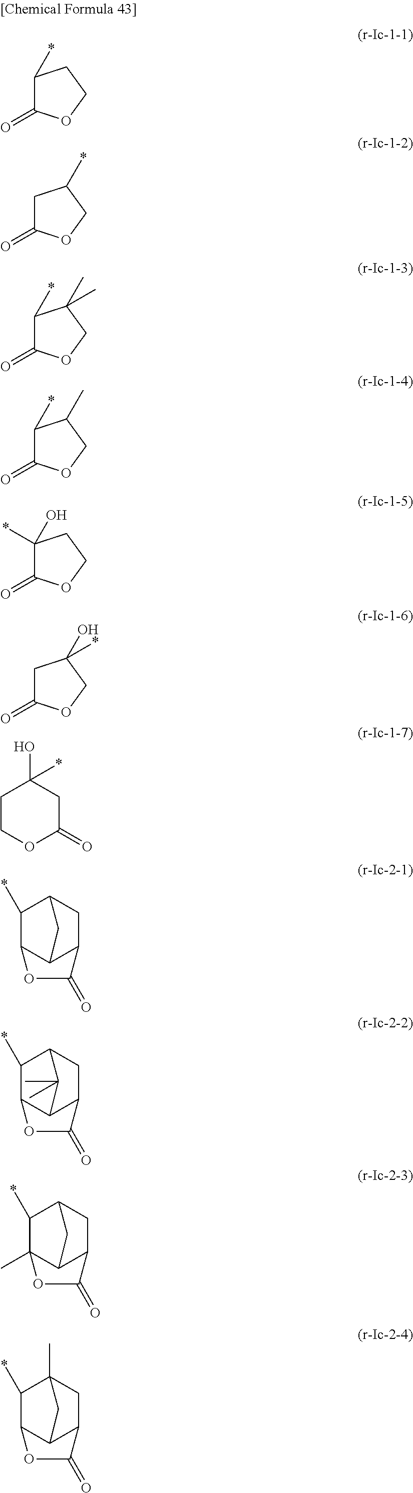

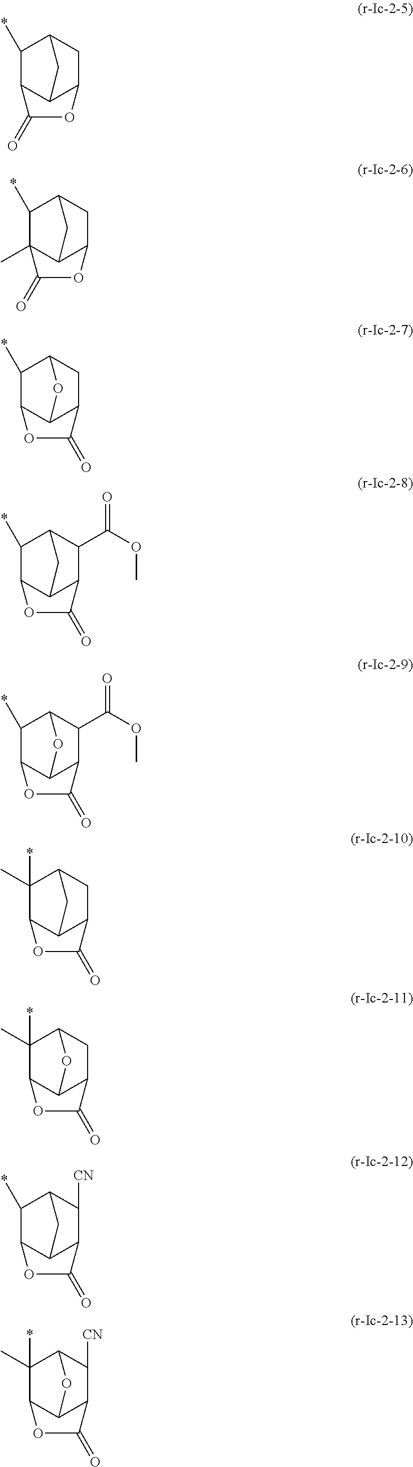

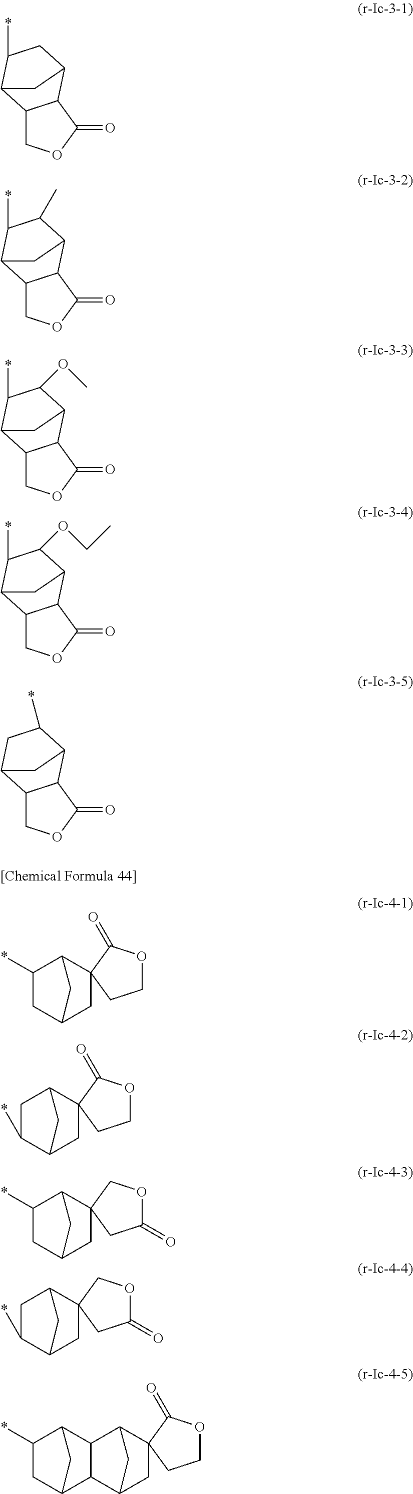

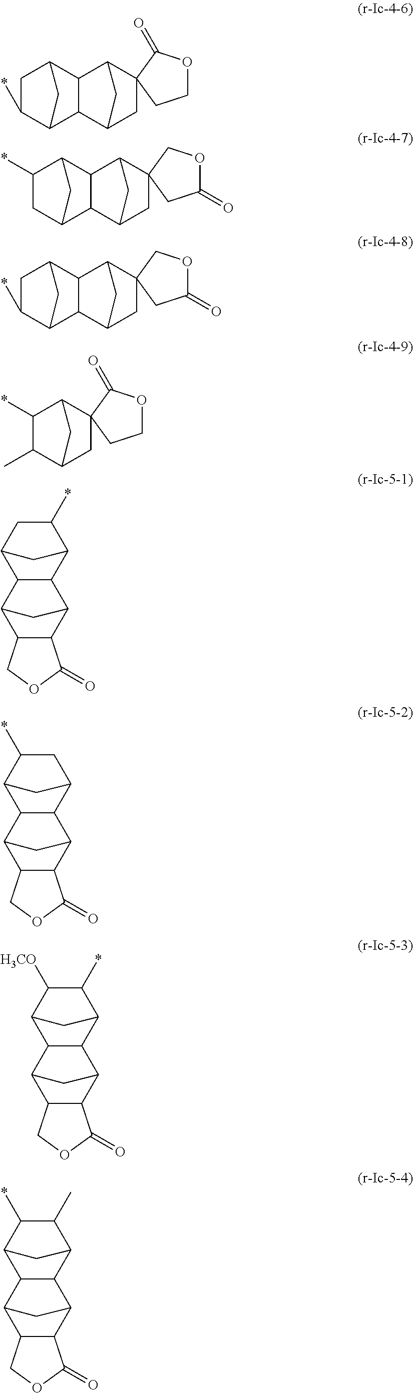

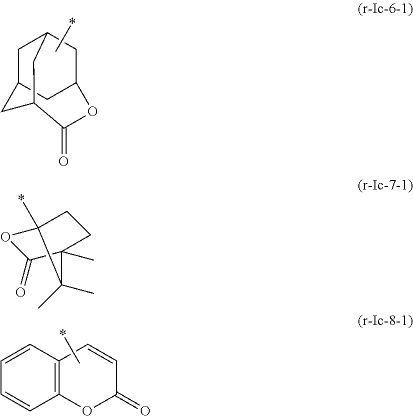

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

More specific examples of the —SO₂— containing cyclic group include groups represented by general formulae (a5-r-1) to (a5-r-4) shown below.

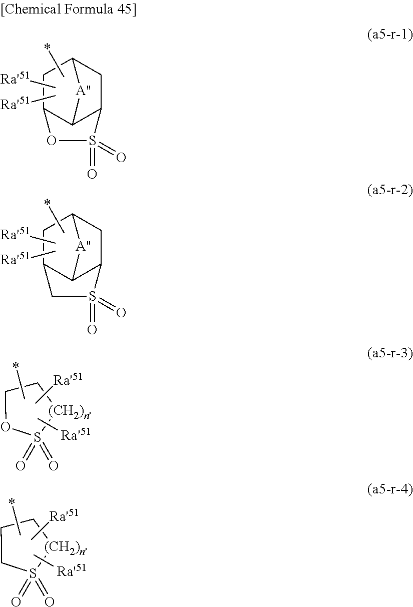

In the formulae, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2.

In general formulae (a5-r-1) to (a5-r-4), A″ is the same as defined for A″ in general formulae (a2-r-2), (a2-r-3) and (a2-r-5).

Examples of the alkyl group, alkoxy group, halogen atom, halogenated alkyl group, —COOR″, —OC(═O)R″ and hydroxyalkyl group for Ra′⁵¹ include the same groups as those described above in the explanation of Ra′²¹ in the general formulae (a1-r-1) to (a2-r-8).

Specific examples of the group represented by the aforementioned general formulae (a5-r-1) to (a5-r-4) are shown below. In the formulae shown below, “Ac” represents an acetyl group.

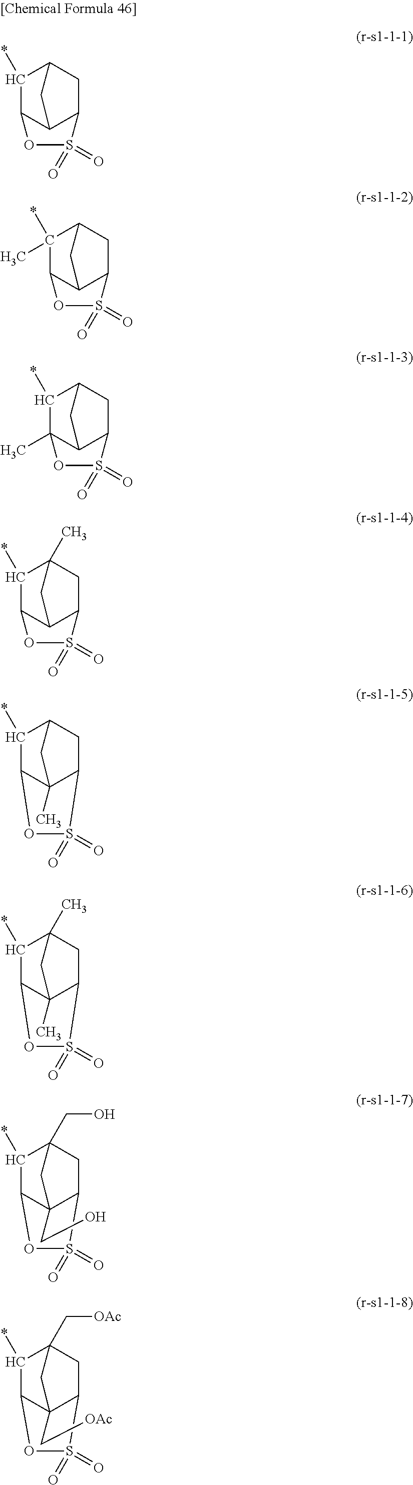

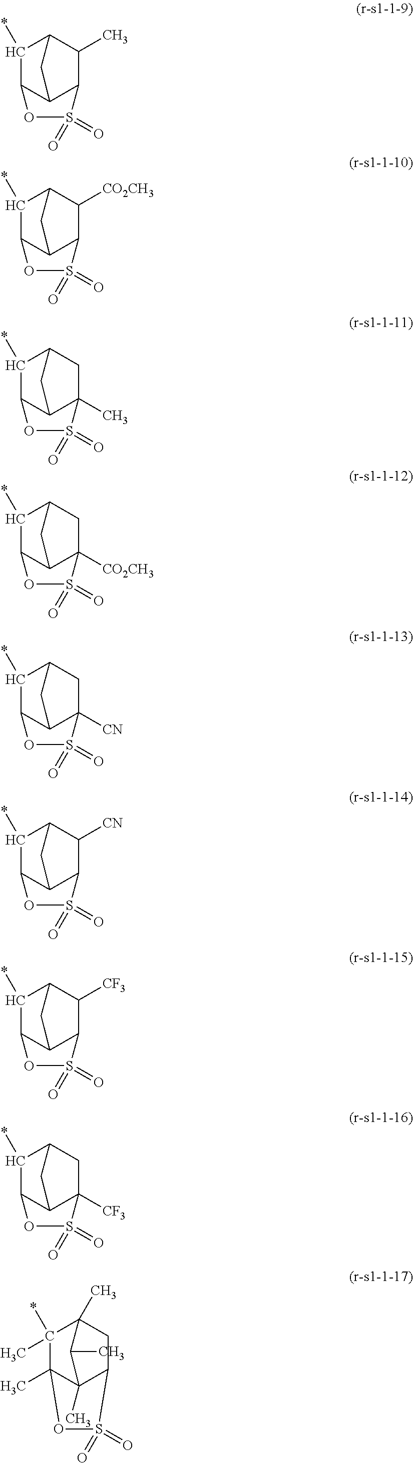

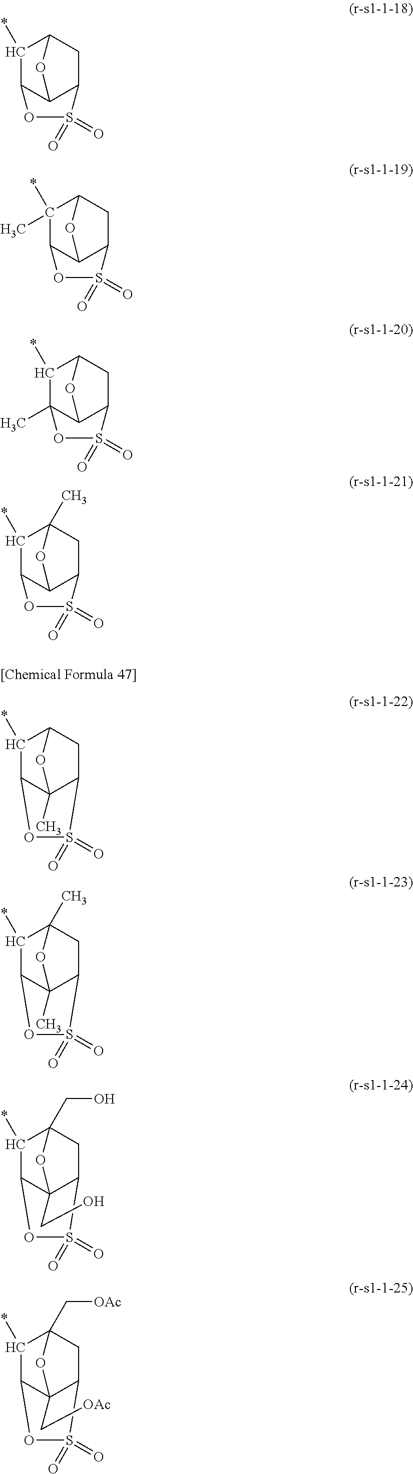

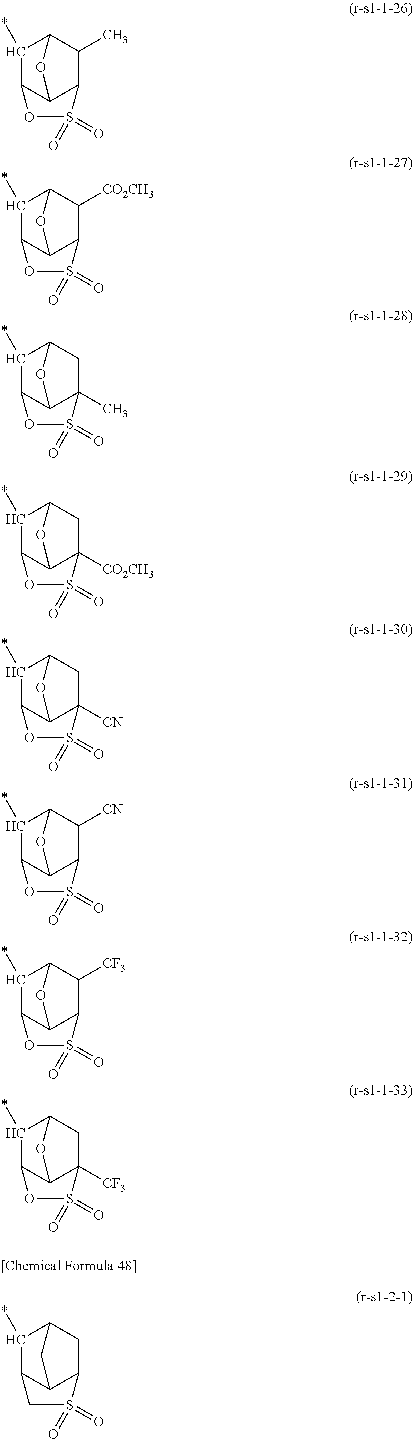

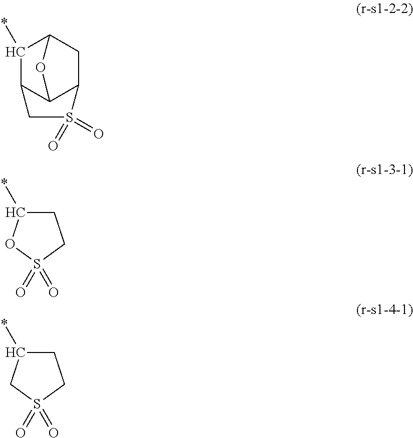

The term “carbonate-containing cyclic group” refers to a cyclic group including a ring containing a —O—C(═O)—O— structure (carbonate ring) in the ring skeleton thereof. The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

The carbonate-containing cyclic group is not particularly limited, and an arbitrary group may be used. Specific examples include groups represented by general formulae (ax3-r-1) to (ax3-r-3) shown below.

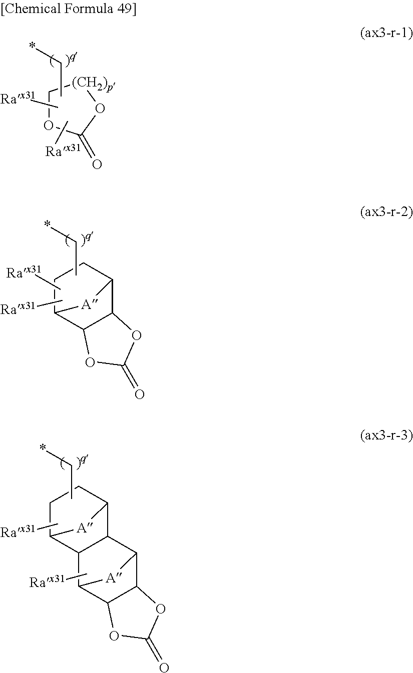

In the formulae, each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; p′ represents an integer of 1 to 3; and q′ represents 0 or 1.

In general formulae (ax3-r-1) to (ax3-r-3), A″ is the same as defined for A″ in general formulae (a2-r-2), (a2-r-3) and (a2-r-5).

Examples of the alkyl group, alkoxy group, halogen atom, halogenated alkyl group, —COOR″, —OC(═O)R″ and hydroxy alkyl group for Ra′³¹ include the same groups as those exemplified for

Ra′²¹ in the formulae (a2-r-1) to (a2-r-8).

Specific examples of the group represented by the aforementioned general formulae (ax3-r-1) to (ax3-r-3) are shown below.

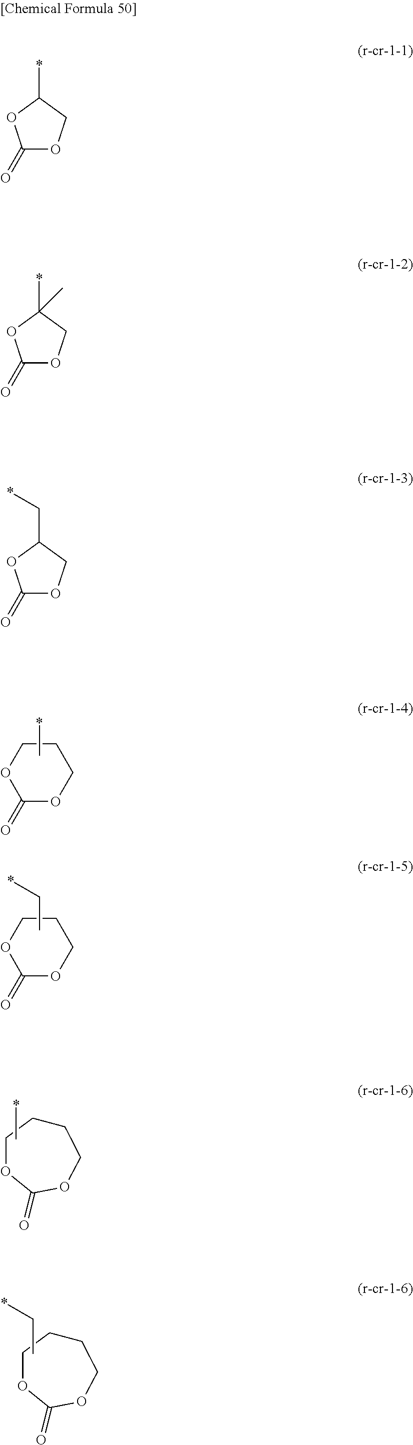

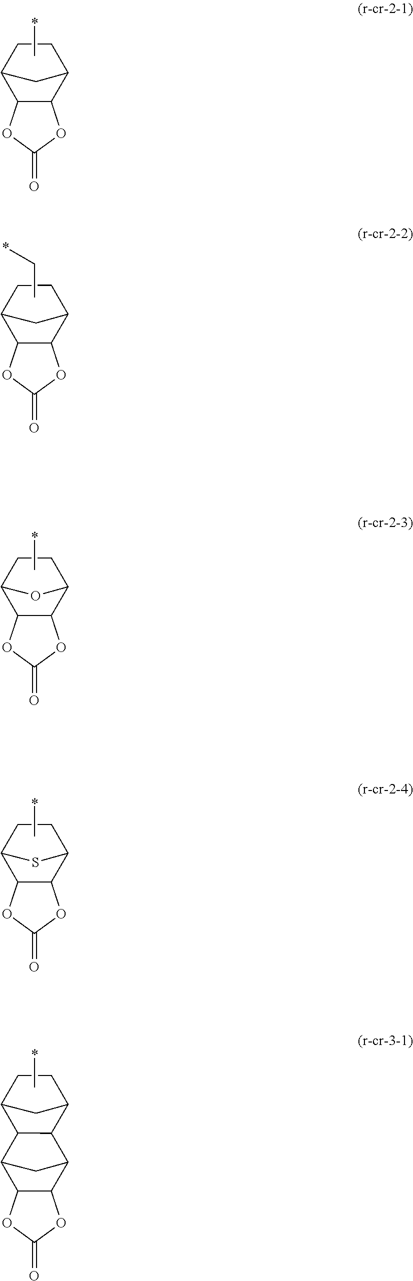

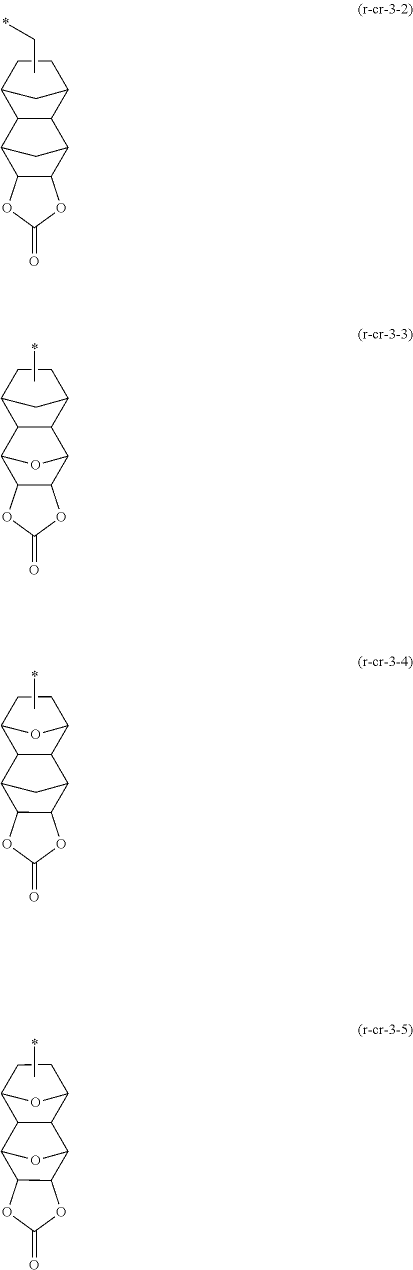

The structural unit (a2) is preferably a structural unit represented by general formula (a2-1) shown below.

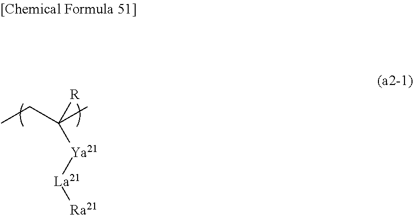

In the formula, R represents a hydrogen atom, an alkyl group of 1 to 5 carbon atoms or a halogenated alkyl group of 1 to 5 carbon atoms; Ya²¹ represents a single bond or a divalent linking group; La²¹ represents —O—, —COO—, —CON(R′)—, —COO—, —CONHCO— or —CONHCS—; R′ represents a hydrogen atom or a methyl group, provided that when La²¹ represents —O—, Ya²¹ does not represents —CO—; and Ra²¹ represents a lactone-containing cyclic group, a carbonate-containing cyclic group or an —SO₂— containing cyclic group.

In the formula (a2-1), R is the same as defined above.

The divalent linking group for Ya²¹ is not particularly limited, and preferable examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

The aliphatic hydrocarbon group for Ya²¹ may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and a carbonyl group.

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed within a linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic alicyclic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

In the cyclic aliphatic hydrocarbon group, part of the carbon atoms constituting the ring structure thereof may be substituted with a substituent containing a hetero atom.

The substituent containing a hetero atom is preferably —O—, —C(═O)—O—, —S—, —S(═O)₂—, or —S(═O)₂—O—

The aromatic hydrocarbon group for Ya²¹ is a hydrocarbon group having at least one aromatic ring.

The aromatic ring is not particularly limited, as long as it is a cyclic conjugated compound having (4n+2) π electrons, and may be either monocyclic or polycyclic. The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic hydrocarbon group. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hetero ring include a pyridine ring and a thiophene ring.

Specific examples of the aromatic hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and particularly preferably 1 carbon atom.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and a methyl group, an ethyl group, a propyl group, an n-butyl group or a tert-butyl group is most desirable.

As the alkoxy group, the halogen atom and the halogenated alkyl group for the substituent, the same groups as the aforementioned substituent groups for substituting a hydrogen atom within the cyclic aliphatic hydrocarbon group can be used.

(Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

In the case where Ya²¹ represents a divalent linking group containing a hetero atom, preferable examples of the linking group include —O—, —C(═O)—O—, —C(═O)—, —O—C(═O)—O—, —C(═O)—NH—, —NH—, —NH—C(═NH)— (wherein H may be substituted with a substituent such as an alkyl group or an acyl group), —S—, —S(═O)₂—, —S(═O)₂—O— and a group represented by general formula —Y²¹—O—Y²²—, —Y²¹—O—, Y²¹—C(═O)—O—, —[Y²¹—C(═O)—O]_{m″}—Y²²—, —Y²¹—O—C(═O)—Y²²— or —Y²¹—S(═O)₂—O—Y²²— [in the formulae, each of Y²¹ and Y²² independently represents a divalent hydrocarbon group which may have a substituent, O represents an oxygen atom, and m″ represents an integer of 0 to 3].

When the divalent linking group containing a hetero atom represents —C(═O)—NH—, —C(═O)—NH—C(═O)—, —NH— or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In general formula —Y²¹—O—Y²²—, —Y²¹—O—, Y²¹—C(═O)—O—, —[Y²¹—C(═O)—O]_{m″}—Y²²—, —Y²¹—O—C(═O)—Y²²— or —Y²¹—S(═O)₂—O—Y²², Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m″}—Y²²—, m″ represents an integer of 0 to 3, preferably an integer of 0 to 2, more preferably 0 or 1, and particularly preferably 1. Namely, it is particularly desirable that the group represented by the formula —[Y²¹—C(═O)—O]_{m″}—Y²²— is a group represented by the formula —Y²¹—C(═O)—O—Y²²—. Among these, a group represented by the formula —(CH₂)_{a′}—C(═O)—O—(CH₂)_{b′} is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

Ya²¹ preferably represents an ester bond [—C(═O)—O-], an ether bond (—O—), a linear or branched alkylene group, a combination of these, or a single bond.

In the formula (a2-1), Ra²¹ represents a lactone-containing cyclic group, an —SO₂-containing cyclic group or a carbonate-containing cyclic group.

Preferable examples of the lactone-containing cyclic group, the —SO₂— containing cyclic group and the carbonate-containing cyclic group for Ra²¹ include groups represented by the aforementioned formulae (a2-r-1) to (a2-r-8), groups represented by general formulae (a5-r-1) to (a5-r-4) and groups represented by general formulae (ax3-r-1) to (ax3-r-3).

Among the examples shown above, a lactone-containing cyclic group or an —SO₂-containing cyclic group is preferable, a group represented by the general formula (a2-r-1), (a2-r-2), (a2-r-8) or (a5-r-1) is more preferable, and a group represented by any one of the chemical structures (r-1c-1-1) to (r-1c-1-7), (r-1c-2-1) to (r-1c-2-13), (r-1c-8-1), (r-s1-1-1) and (r-s1-1-18) is still more preferable.

As the structural unit (a2) contained in the component (A1), 1 type of structural unit may be used, or 2 or more types may be used.

When the component (A1) contains the structural unit (a2), the amount of the structural unit (a2) based on the combined total of all structural units constituting the component (A1) is preferably 1 to 80 mol %, more preferably 10 to 70 mol %, still more preferably 10 to 65 mol %, and particularly preferably 10 to 60 mol %.

When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties and pattern shape can be improved.

Structural Unit (a3):

The structural unit (a3) is a structural unit containing a polar group-containing aliphatic hydrocarbon group (provided that the structural units that fall under the definition of structural units (a0), (a6), (a1) and (a2) are excluded).

When the component (A1) includes the structural unit (a3), the hydrophilicity of the component (A1) is enhanced, thereby contributing to improvement in resolution.

Examples of the polar group include a hydroxyl group, a cyano group, a carboxyl group, or a hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups may be either monocyclic or polycyclic, and can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that includes an aliphatic polycyclic group that contains a hydroxyl group, a cyano group, a carboxyl group or a hydroxyalkyl group in which part of the hydrogen atoms of the alkyl group have been substituted with fluorine atoms, are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, a group in which two or more hydrogen atoms have been removed from adamantane, a group in which two or more hydrogen atoms have been removed from norbornane or a group in which two or more hydrogen atoms have been removed from tetracyclododecane is preferred industrially.

As the structural unit (a3), there is no particular limitation as long as it is a structural unit containing a polar group-containing aliphatic hydrocarbon group, and an arbitrary structural unit may be used.

The structural unit (a3) is preferably a structural unit derived from an acrylate ester which may have the hydrogen atom bonded to the carbon atom on the α-position substituted with a substituent and contains a polar group-containing aliphatic hydrocarbon group.

When the hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulae (a3-1), (a3-2) and (a3-3) shown below are preferable.

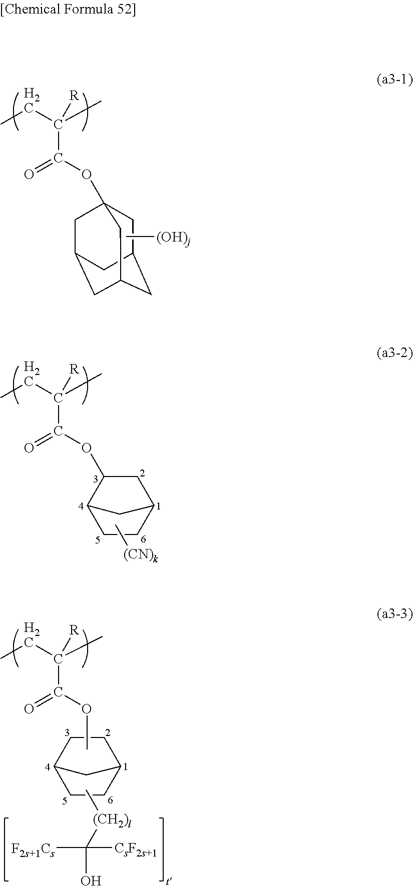

In the formulae, R is as defined above; j is an integer of 1 to 3; k is an integer of 1 to 3; t′ is an integer of 1 to 3; 1 is an integer of 1 to 5; and s is an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, in formula (a3-3), it is preferable that a 2-norbonyl group or 3-norbonyl group be bonded to the terminal of the carboxy group of the acrylic acid. The fluorinated alkyl alcohol is preferably bonded to the 5th or 6th position of the norbornyl group.

As the structural unit (a3) contained in the component (A1), 1 type of structural unit may be used, or 2 or more types may be used.

When the component (A1) contains the structural unit (a3), the amount of the structural unit (a3) within the component (A1) based on the combined total of all structural units constituting the component (A1) is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

Structural Unit (a4):

The structural unit (a4) is a structural unit containing an acid non-dissociable, aliphatic cyclic group.

When the component (A1) includes the structural unit (a4), dry etching resistance of the resist pattern to be formed is improved. Further, the hydrophobicity of the component (A) is further improved. Increase in the hydrophobicity contributes to improvement in terms of resolution, shape of the resist pattern and the like, particularly in an organic solvent developing process.

An “acid non-dissociable, aliphatic cyclic group” in the structural unit (a4) refers to a cyclic group which is not dissociated by the action of the acid (e.g., acid generated from the components (A1) or a component (B) described later) generated upon exposure, and remains in the structural unit.

As the structural unit (a4), a structural unit which contains a non-acid-dissociable aliphatic cyclic group, and is also derived from an acrylate ester is preferable. Examples of this cyclic group include the same groups as those described above in relation to the aforementioned structural unit (a1), and any of the multitude of conventional groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include structural units represented by general formulae (a4-1) to (a4-7) shown below.

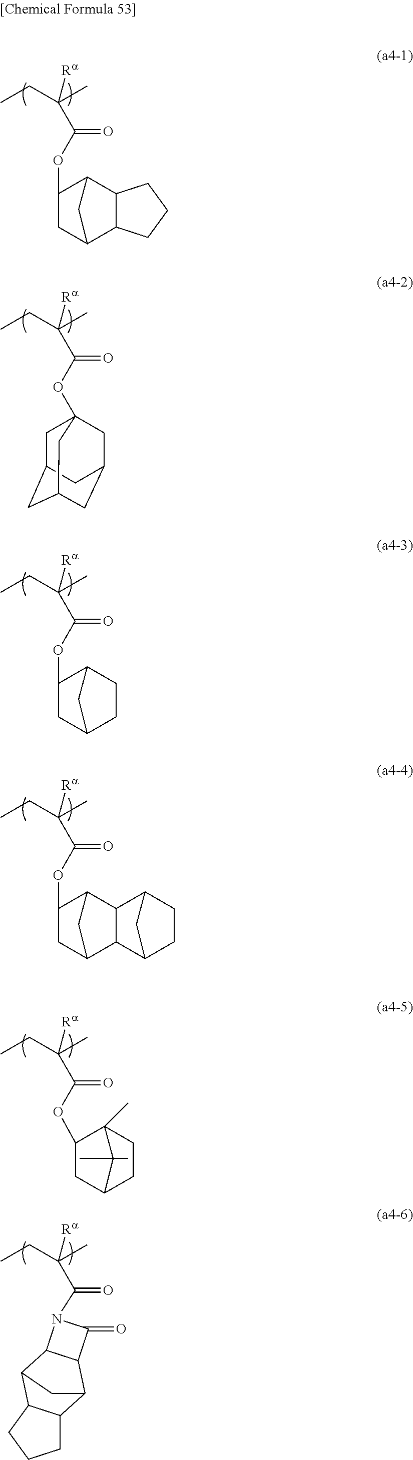

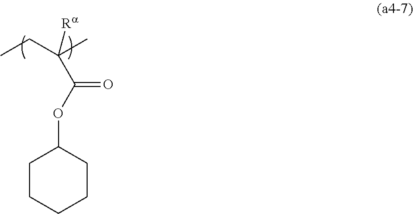

In the formulae, R^{α} is the same as defined above.

As the structural unit (a4) contained in the component (A1), 1 type of structural unit may be used, or 2 or more types may be used.

When the component (A1) includes the structural unit (a4), the amount of the structural unit (a4) based on the combined total of all structural units constituting the component (A1) is preferably 1 to 30 mol %, and more preferably 3 to 20 mol %.

When the amount of the structural unit (a4) is at least as large as the lower limit of the above-mentioned range, the effect of using the structural unit (a4) can be satisfactorily achieved. On the other hand, when the amount of the structural unit (a4) is no more than the upper limit of the above-mentioned range, a good balance can be achieved with the other structural units.

Structural Unit (a10):

The component (A1) may include a structural unit represented by general formula (a10-1) shown below (hereafter, referred to “structural unit (a10)”).

By virtue of including the structural unit (a10), the solubility in an organic solvent becomes excellent, the solubility in an alkali developing solution is improved, and the etching resistance becomes excellent.

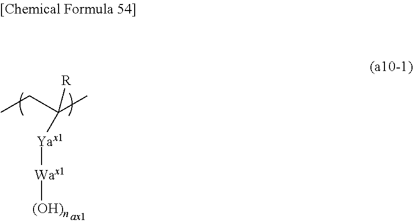

In the formula, R is the same as defined above; Ya^{x1} represents a single bond or a divalent linking group; Wa^{x1} represents an aromatic hydrocarbon group having a valency of (mₐₓ₁+1); and nₐₓ₁ represents an integer of 0 to 3, provided that, when nₐₓ₁ is 0, Ya^{x1} represents a divalent linking group containing a NH bond (—NH—).

In the formula (a10-1), the divalent linking group for Ya^{x1} is the same divalent linking group as those described above for Ya²¹ in the formula (a2-1).

The aromatic hydrocarbon group for Wa^{1x} is a hydrocarbon group containing an aromatic ring, and the aromatic ring preferably has 5 to 30 carbon atoms, more preferably 5 to 20, still more preferably 6 to 15, and particularly preferably 6 to 12. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Examples of aromatic hydrocarbon groups for Wa^{x1} include a group in which (nₐₓ₁+1) hydrogen atoms have been removed from the aromatic hydrocarbon ring or aromatic hetero ring exemplified as an aromatic ring.

nₐₓ₁ represents an integer of 0 to 3, and preferably 0, 1 or 2.

Specific examples of structural units represented by general formulae (a10-1) are shown below. In the formulae shown below, R^{α} represents a hydrogen atom, a methyl group or a trifluoromethyl group.

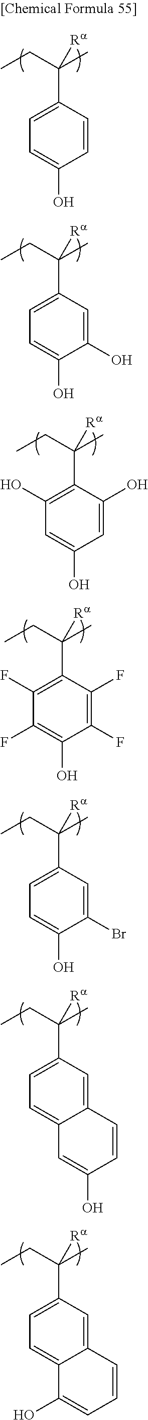

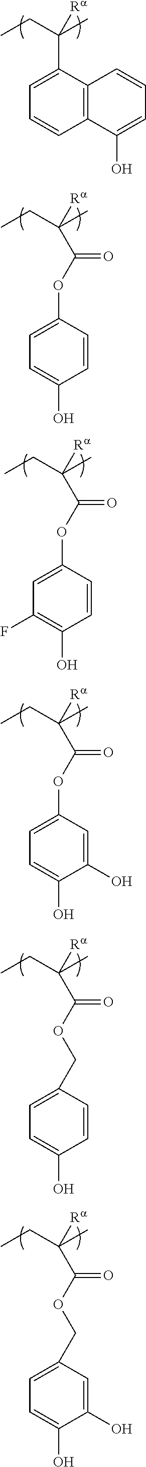

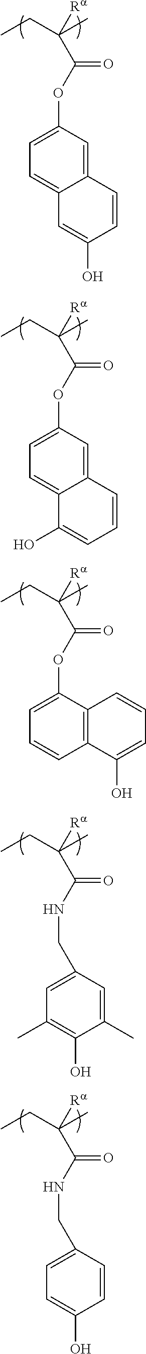

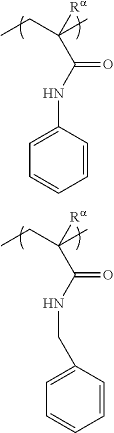

As the structural unit (a10) contained in the component (A1), 1 type of structural unit may be used, or 2 or more types may be used.

When the component (A1) includes the structural unit (a10), the amount of the structural unit (a10) based on the combined total of all structural units constituting the component (A1) is preferably 5 to 70 mol %, more preferably 10 to 65 mol %, and still more preferably 15 to 60 mol %.

When the amount of the structural unit (a10) is at least as large as the lower limit of the above-mentioned range, the effect of using the structural unit (a10) can be satisfactorily achieved. On the other hand, when the amount of the structural unit (a10) is no more than the upper limit of the above-mentioned range, a good balance can be achieved with the other structural units.

The component (A1) is a polymeric compound containing the structural unit (a0) and the structural unit (a6), and preferably a polymeric compound containing the structural unit (a2), as well as the structural unit (a0) and the structural unit (a6). Further, the component (A1) is preferably a polymeric compound containing the structural unit (a10), as well as the structural unit (a0) and the structural unit (a6).

Preferable examples of the component (A1) include a polymeric compound consisting of a repeating structure of the structural unit (a0), the structural unit (a6) and the structural unit (a2); a polymeric compound consisting of a repeating structure of the structural unit (a0), the structural unit (a6), the structural unit (a2) and the structural unit (a3); a polymeric compound consisting of a repeating structure of the structural unit (a0), the structural unit (a6) and the structural unit (a10); and a polymeric compound consisting of a repeating structure of the structural unit (a0), the structural unit (a6), the structural unit (a10) and the structural unit (a2).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 4.0, and most preferably 1.0 to 3.0. Here, Mn is the number average molecular weight.

As the component (A1), one type may be used alone, or two or more types may be used in combination.

In the component (A), the amount of the component (A1) based on the total weight of the component (A) is preferably 25% by weight or more, more preferably 50% by weight or more, still more preferably 75% by weight or more, and may be even 100% by weight. When the amount of the component (A1) is 25% by weight or more, thickness loss during formation of a resist pattern can be suppressed. Further, lithography properties such as mask reproducibility (MEEF), drawing fidelity (WEEF), exposure latitude, reduction of roughness and the like, resolution and shape of the resist pattern can be further improved.

In the resist composition of the present embodiment, as the component (A), one type may be used, or two or more types may be used in combination.

In the resist composition of the present embodiment, the amount of the component (A) can be appropriately adjusted depending on the thickness of the resist film to be formed, and the like.

In the resist composition of the present embodiment, as the base component, “a base component which exhibits changed solubility in a developing solution under action of acid” other than the component (A1) (hereafter, referred to as “component (A′)”) and the component (A1) may be used in combination.

The component (A′) is not particularly limited, and any of the multitude of conventional base components used within chemically amplified resist compositions (e.g., base resins used within chemically amplified resist compositions for ArF excimer lasers or KrF excimer lasers, preferably ArF excimer lasers) can be used. As the component (A′), one type of base component may be used, or two or more types of base components may be used in combination.

<Other Components>

The resist composition of the present embodiment may further include an acid generator component (B) (hereafter, referred to as “component (B)”) which generates acid upon exposure, in addition to the component (A).

[Component (13)]

As the component (B), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators. Among these, onium salt acid generators are preferably used.

Examples of the onium salt acid generators include a compound represented by general formula (b-1) shown below (hereafter, sometimes referred to as “component (b-1)”), a compound represented by general formula (b-2) shown below (hereafter, sometimes referred to as “component (b-2)”) and a compound represented by general formula (b-3) shown below (hereafter, sometimes referred to as “component (b-3)”).

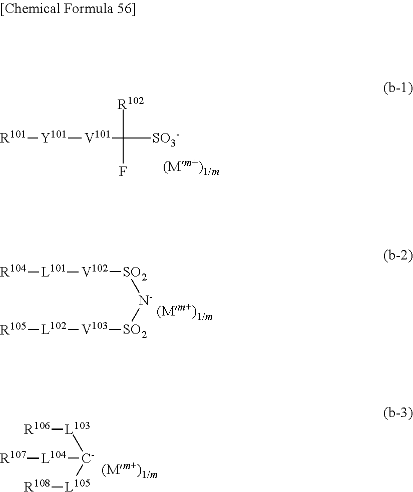

In the formulae, R¹⁰¹ and R¹⁰⁴ to R¹⁰⁸ each independently represents a cyclic group which may have a substituent, a chain-like alkyl group which may have a substituent or a chain-like alkenyl group which may have a substituent, provided that, R¹⁰⁴ and R¹⁰⁵ may be mutually bonded to form a ring; R¹⁰² represents a fluorine atom or a fluorinated alkyl group of 1 to 5 carbon atoms; Y¹⁰¹ represents a single bond or a divalent linking group containing an oxygen atom; V¹⁰¹ to V¹⁰³ each independently represents a single bond, an alkylene group or a fluorinated alkylene group; L¹⁰¹ and L¹⁰² each independently represents a single bond or an oxygen atom; L¹⁰³ to L¹⁰⁵ each independently represents a single bond, —CO— or —SO₂—; and M′^{m+} represents an onium cation having a valency of m.

{Anion Moiety}

—Anion Moiety of Component (b-1)

In the formula (b-1), R¹⁰¹ represents a cyclic group which may have a substituent, a chain-like alkyl group which may have a substituent or a chain-like alkenyl group which may have a substituent.

(Cyclic Group which May have a Substituent)

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated.

The aromatic hydrocarbon group for R¹⁰¹ is a hydrocarbon group having an aromatic ring. The aromatic hydrocarbon group preferably has 3 to 30 carbon atoms, more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group for R¹⁰¹ include benzene, biphenyl, fluorene, naphthalene, anthracene and phenanthrene; and aromatic hetero rings in which part of the carbon atoms constituting these aromatic rings has been substituted with a hetero atom. Examples of the hetero atom within the aromatic hetero rings include an oxygen atom, a sulfur atom and a nitrogen atom.

Specific examples of the aromatic hydrocarbon group for R¹⁰¹ include a group in which one hydrogen atom has been removed from the aforementioned aromatic ring (aryl group such as a phenyl group and a naphthyl group); and a group in which one hydrogen atom of the aforementioned aromatic ring has been substituted with an alkylene group (an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atoms, more preferably 1 or 2, and most preferably 1.

Examples of the cyclic aliphatic hydrocarbon group for R¹⁰¹ include an aliphatic hydrocarbon group containing a ring in the structure thereof.

As examples of the aliphatic hydrocarbon group containing a ring in the structure thereof, an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed within a linear or branched aliphatic hydrocarbon group, can be given.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

Among these, as the cyclic aliphatic hydrocarbon group for R¹⁰¹, a group in which one or more hydrogen atoms have been removed from a monocycloalkane or a polycycloalkane is preferable, and a group in which one hydrogen atom has been removed from a polycycloalkane is more preferable, an adamantyl group and a norbornyl group are particularly preferable, and an adamantyl group is most preferable.

The linear or branched aliphatic hydrocarbon group which may be bonded to the alicyclic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

Further, the cyclic hydrocarbon group for R¹⁰¹ may contain a hetero atom, like as a heterocycle. Specific examples thereof include lactone-containing cyclic groups represented by the aforementioned general formulae (a2-r-1) to (a2-r-8), —SO₂— containing cyclic groups represented by the aforementioned formulae (a5-r-1) to (a5-r-4) and heterocycles shown below.

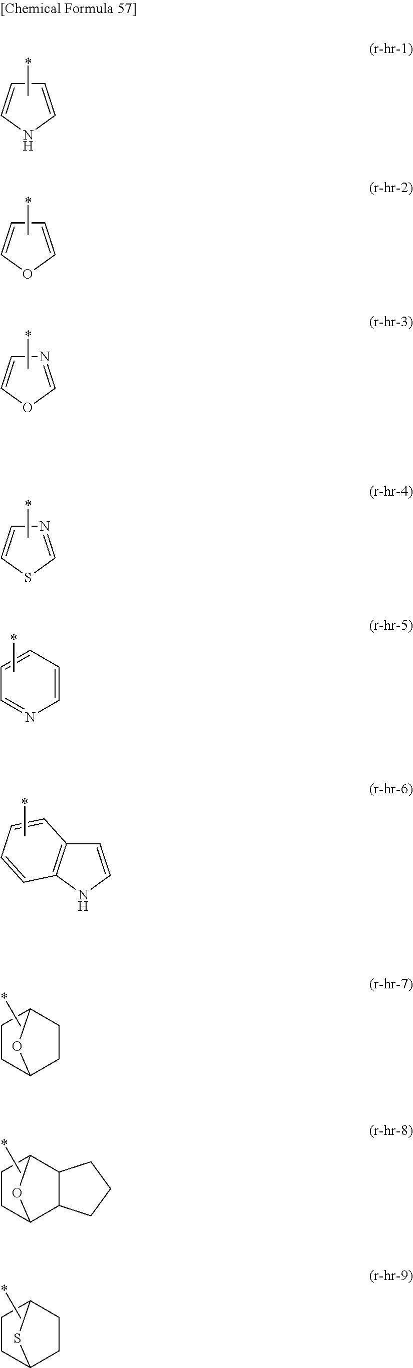

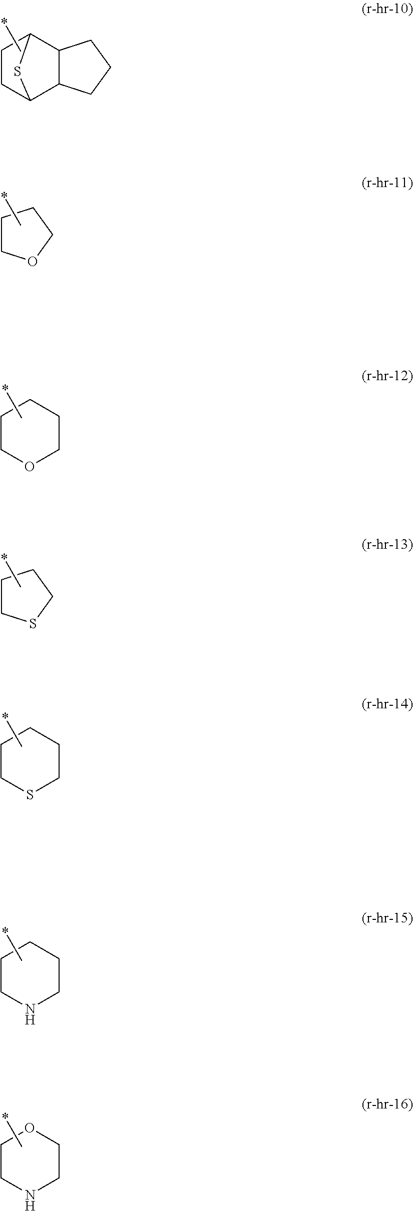

As the substituent for substituting the cyclic hydrocarbon group for R¹⁰¹, an alkyl group, an alkoxy group, a halogen atom, a halogenated alkyl group, a hydroxyl group, a carbonyl group, a nitro group or the like can be used.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

Example of the halogenated alkyl group as a substituent includes a group in which a part or all of the hydrogen atoms within an alkyl group of 1 to 5 carbon atoms such as a methyl group, an ethyl group, a propyl group, an n-butyl group or a tert-butyl group have been substituted with the aforementioned halogen atoms.

The carbonyl group as a substituent is a group to substitute a methylene group (—CH₂—) constituting a cyclic hydrocarbon group.

(Chain-Like Alkyl Group which May have a Substituent)

The chain-like alkyl group for R¹⁰¹ may be either linear or branched.

The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

(Chain-Like Alkenyl Group which May have a Substituent)

The chain-like alkenyl group for R¹⁰¹ may be linear or branched, and preferably has 2 to 10 carbon atoms, more preferably 2 to 5 carbon atoms, still more preferably 2 to 4 carbon atoms, and particularly preferably 3 carbon atoms. Examples of linear alkenyl groups include a vinyl group, a propenyl group (an allyl group) and a butynyl group. Examples of branched alkenyl groups include a 1-methylvinyl group, 2-methylvinyl group, a 1-methylpropenyl group and a 2-methylpropenyl group.

Among the above-mentioned examples, as the chain-like alkenyl group, a vinyl group and a propenyl group are preferable, and a vinyl group is particularly desirable.

As the substituent for substituting the chain-like alkyl group or alkenyl group for R¹⁰¹, an alkoxy group, a halogen atom, a halogenated alkyl group, a hydroxyl group, a carbonyl group, a nitro group, an amino group, the same cyclic group as described above for R¹⁰¹ or the like can be used.

Among these, as R¹⁰¹, a cyclic group which may have a substituent is preferable, and a cyclic hydrocarbon group which may have a substituent is more preferable.

Specific examples include a group in which one or more hydrogen atoms have been removed from a phenyl group, a naphthyl group or a polycycloalkane, lactone-containing cyclic groups represented by the aforementioned formulae (a2-r-1) to (a2-r-8) and —SO₂— containing cyclic groups represented by the aforementioned formulae (a5-r-1) to (a5-r-4) and the like.

In the formula (b-1), Y¹⁰¹ represents a single bond or a divalent linking group containing an oxygen atom.

In the case where Y¹⁰¹ is a divalent linking group containing an oxygen atom, Y¹⁰¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—) and a carbonate group (—O—C(═O)—O—); and a combination of any of the aforementioned non-hydrocarbon, oxygen atom-containing linking groups with an alkylene group. Furthermore, the combinations may have a sulfonyl group (—SO₂—) bonded thereto. As the combination, the linking groups represented by formulae (y-al-1) to (y-al-7) shown below can be mentioned.

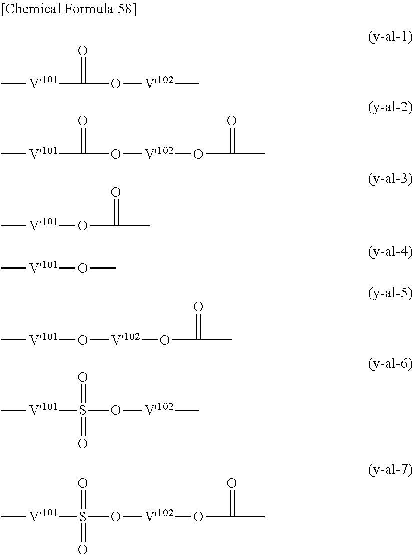

In the formulae, V′¹⁰¹ represents a single bond or an alkylene group of 1 to 5 carbon atoms; and V′¹⁰² represents a divalent saturated hydrocarbon group of 1 to 30 carbon atoms.

The divalent saturated hydrocarbon group for V′¹⁰² is preferably an alkylene group of 1 to 30 carbon atoms.

As the alkylene group for V′¹⁰¹ and V′¹⁰², a linear alkylene group or a branched alkylene group can be used, and a linear alkylene group is preferable.

Specific examples of the alkylene group for V′¹⁰¹ and V′¹⁰² include a methylene group[—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group[—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group)[—CH₂CH₂CH₂—]; alkyltrimethylene groups such as —CH(CH₃)CH₂CH₂— and —CH₂CH(CH₃)CH₂—; a tetramethylene group[—CH₂CH₂CH₂CH₂—]; alkyltetramethylene groups such as —CH(CH₃)CH₂CH₂CH₂— and —CH₂CH(CH₃)CH₂CH₂—; and a pentamethylene group[—CH₂CH₂CH₂CH₂CH₂—].

Further, part of methylene group within the alkylene group for and V′¹⁰¹ and V′¹⁰² may be substituted with a divalent aliphatic cyclic group of 5 to 10 carbon atoms. The aliphatic cyclic group is preferably a divalent group in which one hydrogen atom has been removed from the cyclic aliphatic hydrocarbon group described above for Ra′³ in the aforementioned formula (a1-r-1), and a cyclohexylene group, 1,5-adamantylene group or 2,6-adamantylene group is more preferable.

Y¹⁰¹ is preferably a divalent linking group containing an ether bond or an ester bond, and linking groups represented by the aforementioned formulae (y-al-1) to (y-al-5) are preferable.

In the formula (b-1), V¹⁰¹ represents a single bond, an alkylene group or a fluorinated alkylene group. The alkylene group or fluorinated alkylene group for V¹⁰¹ preferably has 1 to 4 carbon atoms. As the fluorinated alkylene group for V¹⁰¹, a group in which part or all of the hydrogen atoms within the aforementioned alkylene group for V¹⁰¹ has been substituted with fluorine atoms can be used. Among these, V¹⁰¹ is preferably a single bond or a fluorinated alkylene group of 1 to 4 carbon atoms.

In the formula (b-1), R¹⁰² represents a fluorine atom or a fluorinated alkyl group of 1 to 5 carbon atoms. R¹⁰² is preferably a fluorine atom or a perfluoroalkyl group of 1 to 5 carbon atoms, and is more preferably a fluorine atom.

As specific examples of anion moieties in the compound (b-1), when Y¹⁰¹ is a single bond, fluorinated alkylsulfonate anions such as a trifluoromethanesulfonate anion or a perfluorobutanesulfonate anion can be mentioned; and when Y¹⁰¹ is a divalent linking group containing an oxygen atom, anions represented by formulae (an-1) to (an-3) shown below can be mentioned.

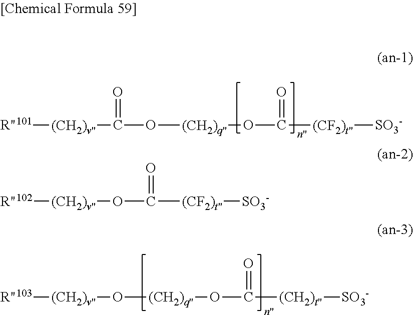

In the formulae, R″¹⁰¹ represents an aliphatic cyclic group which may have a substituent, a group represented by any one of the aforementioned formulae (r-hr-1) to (r-hr-6) or a chain-like alkyl group which may have a substituent; R″¹⁰² represents an aliphatic cyclic group which may have a substituent, a lactone-containing cyclic group represented by any one of the aforementioned formulae (a2-r-1) to (a2-r-8) or an —SO₂-containing cyclic group represented by any one of the aforementioned formulae (a5-r-1) to (a5-r-4); R″¹⁰³ represents an aromatic cyclic group which may have a substituent, an aliphatic cyclic group which may have a substituent or a chain-like alkenyl group which may have a substituent; v″ represents an integer of 0 to 3; q″ represents an integer of 1 to 20; t″ represents an integer of 1 to 3; and n″ represents 0 or 1.

As the aliphatic cyclic group for R′¹⁰¹, R″¹⁰² and R″¹⁰³ which may have a substituent, the same groups as the cyclic aliphatic hydrocarbon group for R¹⁰¹ described above are preferable. As the substituent, the same groups as those described above for substituting the cyclic aliphatic hydrocarbon group for R¹⁰¹ can be mentioned.

As the aromatic cyclic group for R″¹⁰³ which may have a substituent, the same groups as the aromatic hydrocarbon group exemplified as a cyclic hydrocarbon group for R¹⁰¹ described above are preferable. As the substituent, the same groups as those described above for substituting the aromatic hydrocarbon group for R¹⁰¹ can be mentioned.

As the chain-like alkyl group for R″¹⁰¹ which may have a substituent, the same groups exemplified as the chain-like alkyl group for R¹⁰¹ are preferable. As the chain-like alkenyl group for R″¹⁰³ which may have a substituent, the same groups exemplified as the chain-like alkenyl group for R¹⁰¹ are preferable.

—Anion Moiety of Component (b-2)

In formula (b-2), R¹⁰⁴ and R¹⁰⁵ each independently represents a cyclic group which may have a substituent, a chain-like alkyl group which may have a substituent or a chain-like alkenyl group which may have a substituent, and is the same groups as those defined above for R¹⁰¹ in the aforementioned formula (b-1), provided that, R¹⁰⁴ and R¹⁰⁵ may be mutually bonded to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group preferably has 1 to 10 carbon atoms, preferably 1 to 7, and more preferably 1 to 3. The smaller the number of carbon atoms of the chain-like alkyl group for R¹⁰⁴ and R¹⁰⁵ within the above-mentioned range of the number of carbon atoms, the more the solubility in a resist solvent is improved. Further, in the chain-like alkyl group for R¹⁰⁴ and R¹⁰⁵, it is preferable that the number of hydrogen atoms substituted with fluorine atoms is as large as possible because the acid strength increases and the transparency to high energy radiation of 200 nm or less or electron beam is improved. The fluorination ratio of the chain-like alkyl group is preferably from 70 to 100%, more preferably from 90 to 100%, and it is particularly desirable that the chain-like alkyl group be a perfluoroalkyl group in which all hydrogen atoms are substituted with fluorine atoms.

In formula (b-2), V¹⁰² and V¹⁰³ each independently represents a single bond, an alkylene group or a fluorinated alkylene group, and is the same groups as those defined above for V¹⁰¹ in the aforementioned formula (b-1).

In the formula (b-2), L¹⁰¹ and L¹⁰² each independently represents a single bond or an oxygen atom.

—Anion Moiety of Component (b-3)

In formula (b-3), R¹⁰⁶ to R¹⁰⁸ each independently represents a cyclic group which may have a substituent, a chain-like alkyl group which may have a substituent or a chain-like alkenyl group which may have a substituent, and is the same groups as those defined above for R¹⁰¹ in the aforementioned formula (b-1).

L¹⁰³ to L¹⁰⁵ each independently represents a single bond, —CO— or —SO₂—.

{Cation Moiety}

In the formulae (b-1), (b-2) and (b-3), M′^{m+} represents an onium cation having a valency of m. Among these, a sulfonium cation or an iodonium cation is preferable.

Specific examples include the same groups as organic cations exemplified above for M^{m+} (organic cation having a valency of m) represented by general formulae (ca-1) to (ca-4) in the formulae (a6a-1) to (a6a-8).

As the component (B), one type of these acid generators may be used alone, or two or more types may be used in combination.

When the resist composition of the present embodiment contains the component (B), the amount of the component (B) relative to 100 parts by weight of the component (A) is preferably within a range from 0.5 to 60 parts by weight, more preferably from 1 to 50 parts by weight, and still more preferably from 1 to 40 parts by weight. When the amount of the component (B) is within the above-mentioned range, formation of a resist pattern can be satisfactorily performed. Further, by virtue of the above-mentioned range, when each of the components is dissolved in an organic solvent, an uniform solution can be obtained and the storage stability becomes satisfactory.

[Component (D)]

Moreover, the resist composition of the present embodiment may include an acid diffusion control agent component (hereafter, referred to as “component (D)”), in addition to the component (A), or in addition to the component (A) and the component (B).

The component (D) functions as an acid diffusion control agent, i.e., a quencher which traps the acid generated from the component (A), the component (B) and the like upon exposure.

The component (D) may be a photodecomposable base (D1) (hereafter, referred to as “component (D1)”) which is decomposed upon exposure and then loses the ability of controlling of acid diffusion, or a nitrogen-containing organic compound (D2) (hereafter, referred to as “component (D2)”) which does not fall under the definition of component (D1).

—Component (D1)

When a resist pattern is formed using a resist composition containing the component (D1), the contrast between exposed portions and unexposed portions is improved.

The component (D1) is not particularly limited, as long as it is decomposed upon exposure and then loses the ability of controlling of acid diffusion. As the component (D1), at least one compound selected from the group consisting of a compound represented by general formula (d1-1) shown below (hereafter, referred to as “component (d1-1)”), a compound represented by general formula (d1-2) shown below (hereafter, referred to as “component (d1-2)”) and a compound represented by general formula (d1-3) shown below (hereafter, referred to as “component (d1-3)”) is preferably used.

At exposed portions, the components (d1-1) to (d1-3) are decomposed and then lose the ability of controlling of acid diffusion (i.e., basicity), and therefore the components (d1-1) to (d1-3) cannot function as a quencher, whereas at unexposed portions, the components (d1-1) to (d1-3) function as a quencher.

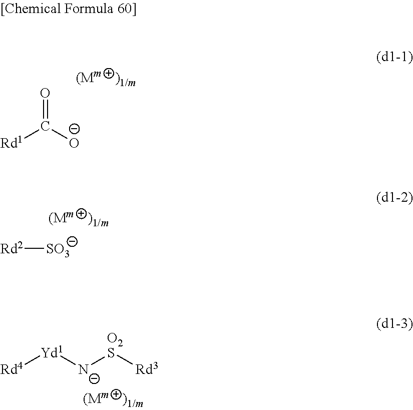

In the formulae, Rd¹ to Rd⁴ represents a cyclic group which may have a substituent, a chain-like alkyl group which may have a substituent or a chain-like alkenyl group which may have a substituent; provided that, in the formula (d1-2), the carbon atom within the Rd² adjacent to the sulfur atom has no fluorine atom bonded thereto; Yd¹ represents a single bond or a divalent linking group; m represents an integer of 1 or more; and M^{m+} each independently represents an organic cation having a valency of m.

{Component (d 1-1)} . . . Anion Moiety

In formula (d1-1), Rd¹ represents a cyclic group which may have a substituent, a chain-like alkyl group which may have a substituent or a chain-like alkenyl group which may have a substituent, and is the same groups as those defined above for R¹⁰¹ in the formula (b-1).

Among these, as the group for Rd¹, an aromatic hydrocarbon group which may have a substituent, an aliphatic cyclic group which may have a substituent and a chain-like alkyl group which may have a substituent are preferable. As the substituents which these groups may have, a hydroxy group, a fluorine atom or a fluorinated alkyl group is preferable.

The aromatic hydrocarbon group is more preferably a phenyl group or a naphthyl group.

Examples of the aliphatic cyclic group include groups in which one or more hydrogen atoms have been removed from a polycycloalkane such as adamantane, norbornane, isobornane, tricyclodecane or tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

When the chain-like alkyl group is a fluorinated alkyl group containing a fluorine atom or a fluorinated alkyl group as a substituent, the fluorinated alkyl group preferably has 1 to 11 carbon atoms, more preferably 1 to 8, and still more preferably 1 to 4. The fluorinated alkyl group may contain an atom other than fluorine. Examples of the atom other than fluorine include an oxygen atom, a carbon atom, a hydrogen atom, a sulfur atom and a nitrogen atom.

As for Rd¹, a fluorinated alkyl group in which part or all of the hydrogen atoms constituting a linear alkyl group have been substituted with fluorine atom(s) is preferable, and a fluorinated alkyl group in which all of the hydrogen atoms constituting a linear alkyl group have been substituted with fluorine atoms (i.e., a linear perfluoroalkyl group) is more preferable.

Specific examples of preferable anion moieties for the component (d1-1) are shown below.

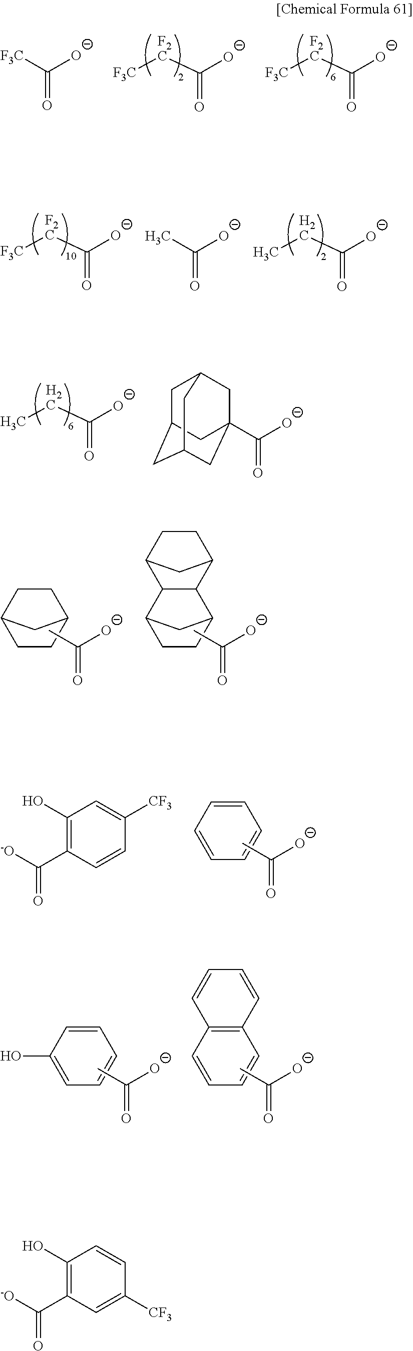

. . . Cation Moiety

In formula (d1-1), M^{m+} represents an organic cation having a valency of m.

Examples of the organic cation for M^{m+} include the same cation moieties as those for M^{m+} in the formulae (a6a-1) to (a6a-8), cation moieties represented by the aforementioned formulae (ca-1) to (ca-4) are preferable, and cation moieties represented by the aforementioned formulae (ca-1-1) to (ca-1-67) are more preferable.

As the component (d1-1), one type of compound may be used, or two or more types of compounds may be used in combination.

{Component (d1-2)} . . . Anion Moiety

In formula (d1-2), Rd² represents a cyclic group which may have a substituent, a chain-like alkyl group which may have a substituent or a chain-like alkenyl group which may have a substituent, and is the same groups as those defined above for R¹⁰¹ in the formula (b-1),

provided that, the carbon atom within Rd² group adjacent to the sulfur atom has no fluorine atom bonded thereto (i.e., the carbon atom within Rd² group adjacent to the sulfur atom does not substituted with a fluorine atom). As a result, the anion of the component (d1-2) becomes an appropriately weak acid anion, thereby improving the quenching ability of the component (D).

As Rd², an aliphatic cyclic group which may have a substituent is preferable, and a group in which one or more hydrogen atoms have been removed from adamantane, norbornane, isobornane, tricyclodecane or tetracyclododecane (which may have a substituent); or a group in which one or more hydrogen atoms have been removed from camphor is more preferable.

The hydrocarbon group for Rd² may have a substituent. As the substituent, the same groups as those described above for substituting the hydrocarbon group (e.g., aromatic hydrocarbon group, aliphatic hydrocarbon group) for Rd¹ in the formula (d1-1) can be mentioned.

Specific examples of preferable anion moieties for the component (d1-2) are shown below.

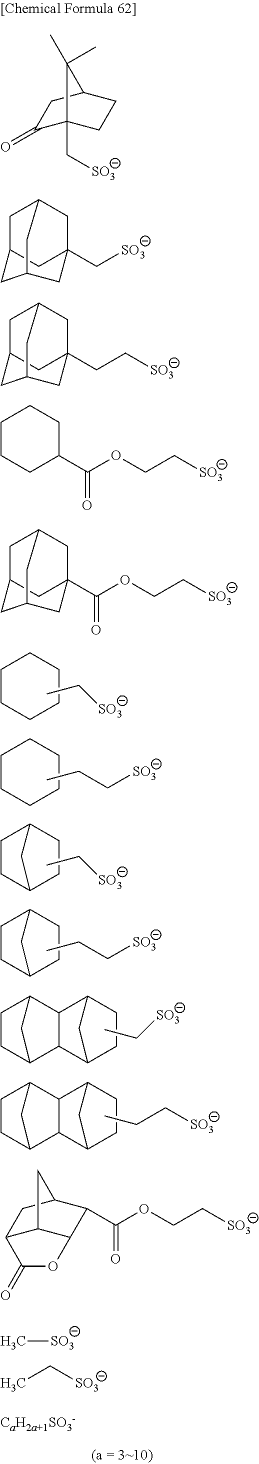

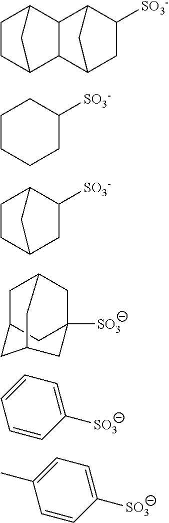

. . . Cation Moiety

In formula (d1-2), M^{m+} is an organic cation having a valency of m, and is the same as defined for M^{m+} in the aforementioned formula (d1-1).

As the component (d1-2), one type of compound may be used, or two or more types of compounds may be used in combination.

{Component (d1-3)} . . . Anion Moiety

In formula (d1-3), Rd³ represents a cyclic group which may have a substituent, a chain-like alkyl group which may have a substituent or a chain-like alkenyl group which may have a substituent, and is the same groups as those defined above for R¹⁰¹ in the formula (b-1), and a cyclic group containing a fluorine atom, a chain-like alkyl group containing a fluorine atom or a chain-like alkenyl group containing a fluorine atom is preferable. Among these, a fluorinated alkyl group is preferable, and more preferably the same fluorinated alkyl groups as those described above for Rd¹.

In formula (d1-3), Rd⁴ represents a cyclic group which may have a substituent, a chain-like alkyl group which may have a substituent or a chain-like alkenyl group which may have a substituent, and is the same groups as those defined above for R¹⁰¹ in the formula (b-1).

Among these, an alkyl group which may have substituent, an alkoxy group which may have substituent, an alkylene group which may have substituent or a cyclic group which may have substituent is preferable.

The alkyl group for Rd⁴ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are desirable.

As the alkenyl group for Rd⁴, the same groups as those described above for R¹⁰¹ in the formula (b-1) can be mentioned, and a vinyl group, a propenyl group (an allyl group), a 1-methylpropenyl group and a 2-methylpropenyl group are preferable. These groups may have an alkyl group of 1 to 5 carbon atoms or a halogenated alkyl group of 1 to 5 carbon atoms as a substituent.

As the cyclic group for Rd⁴, the same groups as those described above for R¹⁰¹ in the formula (b-1) can be mentioned. Among these, as the cyclic group, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When Rd⁴ is an alicyclic group, the resist composition can be satisfactorily dissolved in an organic solvent, thereby improving the lithography properties. Alternatively, when Rd⁴ is an aromatic group, the resist composition exhibits an excellent photoabsorption efficiency in a lithography process using EUV or the like as the exposure source, thereby resulting in the improvement of the sensitivity and the lithography properties.

In formula (d1-3), Yd¹ represents a single bond or a divalent linking group.

The divalent linking group for Yd¹ is not particularly limited, and examples thereof include a divalent hydrocarbon group (aliphatic hydrocarbon group, or aromatic hydrocarbon group) which may have a substituent and a divalent linking group containing a hetero atom. As these groups, the same groups as those described above for the divalent hydrocarbon group which may have a substituent and the divalent linking group containing a hetero atom in the explanation of the divalent linking group for Ya²¹ in the formula (a2-1) can be mentioned.

As Yd¹, a carbonyl group, an ester bond, an amide bond, an alkylene group or a combination of these groups is preferable. As the alkylene group, a linear or branched alkylene group is more preferable, and a methylene group or an ethylene group is still more preferable.

Specific examples of preferable anion moieties for the component (d1-3) are shown below.

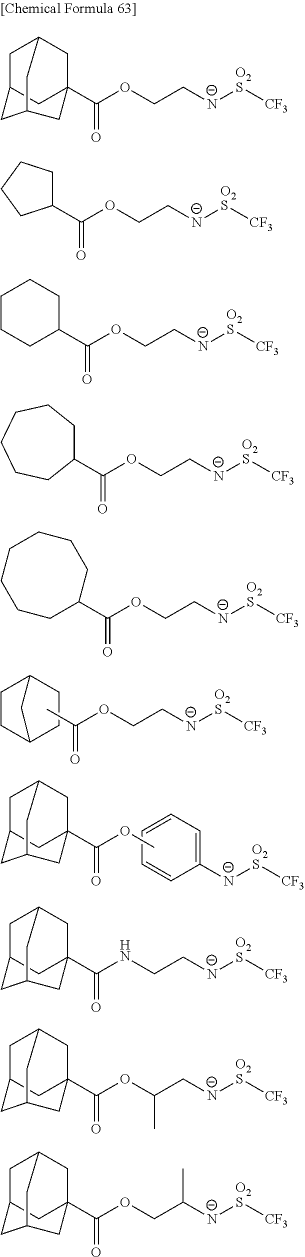

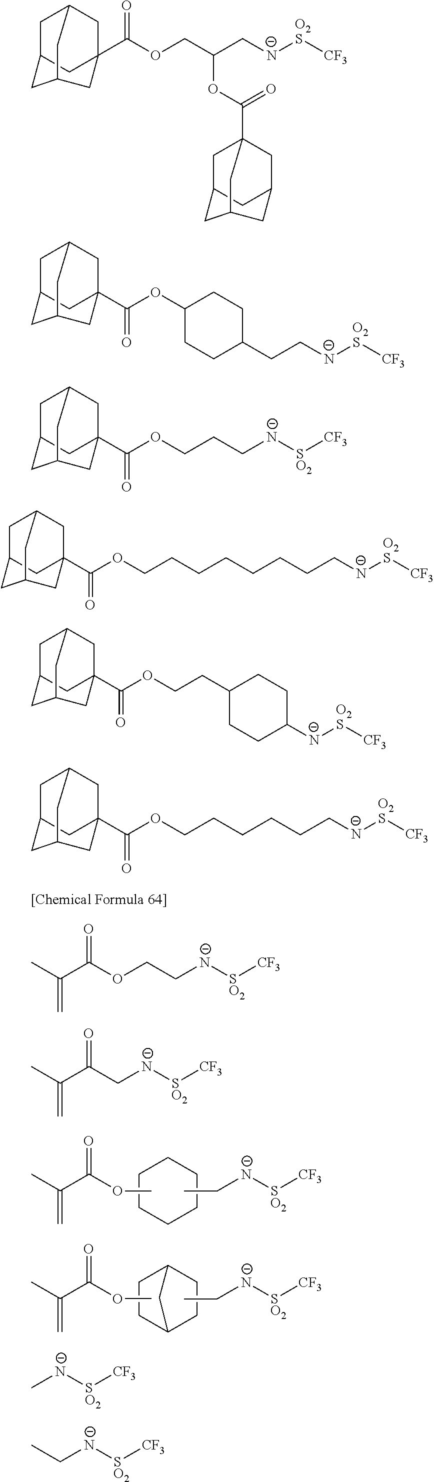

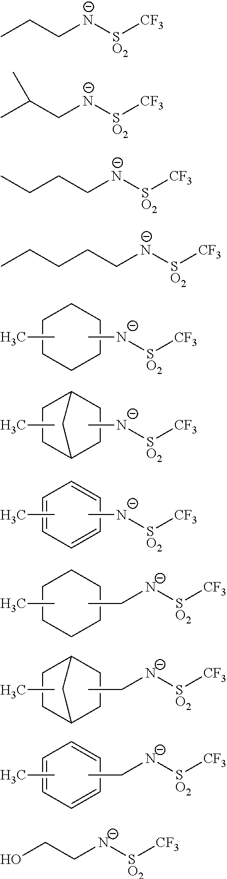

. . . Cation Moiety

In formula (d1-3), M^{m+} is an organic cation having a valency of m, and is the same as defined for M^{m+} in the aforementioned formula (d1-1).

As the component (d1-3), one type of compound may be used, or two or more types of compounds may be used in combination.

As the component (D1), one type of the aforementioned components (d1-1) to (d1-3) can be used, or at least two types of the aforementioned components (d1-1) to (d1-3) can be used in combination.

The amount of the component (D1) relative to 100 parts by weight of the component (A) is preferably within a range from 0.5 to 10 parts by weight, more preferably from 0.5 to 8 parts by weight, and still more preferably from 1 to 8 parts by weight.

When the amount of the component (D1) is at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and through-put becomes excellent.

(Production Method of Components (D1))

The production methods of the components (d1-1) and (d1-2) are not particularly limited, and the components (d1-1) and (d1-2) can be produced by conventional methods.

The production methods of the component (d1-3) are not particularly limited, and for example, the component (d1-3) can be produced by a method described in US2012-0149916.

—Component (D2)

The acid diffusion control agent component may contain a nitrogen-containing organic compound (D2) (hereafter, referred to as “component (D2)”) which does not fall under the definition of component (D1).

The component (D2) is not particularly limited, as long as it functions as an acid diffusion control agent, and does not fall under the definition of the component (D1). As the component (D2), any of the conventionally known compounds may be selected for use. Among these, an aliphatic amine is preferable, and a secondary aliphatic amine or tertiary aliphatic amine is particularly preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris {2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include 4-dimethylaminopyridine, pyrrole, indole, pyrazole, imidazole and derivatives thereof, as well as tribenzylamine, 2,6-diisopropylaniline and N-tert-butoxycarbonylpyrrolidine.

As the component (D2), one type of compound may be used alone, or two or more types may be used in combination.

The component (D2) is typically used in an amount within a range from 0.01 to 5 parts by weight, relative to 100 parts by weight of the component (A). When the amount of the component (D2) is within the above-mentioned range, the shape of the resist pattern and the post exposure stability of the latent image formed by the pattern-wise exposure of the resist layer are improved.

[Component (E)]

Furthermore, in the resist composition of the present embodiment, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added as an optional component.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorous oxo acid derivatives include esters in which a hydrogen atom within the above-mentioned phosphorous oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phenylphosphinic acid and phosphinic acid esters.

As the component (E), one type may be used alone, or two or more types may be used in combination.

The component (E) is typically used in an amount within a range from 0.01 to 5 parts by weight, relative to 100 parts by weight of the component (A).

[Component (F)]

In the present invention, the resist composition of the present embodiment may further include a fluorine additive (hereafter, referred to as “component (F)”) for imparting water repellency to the resist film.

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used.

Specific examples of the component (F) include polymers having a structural unit (f1) represented by general formula (f1-1) shown below. As the polymer, a polymer (homopolymer) consisting of a structural unit (f1) represented by formula (f1-1) shown below; a copolymer of a structural unit (f1) and the aforementioned structural unit (a1); and a copolymer of a structural unit (f1), a structural unit derived from acrylic acid or methacrylic acid and the aforementioned structural unit (a1) are preferable. As the structural unit (a1) to be copolymerized with a structural unit (f1), a structural unit derived from 1-ethyl-1-cyclooctyl(meth)acrylate is preferable.

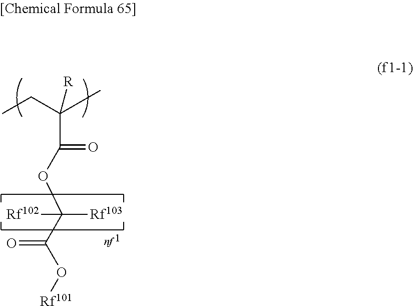

In the formula, R is the same as defined above; Rf¹⁰² and Rf¹⁰³ each independently represents a hydrogen atom, a halogen atom, an alkyl group of 1 to 5 carbon atoms, or a halogenated alkyl group of 1 to 5 carbon atoms, provided that Rf¹⁰² and Rf¹⁰³ may be the same or different; nf¹ represents an integer of 1 to 5; and Rf¹⁰¹ represents an organic group containing a fluorine atom.

In formula (f1-1), R bonded to the carbon atom on the α-position is the same as defined above. As R, a hydrogen atom or a methyl group is preferable.

In formula (f1-1), examples of the halogen atom for Rf¹⁰² and Rf¹⁰³ include a fluorine atom, a chlorine atom, a bromine atom and an iodine atom, and a fluorine atom is particularly desirable. Examples of the alkyl group of 1 to 5 carbon atoms for Rf¹⁰² and Rf¹⁰³ include the same alkyl group of 1 to 5 carbon atoms as those described above for R, and a methyl group or an ethyl group is preferable. Specific examples of the halogenated alkyl group of 1 to 5 carbon atoms represented by Rf¹⁰² and Rf¹⁰³ include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly desirable. Among these, as Rf¹⁰² and Rf¹⁰³, a hydrogen atom, a fluorine atom or an alkyl group of 1 to 5 carbon atoms is preferable, and a hydrogen atom, a fluorine atom, a methyl group or an ethyl group is more preferable.

In formula (f1-1), nf¹⁰¹ represents an integer of 1 to 5, preferably an integer of 1 to 3, and more preferably 1 or 2.

In formula (f1-1), R¹⁰¹ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and most preferably 1 to 10 carbon atoms.

It is preferable that the hydrocarbon group having a fluorine atom has 25% or more of the hydrogen atoms within the hydrocarbon group fluorinated, more preferably 50% or more, and most preferably 60% or more, as the hydrophobicity of the resist film during immersion exposure is enhanced.

Among these, as R¹⁰¹, a fluorinated hydrocarbon group of 1 to 5 carbon atoms is preferable, and a trifluoromethyl group, —CH₂—CF₃, —CH₂—CF₂—CF₃, —CH(CF₃)₂, —CH₂—CH₂—CF₃ and —CH₂—CH₂—CF₂—CF₂—CF₂—CF₃ are most preferable.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

As the component (F), one type may be used alone, or two or more types may be used in combination.

The component (F) is typically used in an amount within a range from 0.5 to 10 parts by weight, relative to 100 parts by weight of the component (A).

If desired, other miscible additives can also be added to the resist composition of the present embodiment. Examples of such miscible additives include additive resins for improving the performance of the resist film, dissolution inhibitors, plasticizers, stabilizers, colorants, halation prevention agents, and dyes.

[Component (S)]

The resist composition according to the present embodiment can be prepared by dissolving the resist materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone (MEK), cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, PGMEA, PGME, γ-butyrolactone, EL and cyclohexanone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL or cyclohexanone is mixed as the polar solvent, the PGMEA:EL weight ratio or PGMEA:cyclohexanone weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3. Furthermore, a mixed solvent of PGMEA, PGME and cyclohexanone is also preferable.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate. In general, the organic solvent is used in an amount such that the solid content of the resist composition becomes within the range from 1 to 20% by weight, and preferably from 2 to 15% by weight.

According to the resist composition of the first aspect of the present invention, excellent lithography properties such as resolution and exposure latitude can be achieved, when a resist pattern is formed by EUV exposure or EB exposure. Further, the roughness can be reduced, the rectangularity of the cross-sectional shape of the resist pattern can be improved (i.e., the perpendicularity of the side wall of the pattern can be improved), and a resist pattern having an excellent shape can be formed.

The resist composition of this embodiment includes the polymeric compound (A1) as a base resin, which contains the structural unit (a0) and the structural unit (a6).

The structural unit (a0) contains an aryl group)(Ra⁰) having a bulky structure, and an acid decomposable group which is readily dissociated by the action of acid during EUV exposure or EB exposure. Further, since the structural unit (a0) has a bulky structure, thickness loss during development can be suppressed.

The structural unit (a6) has an acid generating portion which generates acid upon exposure. Further, since the component (A1) is a polymeric compound, each of structural units constituting the component (A1) can be uniformly distributed within a resist film. As a result, in the formation of a resist film, acid generates from the structural unit (a6) upon exposure uniformly at exposed portions of a resist film. Further, by shortening the diffusion length of the generated acid, the acid generated at exposed portions is suppressed from being diffused to unexposed portions.

By virtue of the synergistic effect of the structural unit (a0) and structural unit (a6) each exhibiting such an effect, the influence from flare due to EUV exposure apparatus and blur due to EB can be suppressed.

As a result, an excellent contrast between exposed portions and unexposed portions of a resist film can be reliably obtained. Furthermore, thickness loss of the resist film can be suppressed, roughness on the side wall surfaces of a pattern can be reduced, and therefore, a resist pattern with high rectangularity can be obtained.

Further, the acid decomposable group in the structural unit (a0) has a bulky structure. The acid decomposable group is less likely to be vaporized after dissociation. Therefore, by using the resist composition of this embodiment, outgas can be suppressed during formation of a resist pattern, and contamination and the like of the exposure apparatus can be reduced. Furthermore, the structural unit (a0) has an aryl group)(Ra⁰) having a dense structure. Therefore, by using the resist composition of this embodiment, the etching rate can be improved and etching resistance can be enhanced.

EUV lithography and EB lithography is aiming the formation of a fine pattern having a size of several nanometers order to several tens of nanometers order. Therefore, the resist composition of this embodiment, which has an excellent effect of suppressing thickness loss and an excellent effect of reducing roughness, is extremely useful for EUV or EB.

<<Method of Forming a Resist Pattern>>

The method of forming a resist pattern of the second aspect of the present invention, including forming a resist film on a substrate using a resist composition for EUV or EB according to the present invention, subjecting the resist film to irradiate with EUV or EB, and subjecting the resist film to developing to form a resist pattern.

The method for forming a resist pattern according to the present embodiment can be performed, for example, as follows.

Firstly, a resist composition of the present embodiment is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by irradiating with EUV or EB through a mask having a predetermined pattern formed thereon (mask pattern) using an exposure apparatus such as an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment. In the case of an alkali developing process, an alkali developing solution such as a 0.1 to 10% by weight aqueous solution of tetramethylammonium hydroxide (TMAH) is used to perform an alkali developing treatment. Alternatively, in the case of a solvent developing process, an organic solvent is used to perform a developing treatment.

After the developing treatment, it is preferable to conduct a rinse treatment. In the case of an alkali developing process, it is preferable to conduct a water rinse using pure water. In the case of a solvent developing process, it is preferable to use a rinse liquid containing the aforementioned organic solvent.

Thereafter, drying is conducted. If desired, bake treatment (post bake) can be conducted following the developing.

In this manner, a resist pattern can be obtained. In particular, the resist composition of the present embodiment is preferably used in a method of forming a positive-tone resist pattern in an alkali developing process.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic anti-reflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film is formed (triple-layer resist method).

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which preferably have a boiling point within a range from 70 to 180° C. and more preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used, which are capable of dissolving the component (A) (prior to exposure). Specific examples of the organic solvent include polar solvents such as ketone solvents, ester solvents, alcohol solvents, amide solvents and ether solvents, and hydrocarbon solvents. Among these, ester solvents are preferable. As an ester solvent, butyl acetate is preferable.

If desired, the organic developing solution may have a conventional additive blended. Examples of the additive include surfactants. The surfactant is not particularly limited, and for example, an ionic or non-ionic fluorine and/or silicone surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly desirable.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

In the following examples, a compound represented by a chemical formula (I) is designated as “compound (I)”, and the same applies for compounds represented by other chemical formulae.

<Preparation of Base Component>

The polymeric compounds used as the base component in the present examples were synthesized by copolymerizing the compounds represented by the chemical formulae shown below as monomers in a predetermined molar ratio by a conventional radical polymerization method.

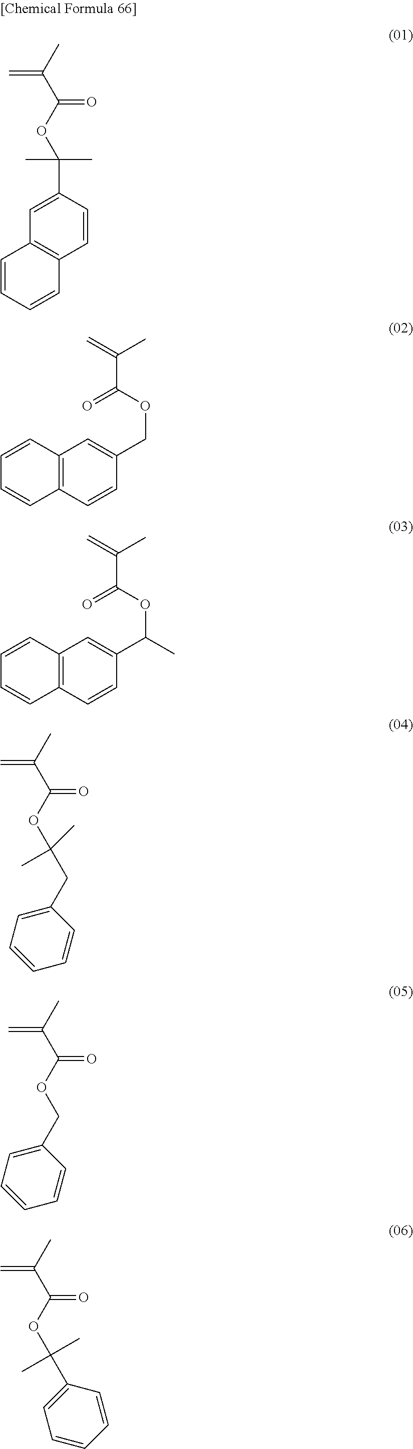

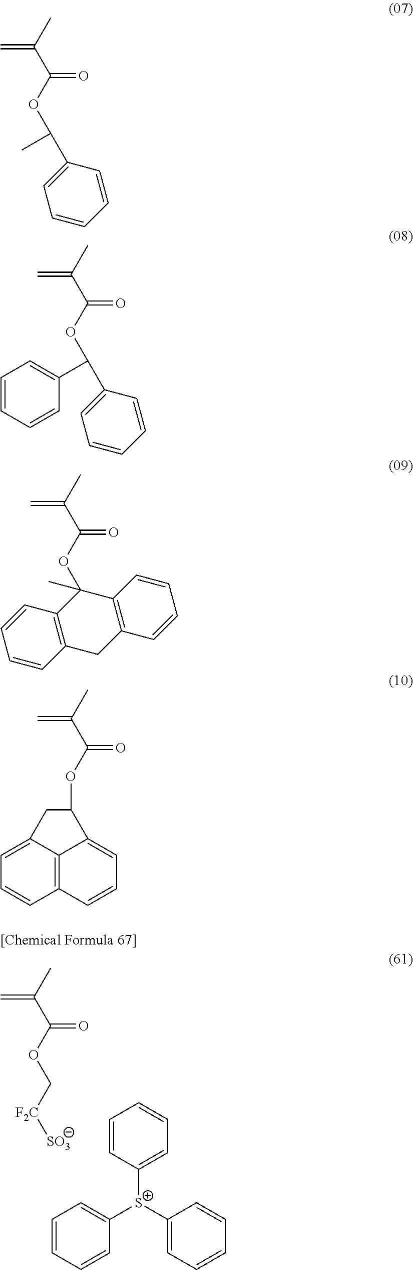

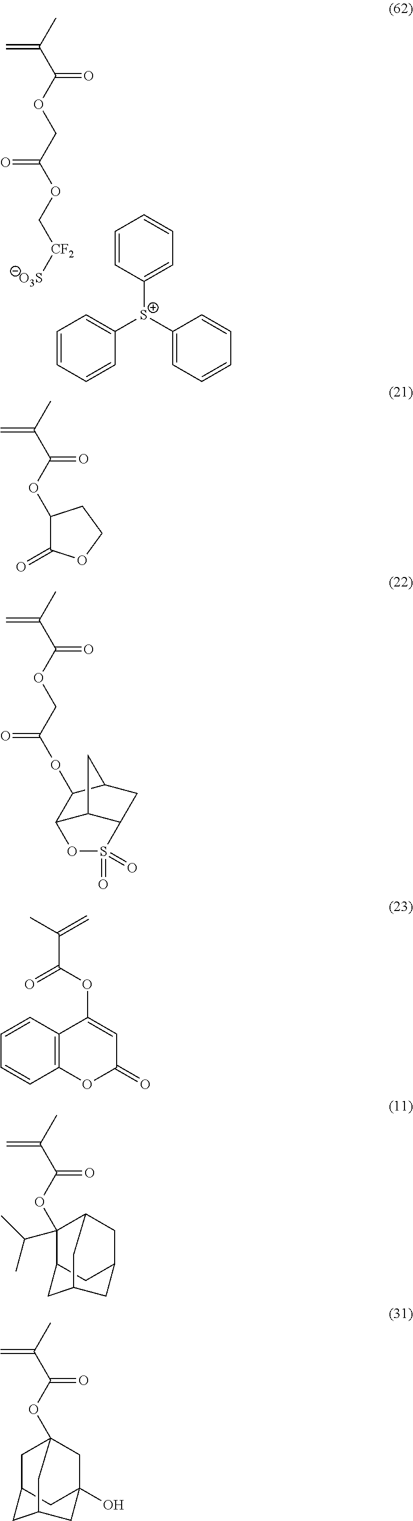

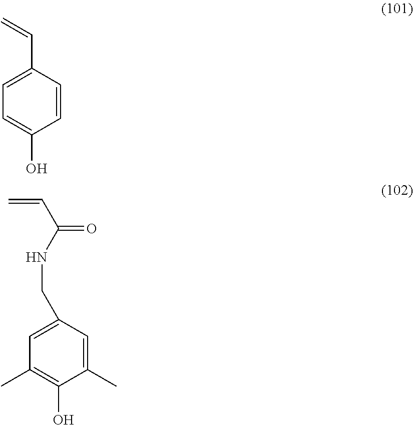

With respect to each of the obtained polymeric compounds A-1 to A-22 and A′-1 to A′-8, the compositional ratio of the polymeric compound (ratio (molar ratio) of the respective structural units within the structure) as determined by ¹³C-NMR, and the weight average molecular weight (Mw) and the dispersity (Mw/Mn) determined by the polystyrene equivalent value as measured by GPC are shown in Table 1.

TABLE 1

| Polymeric | | | | |
|---|---|---|---|---|
| compound | Composition of monomers | Molar ratio | Mw | Mw/Mn |
| A-1 | (21)/(01)/(31)/(61) | 35/33/18/14 | 6600 | 2.56 |
| A-2 | (21)/(01)/(61) | 44/42/14 | 7000 | 2.60 |
| A-3 | (22)/(01)/(31)/(61) | 35/33/18/14 | 6600 | 2.31 |
| A-4 | (22)/(01)/(61) | 44/42/14 | 6800 | 2.60 |
| A-5 | (21)/(01)/(31)/(62) | 35/33/18/14 | 6800 | 2.49 |
| A-6 | (21)/(01)/(62) | 44/42/14 | 7300 | 2.51 |
| A-7 | (22)/(01)/(31)/(62) | 35/33/18/14 | 7000 | 2.35 |
| A-8 | (22)/(01)/(62) | 44/42/14 | 6900 | 2.55 |
| A-9 | (21)/(02)/(31)/(61) | 35/33/18/14 | 7300 | 2.55 |
| A-10 | (21)/(03)/(31)/(61) | 35/33/18/14 | 7300 | 2.39 |
| A-11 | (21)/(04)/(31)/(61) | 35/33/18/14 | 7100 | 2.41 |
| A-12 | (21)/(05)/(31)/(61) | 35/33/18/14 | 7300 | 2.50 |
| A-13 | (21)/(06)/(31)/(61) | 35/33/18/14 | 7500 | 2.50 |
| A-14 | (21)/(07)/(31)/(61) | 35/33/18/14 | 6800 | 2.51 |
| A-15 | (21)/(08)/(31)/(61) | 35/33/18/14 | 7300 | 2.45 |
| A-16 | (21)/(09)/(31)/(61) | 35/33/18/14 | 6700 | 2.39 |
| A-17 | (21)/(10)/(31)/(61) | 35/33/18/14 | 7000 | 2.41 |
| A-18 | (101)/(01)/(61) | 60/30/10 | 6500 | 2.56 |
| A-19 | (102)/(01)/(61) | 60/30/10 | 6800 | 2.59 |
| A-20 | (102)/(101)/(01)/(61) | 30/30/30/10 | 7200 | 2.43 |
| A-21 | (23)/(01)/(61) | 60/30/10 | 6900 | 2.61 |
| A-22 | (23)/(101)/(01)/(61) | 30/30/30/10 | 7500 | 2.44 |
| A′-1 | (101)/(01) | 70/30 | 6600 | 2.50 |
| A′-2 | (101)/(01) | 60/40 | 6600 | 2.41 |
| A′-3 | (21)/(01)/(31) | 40/40/20 | 6500 | 2.59 |
| A′-4 | (21)/(02)/(31) | 40/40/20 | 7300 | 2.60 |
| A′-5 | (21)/(03)/(31) | 40/40/20 | 7300 | 2.55 |
| A′-6 | (22)/(01)/(31) | 40/40/20 | 7500 | 2.61 |
| A′-7 | (22)/(11)/(61) | 44/42/14 | 7100 | 2.51 |
| A′-8 | (22)/(11)/(31)/(61) | 35/33/18/14 | 6900 | 2.55 |

### Production of Resist Composition

### Examples 1 to 22, Comparative Examples 1 to 8

The components shown in Tables 2 to 4 were mixed together and dissolved to obtain resist compositions.

TABLE 2

| | (A) | (D) | (E) | (S) | | | |
|---|---|---|---|---|---|---|---|
| Example 1 | (A)-1 | (D)-1 | (E)-1 | (S)-1 | (S)-2 | (S)-3 | (S)-4 |
| | [100] | [1.6] | [0.64] | [100] | [1500] | [1000] | [2500] |
| Example 2 | (A)-2 | (D)-1 | (E)-1 | (S)-1 | (S)-2 | (S)-3 | (S)-4 |
| | [100] | [1.6] | [0.64] | [100] | [1500] | [1000] | [2500] |
| Example 3 | (A)-3 | (D)-1 | (E)-1 | (S)-1 | (S)-2 | (S)-3 | (S)-4 |
| | [100] | [1.6] | [0.64] | [100] | [1500] | [1000] | [2500] |
| Example 4 | (A)-4 | (D)-1 | (E)-1 | (S)-1 | (S)-2 | (S)-3 | (S)-4 |
| | [100] | [1.6] | [0.64] | [100] | [1500] | [1000] | [2500] |
| Example 5 | (A)-5 | (D)-1 | (E)-1 | (S)-1 | (S)-2 | (S)-3 | (S)-4 |
| | [100] | [1.6] | [0.64] | [100] | [1500] | [1000] | [2500] |
| Example 6 | (A)-6 | (D)-1 | (E)-1 | (S)-1 | (S)-2 | (S)-3 | (S)-4 |
| | [100] | [1.6] | [0.64] | [100] | [1500] | [1000] | [2500] |
| Example 7 | (A)-7 | (D)-1 | (E)-1 | (S)-1 | (S)-2 | (S)-3 | (S)-4 |
| | [100] | [1.6] | [0.64] | [100] | [1500] | [1000] | [2500] |
| Example 8 | (A)-8 | (D)-1 | (E)-1 | (S)-1 | (S)-2 | (S)-3 | (S)-4 |
| | [100] | [1.6] | [0.64] | [100] | [1500] | [1000] | [2500] |

TABLE 3

| | (A) | (D) | (E) | (S) | | | |
|---|---|---|---|---|---|---|---|
| Example 9 | (A)-9 | (D)-1 | (E)-1 | (S)-1 | (S)-2 | (S)-3 | (S)-4 |
| | [100] | [1.6] | [0.64] | [100] | [1500] | [1000] | [2500] |
| Example | (A)-10 | (D)-1 | (E)-1 | (S)-1 | (S)-2 | (S)-3 | (S)-4 |
| 10 | [100] | [1.6] | [0.64] | [100] | [1500] | [1000] | [2500] |
| Example | (A)-11 | (D)-1 | (E)-1 | (S)-1 | (S)-2 | (S)-3 | (S)-4 |
| 11 | [100] | [1.6] | [0.64] | [100] | [1500] | [1000] | [2500] |
| Example | (A)-12 | (D)-1 | (E)-1 | (S)-1 | (S)-2 | (S)-3 | (S)-4 |
| 12 | [100] | [1.6] | [0.64] | [100] | [1500] | [1000] | [2500] |
| Example | (A)-13 | (D)-1 | (E)-1 | (S)-1 | (S)-2 | (S)-3 | (S)-4 |
| 13 | [100] | [1.6] | [0.64] | [100] | [1500] | [1000] | [2500] |
| Example | (A)-14 | (D)-1 | (E)-1 | (S)-1 | (S)-2 | (S)-3 | (S)-4 |
| 14 | [100] | [1.6] | [0.64] | [100] | [1500] | [1000] | [2500] |
| Example | (A)-15 | (D)-1 | (E)-1 | (S)-1 | (S)-2 | (S)-3 | (S)-4 |
| 15 | [100] | [1.6] | [0.64] | [100] | [1500] | [1000] | [2500] |
| Example | (A)-16 | (D)-1 | (E)-1 | (S)-1 | (S)-2 | (S)-3 | (S)-4 |
| 16 | [100] | [1.6] | [0.64] | [100] | [1500] | [1000] | [2500] |
| Example | (A)-17 | (D)-1 | (E)-1 | (S)-1 | (S)-2 | (S)-3 | (S)-4 |
| 17 | [100] | [1.6] | [0.64] | [100] | [1500] | [1000] | [2500] |
| Example | (A)-18 | (D)-1 | (E)-1 | (S)-1 | (S)-2 | (S)-3 | (S)-4 |
| 18 | [100] | [1.6] | [0.64] | [100] | [1500] | [1000] | [2500] |
| Example | (A)-19 | (D)-1 | (E)-1 | (S)-1 | (S)-2 | (S)-3 | (S)-4 |
| 19 | [100] | [1.6] | [0.64] | [100] | [1500] | [1000] | [2500] |
| Example | (A)-20 | (D)-1 | (E)-1 | (S)-1 | (S)-2 | (S)-3 | (S)-4 |
| 20 | [100] | [1.6] | [0.64] | [100] | [1500] | [1000] | [2500] |
| Example | (A)-21 | (D)-1 | (E)-1 | (S)-1 | (S)-2 | (S)-3 | (S)-4 |
| 21 | [100] | [1.6] | [0.64] | [100] | [1500] | [1000] | [2500] |
| Example | (A)-22 | (D)-1 | (E)-1 | (S)-1 | (S)-2 | (S)-3 | (S)-4 |
| 22 | [100] | [1.6] | [0.64] | [100] | [1500] | [1000] | [2500] |

TABLE 4

| | (A′) | (B) | (D) | (E) | (S) | | | |
|---|---|---|---|---|---|---|---|---|
| Comparative Example 1 | (A′)-1 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 2 | (A′)-2 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 3 | (A′)-3 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 4 | (A′)-4 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 5 | (A′)-5 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 6 | (A′)-6 | (B)-1 | (D)-1 | (E)-1 | (S)-1 | (S)-2 | (S)-3 | (S)-4 |
| | [100] | [38.6] | [1.6] | [0.64] | [100] | [1500] | [1000] | [2500] |
| Comparative Example 7 | (A′)-7 | — | (D)-1 | (E)-1 | (S)-1 | (S)-2 | (S)-3 | (S)-4 |
| | [100] | | [1.6] | [0.64] | [100] | [1500] | [1000] | [2500] |
| Comparative Example 8 | (A′)-8 | — | (D)-1 | (E)-1 | (S)-1 | (S)-2 | (S)-3 | (S)-4 |
| | [100] | | [1.6] | [0.64] | [100] | [1500] | [1000] | [2500] |

In Tables 2 to 4, the reference characters indicate the following. The values in brackets [ ] indicate the amount (in terms of parts by weight) of the component added.

(A)-1 to (A)-22: polymeric compounds A-1 to A-22 shown in Table 1

(A′)-1 to (A′)-8: polymeric compounds A′-1 to A′-8 shown in Table 1

(B)-1: an acid generator consisting of a compound represented by chemical formula (B)-1 shown below

(D)-1: tri-n-octylamine

(E)-1: salicylic acid

(S)-1: γ-butyrolactone

(S)-2: propyleneglycol monomethyletheracetate

(S)-3: propylene glycol monomethyl ether

(S)-4: cyclohexanone

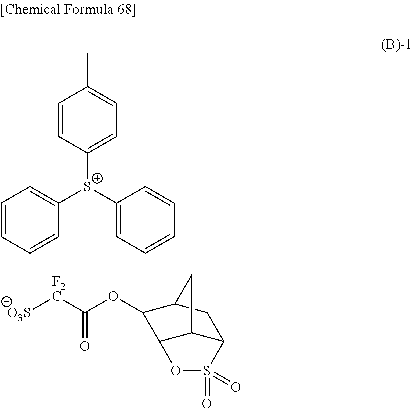

Using the obtained resist compositions, the evaluations of thickness loss, sensitivity, exposure latitude, line width roughness (LWR), resolution and shape of the resist pattern were conducted as follows.

[Evaluation of Thickness Loss]

Using a spinner, each of the resist compositions was uniformly applied to an 8-inch silicon wafer that had been treated with hexamethyldisilazane (HMDS) at 90° C. for 36 seconds, and subjected to heat treatment on a hotplate at 100° C. for 60 seconds.

The obtained resist film was immersed in a 2.38% by weight aqueous solution of tetramethylammonium hydroxide for 240 seconds, and then the dissolution rate (Rₘᵢₙ: [amount of thickness loss]/[immersion time], unit: nm/s) was determined. The results are shown in Table 5.

The smaller the value of Rₘᵢₙ, the more the thickness loss is suppressed.

<Formation of Resist Pattern>

Using a spinner, each resist composition was uniformly applied to an 8-inch silicon wafer that had been treated with hexamethyldisilazane (HMDS) at 90° C. for 36 seconds, and subjected to a prebake treatment (PAB) at a heating temperature indicated in Table 5 for 60 seconds, thereby forming a resist film (film thickness: 50 nm).

Subsequently, the resist film was subjected to drawing (exposure) using an electron beam lithography apparatus JEOL JBX-9300FS (manufactured by JEOL Ltd.) at an acceleration voltage of 100 kV (Beam current: 100 pA, Scan step: 4 nm), to form a dense line and space pattern with a target pattern having a line width of 50 nm and a pitch of 100 nm.

Thereafter, a bake (PEB) treatment was conducted at a heating temperature indicated in Table 5 for 60 seconds, followed by development for 60 seconds at 23° C. in a 2.38% by weight aqueous solution of tetramethylammonium hydroxide (TMAH) (trade name: NMD-3; manufactured by Tokyo Ohka Kogyo Co., Ltd.). Thereafter, water rinsing was conducted for 15 seconds using pure water, followed by drying by shaking.

As a result, in each of the examples, a dense line and space resist pattern (dense LS pattern) having a line width of 50 nm and a pitch of 100 nm was formed.

[Evaluation of Sensitivity]

With respect to each of the resist compositions, the optimum exposure dose Eop (μC/cm²) with which the dense pattern was formed was determined. The results are shown in Table 5.

[Evaluation of Exposure Latitude (EL Margin)]

In the aforementioned formation of a dense LS pattern, the exposure dose with which an LS pattern was formed to have a dimension of the target dimension ±5% (i.e., 47.5 nm to 52.5 nm) was determined, and the EL margin (unit: %) was determined by the following formula. The results are shown in Table 5.

EL margin (%)=(|E1−E2|/Eop)×100

In the formula, E1 represents the exposure dose (μC/cm²) for forming an LS pattern having a line width of 47.5 nm, and E2 represents the exposure dose (μC/cm²) for forming an LS pattern having a line width of 52.5 nm.

The larger the value of EL margin, the smaller the change in the pattern size due to the variation of the exposure dose, thereby resulting in a favorable improvement in the process margin.

[Evaluation of Line Width Roughness (LWR)]

With respect to each of the dense LS patterns formed in the <Formation of resist pattern>, the space width at 400 points in the lengthwise direction of the space was measured using a measuring scanning electron microscope (SEM) (product name: S-9380, manufactured by Hitachi High-Technologies Corporation; acceleration voltage: 300V). From the results, the value of 3 times the standard deviation s (i.e., 3s) was determined, and the average of the 3s values at 400 points was calculated as a yardstick of LWR. The results are indicated under “LWR (nm)” in Table 5.

The smaller this 3s value is, the lower the level of roughness of the line width, indicating that a LS pattern with a uniform width was obtained.

[Evaluation of Resolution]

The critical resolution with the above Eop was determined using a scanning electron microscope (product name: S-9380, manufactured by Hitachi High-Technologies Corporation). The results are indicated under “resolution (nm)” in Table 5.

[Evaluation of Resist Pattern Shape]

With respect to each dense LS pattern formed in the aforementioned <Formation of resist pattern>, the cross-sectional shape thereof was observed using a scanning electron microscope (product name: SU-8000, manufactured by Hitachi High-Technologies Corporation), and the shape was evaluated with the following criteria. The results are shown in Table 5.

(Criteria)

A: high rectangularity and excellent shape

B: T-top shape or microbridge was observed.

TABLE 5

| | Rmin | PAB/PEB | Eop | EL margin | LWR | Resolution | |
|---|---|---|---|---|---|---|---|
| | (nm/s) | (° C./° C.) | (μC/cm²) | (%) | (nm) | (nm) | Shape |
| Example 1 | 0.008 | 130/110 | 70 | 12.4 | 6.5 | 35 | A |
| Example 2 | 0.009 | 130/110 | 73 | 12.4 | 6.2 | 35 | A |
| Example 3 | 0.008 | 130/110 | 72 | 11.0 | 7.3 | 35 | A |
| Example 4 | 0.010 | 130/110 | 75 | 11.5 | 7.0 | 35 | A |
| Example 5 | 0.011 | 130/100 | 66 | 11.6 | 6.9 | 35 | A |
| Example 6 | 0.011 | 130/100 | 68 | 11.0 | 7.1 | 35 | A |
| Example 7 | 0.009 | 130/100 | 68 | 11.3 | 6.8 | 35 | A |
| Example 8 | 0.010 | 130/100 | 70 | 11.9 | 6.8 | 35 | A |
| Example 9 | 0.005 | 130/110 | 81 | 16.8 | 6.3 | 35 | A |
| Example 10 | 0.006 | 130/110 | 79 | 15.5 | 6.9 | 35 | A |
| Example 11 | 0.015 | 130/110 | 69 | 11.0 | 7.3 | 40 | A |
| Example 12 | 0.014 | 130/110 | 83 | 13.9 | 7.9 | 40 | A |
| Example 13 | 0.015 | 130/110 | 70 | 11.1 | 8.3 | 40 | A |
| Example 14 | 0.019 | 130/110 | 75 | 12.2 | 8.1 | 40 | A |
| Example 15 | 0.008 | 130/110 | 69 | 11.0 | 7.5 | 45 | A |
| Example 16 | 0.004 | 130/110 | 76 | 12.2 | 7.1 | 40 | A |
| Example 17 | 0.004 | 130/110 | 76 | 13.0 | 7.1 | 40 | A |
| Example 18 | 0.018 | 130/110 | 65 | 10.9 | 7.0 | 40 | A |
| Example 19 | 0.012 | 130/110 | 75 | 12.4 | 8.1 | 40 | A |
| Example 20 | 0.015 | 130/110 | 71 | 11.9 | 7.8 | 40 | A |
| Example 21 | 0.008 | 130/110 | 74 | 12.4 | 6.9 | 40 | A |
| Example 22 | 0.013 | 130/110 | 73 | 12.5 | 7.0 | 40 | A |
| Comparative | 0.045 | 115/100 | 68 | 7.8 | 11.0 | 50 | A |
| Example 1 | | | | | | | |
| Comparative | 0.039 | 115/100 | 65 | 7.5 | 10.5 | 50 | A |
| Example 2 | | | | | | | |
| Comparative | 0.020 | 115/100 | 69 | 7.8 | 9.2 | 50 | A |
| Example 3 | | | | | | | |
| Comparative | 0.025 | 115/100 | 82 | 9.8 | 9.2 | 50 | A |
| Example 4 | | | | | | | |
| Comparative | 0.025 | 115/100 | 81 | 10.0 | 8.7 | 50 | A |
| Example 5 | | | | | | | |
| Comparative | 0.029 | 115/100 | 72 | 8.8 | 10.0 | 50 | A |
| Example 6 | | | | | | | |
| Comparative | 0.008 | 130/110 | 63 | 9.8 | 11.8 | 50 | B |
| Example 7 | | | | | | | |
| Comparative | 0.010 | 130/110 | 67 | 8.5 | 13.0 | 50 | B |
| Example 8 | | | | | | | |

From the results shown in Table 5, it was confirmed that the resist compositions of the Examples according to the present invention were capable of forming a resist pattern having suppressed thickness loss during formation of a resist pattern, excellent lithography properties, and high rectangularity.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition for EUV or EB, comprising:
a base component (A) which generates acid upon exposure and exhibits changed solubility in a developing solution under action of acid,
the base component (A) comprising a polymeric compound (A1) comprising a structural unit (a0) represented by general formula (a0-1) shown below and a structural unit (a6) which generates acid upon exposure: 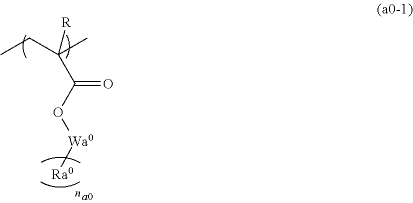
wherein R represents a hydrogen atom, an alkyl group of 1 to 5 carbon atoms or a halogenated alkyl group of 1 to 5 carbon atoms; Wa⁰ represents a single bond or an aliphatic hydrocarbon group having 1 to 5 carbon atoms and having a valency of (nₐ₀+1); Ra⁰ represents an aryl group of 4 to 16 carbon atoms which may have a substituent; and nₐ₀ represents 1 or 2.

2. The resist composition for EUV or EB according to claim 1, wherein the structural unit (a6) has a group represented by general formula (a6a-r-1) shown below, a group represented by general formula (a6a-r-2) shown below or a group represented by general formula (a6a-r-3) shown below: 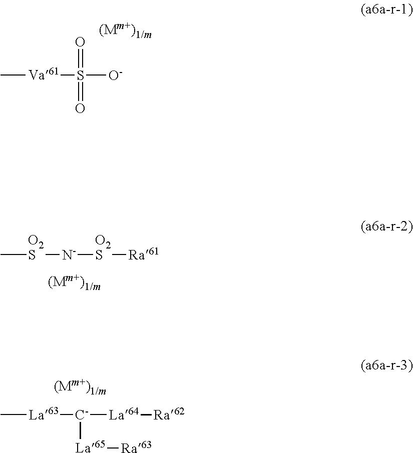
wherein Va′⁶¹ represents a divalent hydrocarbon group containing a fluorine atom; Ra′⁶¹ represents a hydrocarbon group; each of La′⁶³ to La′⁶⁵ independently represents an —SO₂— or a single bond; each of Ra′⁶² and Ra′⁶³ independently represents a hydrocarbon group; m is an integer of 1 or more; and M^{m+} is an organic cation having a valency of m.

3. The resist composition for EUV or EB according to claim 1, wherein
Wa⁰ represents an aliphatic hydrocarbon group having 1 to 5 carbon atoms and having a valency of (nₐ₀+1).

4. The resist composition for EUV or EB according to claim 1, wherein
Ra⁰ represents an aryl group of 8 to 16 carbon atoms which may have a substituent.

5. The resist composition for EUV or EB according to claim 1, wherein
Ra⁰ represents an aryl group of 10 to 14 carbon atoms which may have a substituent.

6. The resist composition for EUV or EB according to claim 1, wherein
the structural unit (a0) is at least one structural unit selected from the group consisting of structural units represented by general formulae (a0-1-1) to (a0-1-10) shown below: 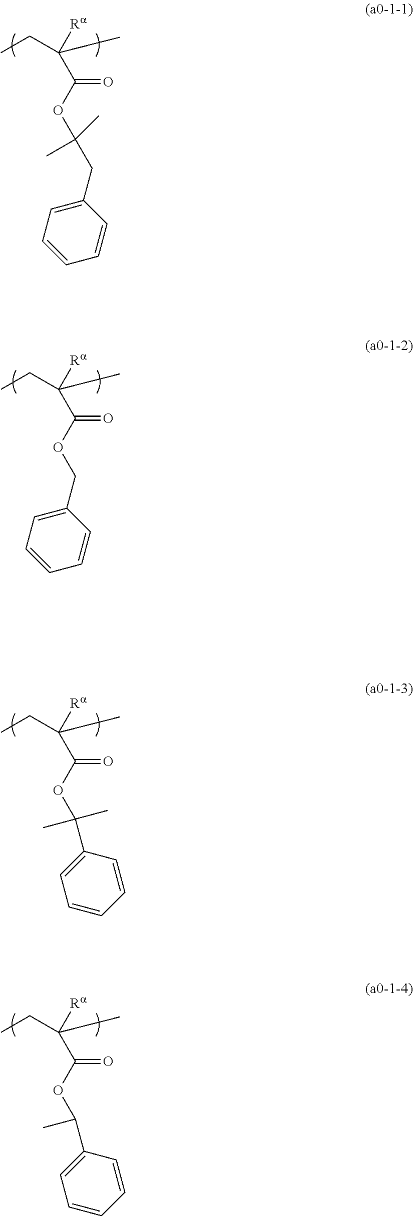 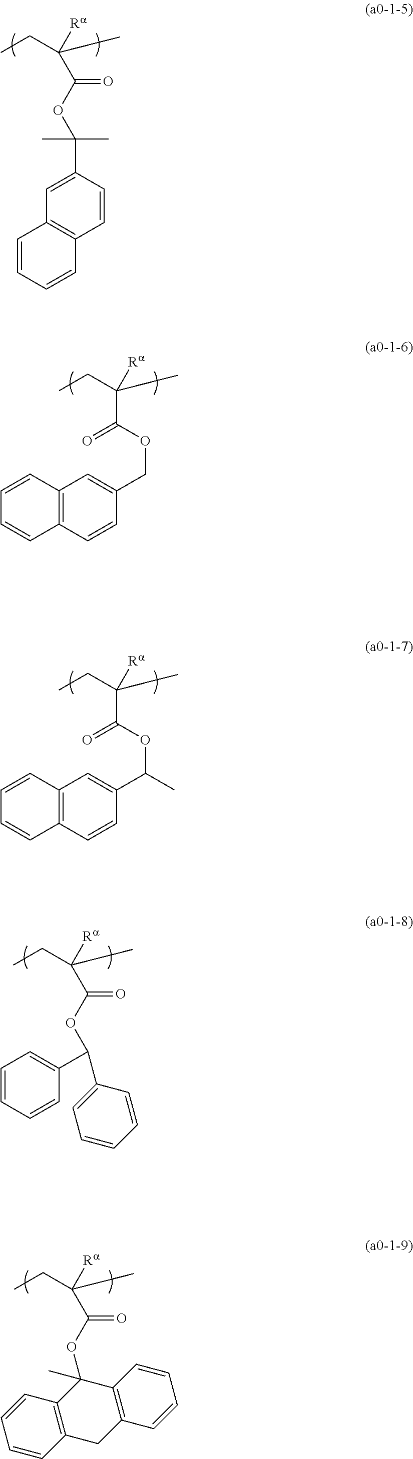 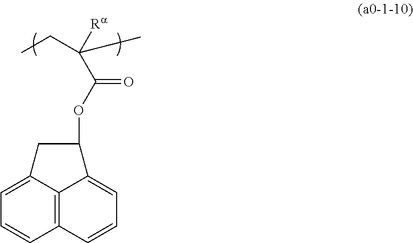
wherein R^{α} represents a hydrogen atom, a methyl group or a trifluoromethyl group.

7. The resist composition for EUV or EB according to claim 1, wherein
the structural unit (a0) is at least one structural unit selected from the group consisting of structural units represented by general formulae (a0-1-5) to (a0-1-7), (a0-1-9), and (a0-1-10) shown below: 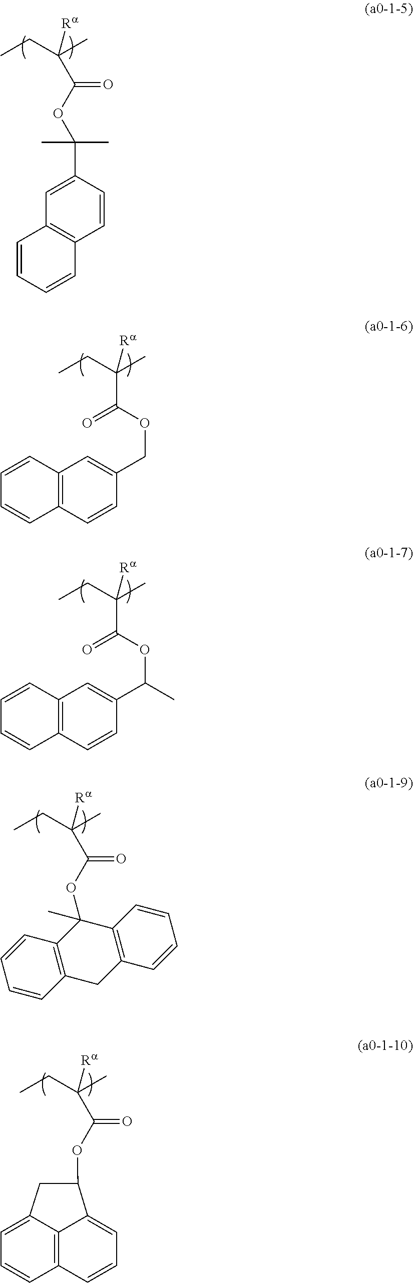
wherein R^{α} represents a hydrogen atom, a methyl group or a trifluoromethyl group.

8. The resist composition for EUV or EB according to claim 1, wherein
the amount of the structural unit (a0) based on the combined total of all structural units constituting the component (A1) is 20 to 60 mol %.

9. The resist composition for EUV or EB according to claim 2, wherein
the structural unit (a6) is at least one structural unit selected from the group consisting of structural units represented by general formulae (a6a-1) to (a6a-8) shown below: 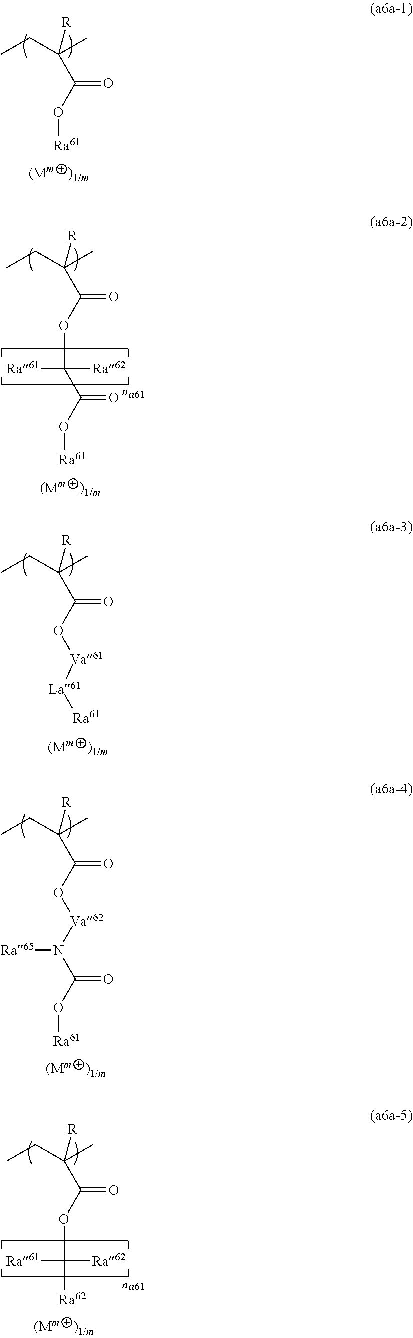 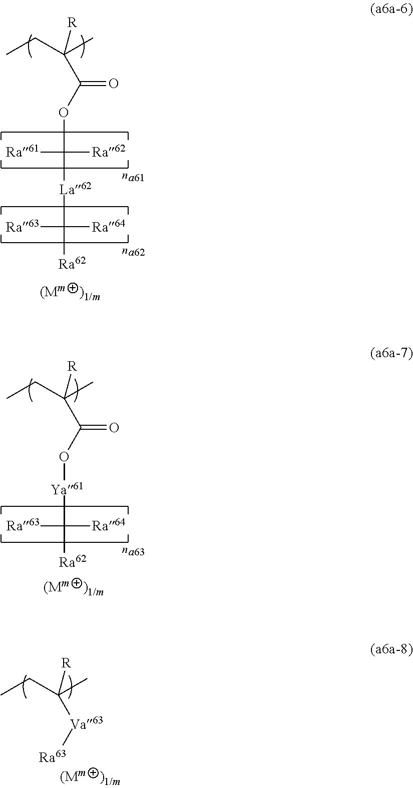
wherein R represents a hydrogen atom, an alkyl group of 1 to 5 carbon atoms or a halogenated alkyl group of 1 to 5 carbon atoms; Ra⁶¹ represents a group represented by the formula (a6a-r-1); Ra⁶² represents a group represented by the formula (a6a-r-2) or (a6a-r-3); Ra⁶³ represents a group represented by the formula (a6a-r-3); each of Ra″⁶¹ to Ra″⁶⁴ independently represents a hydrogen atom, a fluorine atom, an alkyl group of 1 to 5 carbon atoms or a fluorinated alkyl group; each of nₐ₆₁ and nₐ₆₂ independently represents an integer of 1 to 10; nₐ₆₃ represents an integer of 0 to 10; Va″⁶¹ represents a divalent cyclic hydrocarbon group; La″⁶¹ represents —C(═O)—O—, —O—C(═O)—O—, or —O—CH₂—C(═O)—O—; Va″⁶² represents a divalent hydrocarbon group; Ra″⁶⁵ represents a hydrogen atom or an alkyl group of 1 to 5 carbon atoms; La″⁶² represents —C(═O)—O—, —O—C(═O)—O—, or —NH—C(═O)—O—; Ya″⁶¹ represents a divalent linking group containing a cyclic hydrocarbon group; Va″⁶³ represents a divalent cyclic hydrocarbon group or a single bond; m represents an integer of 1 or more; and M^{m+} each independently represents an organic cation having a valency of m.

10. The resist composition for EUV or EB according to claim 9, wherein
the structural unit (a6) is at least one structural unit selected from the group consisting of structural units represented by general formulae shown below: 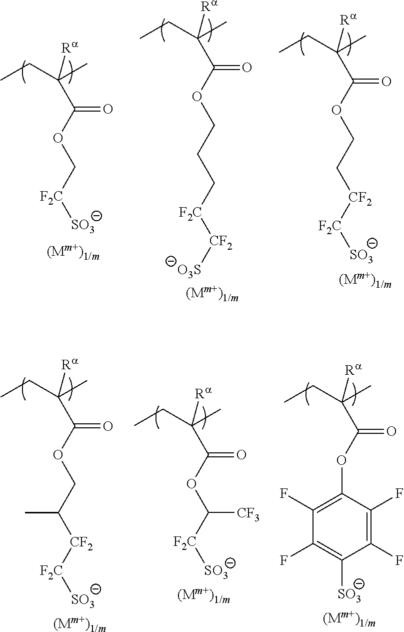
wherein m is an integer of 1 or more; and M^{m+} is an organic cation having a valency of m.

11. The resist composition for EUV or EB according to claim 1, wherein
the amount of the structural unit (a6) within the component (A1) based on the combined total of all structural units constituting the component (A1) is 5 to 35 mol %.

12. The resist composition for EUV or EB according to claim 1, wherein the polymeric compound (A1) further comprises a structural unit (a1) which contains an acid decomposable group and exhibits increased polarity by the action of acid.

13. The resist composition for EUV or EB according to claim 1, wherein the polymeric compound (A1) further comprises a structural unit (a2) which contains a lactone-containing cyclic group, an —SO₂— containing cyclic group or a carbonate-containing cyclic group.

14. The resist composition for EUV or EB according to claim 1, wherein the polymeric compound (A1) further comprises a structural unit (a3) which contains a polar group-containing aliphatic hydrocarbon group.

15. The resist composition for EUV or EB according to claim 1, wherein the polymeric compound (A1) further comprises a structural unit (a10) represented by general formula (a10-1) shown below: 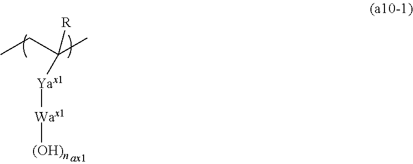
wherein R represents a hydrogen atom, an alkyl group of 1 to 5 carbon atoms or a halogenated alkyl group of 1 to 5 carbon atoms; Ya^{x1} represents a single bond or a divalent linking group; Wa^{x1} represents an aromatic hydrocarbon group having a valency of (nₐₓ₁+1); and nₐₓ₁ represents an integer of 0 to 3, provided that, when nₐₓ₁ is 0, Ya^{x1} represents a divalent linking group containing a NH bond.

16. The resist composition for EUV or EB according to claim 1, wherein
the structural unit (a0) is at least one structural unit selected from the group consisting of structural units represented by general formulae (01) to (10) shown below; and
the structural unit (a6) is at least one structural unit selected from the group consisting of structural units represented by general formulae (61) and (62) shown below:

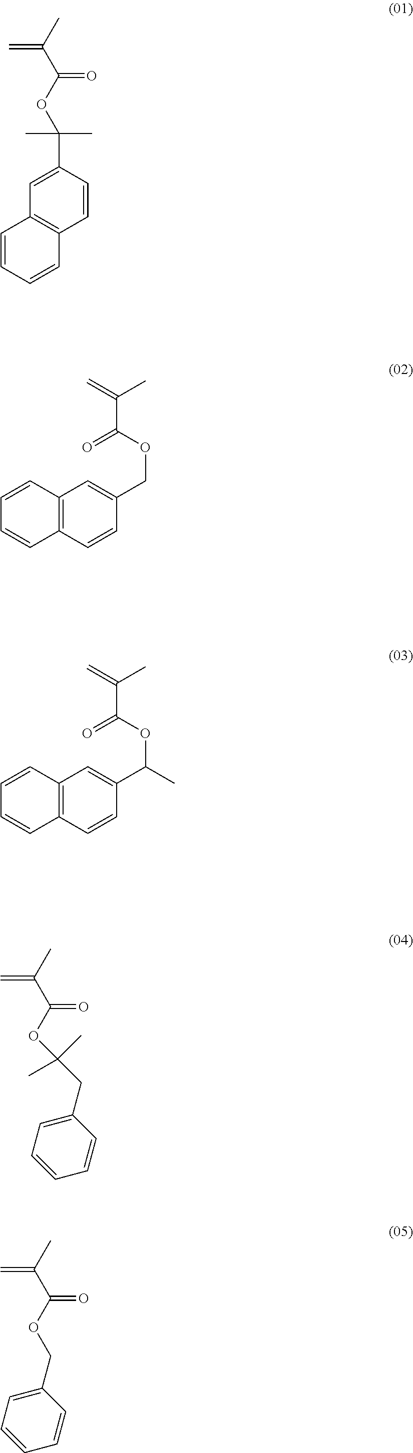

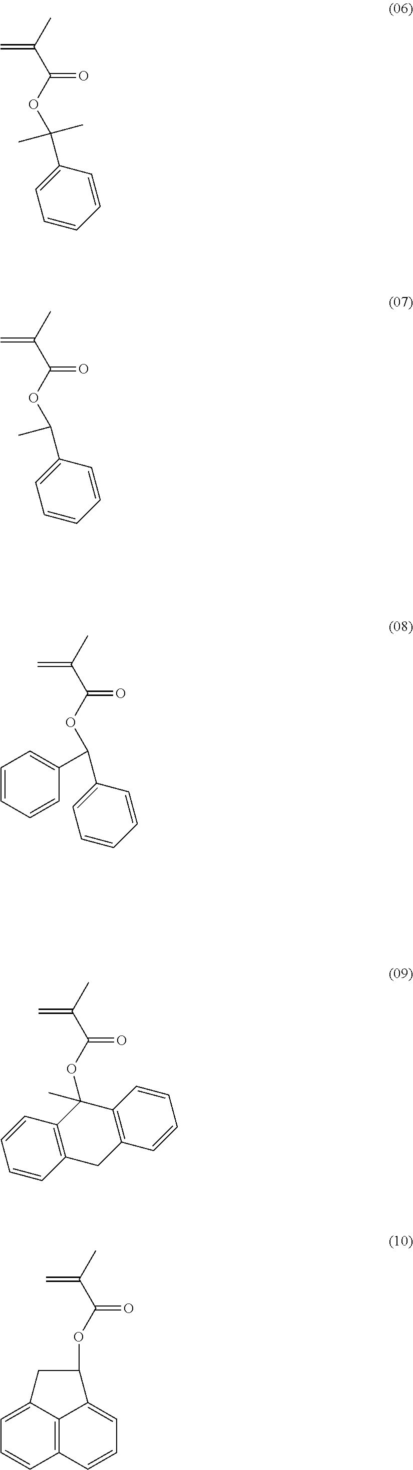

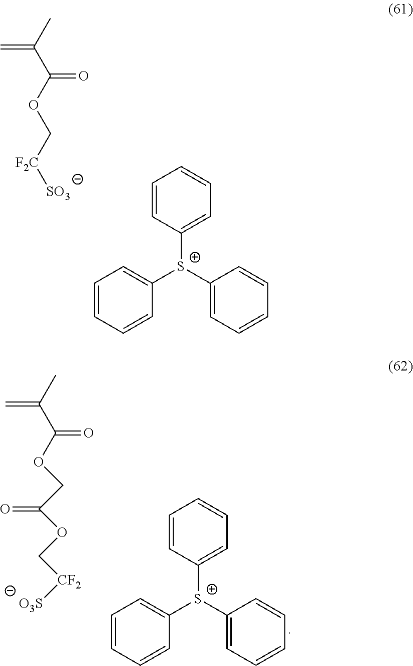

17. The resist composition for EUV or EB according to claim 1, wherein
the structural unit (a0) is at least one structural unit selected from the group consisting of structural units represented by general formulae (01) to (03), (09), and (10) shown below; and
the structural unit (a6) is at least one structural unit selected from the group consisting of structural units represented by general formulae (61) and (62) shown below:

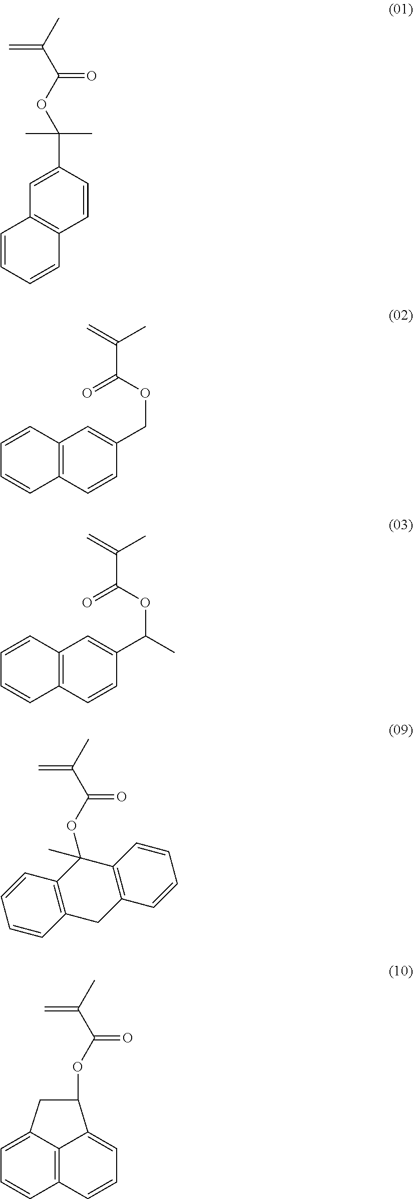

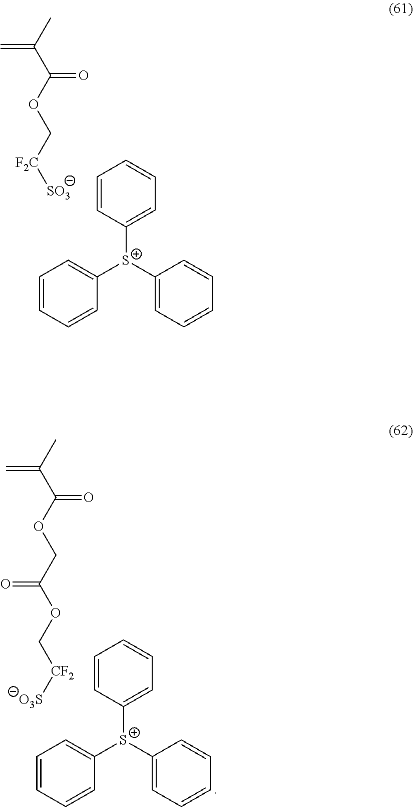

18. The resist composition for EUV or EB according to claim 16, the polymeric compound (A1) further comprises at least one structural unit selected from the group consisting of structural units represented by general formulae (21) to (23), (31), (101) and (102) shown below:

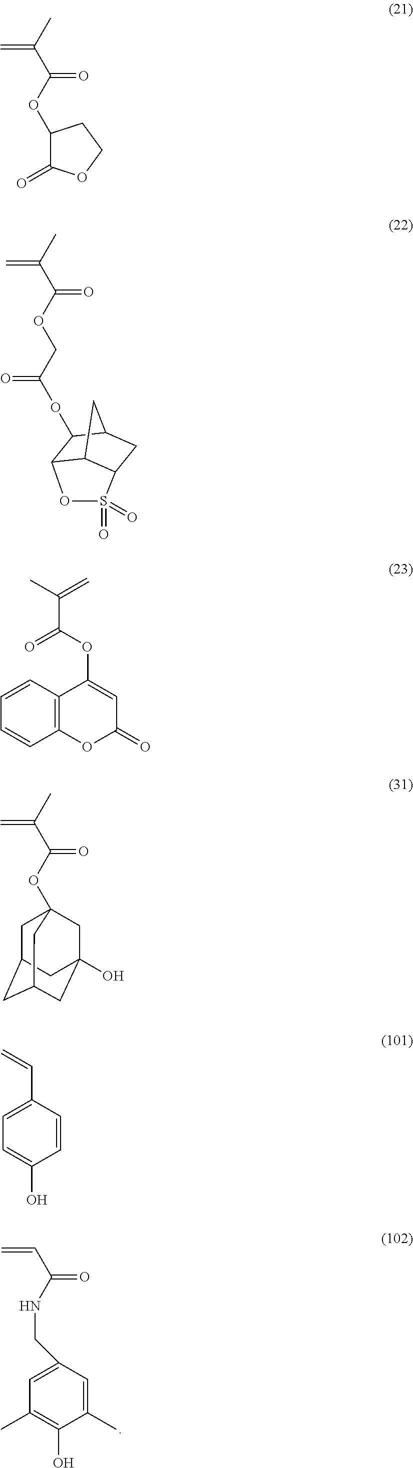

19. The resist composition for EUV or EB according to claim 17, the polymeric compound (A1) further comprises at least one structural unit selected from the group consisting of structural units represented by general formulae (21) to (23), (31), (101) and (102) shown below:

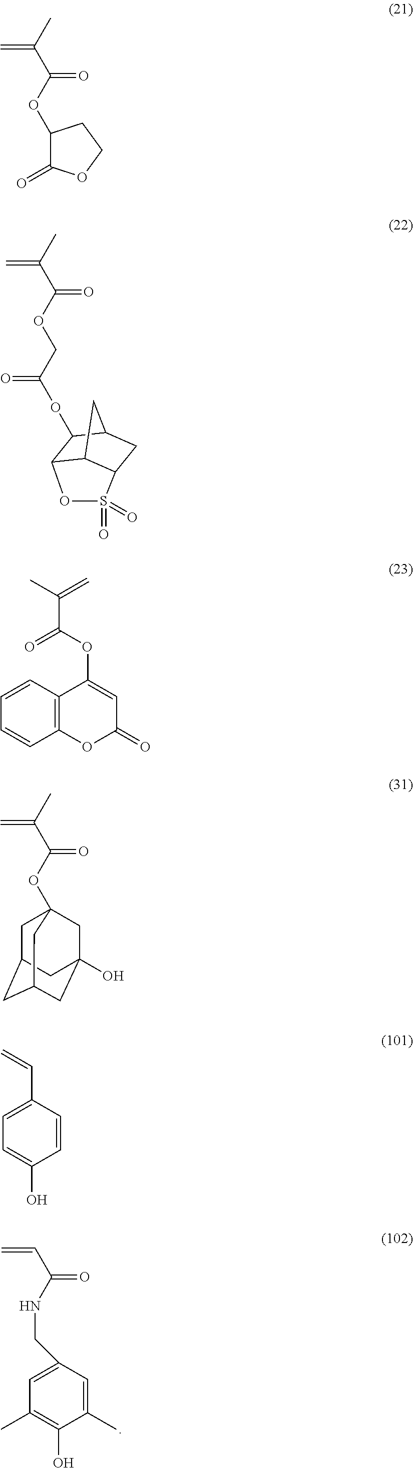

20. A method of forming a resist pattern, comprising: forming a resist film on a substrate using a resist composition for EUV or EB of claim 1; subjecting the resist film to irradiate with EUV or EB; and developing the resist film to form a resist pattern.
